(19) United States
(12) Patent Application Publication
(10) Pub. No.: US 2013/0050228 A1
(43) Pub. Date: Feb. 28, 2013

(54) GLASS AS A SUBSTRATE MATERIAL AND A FINAL PACKAGE FOR MEMS AND IC DEVICES

(71) Applicants: Kurt Edward Petersen, Milpitas, CA (US); Ravindra V. Shenoy, Dublin, CA (US); Justin Phelps Black, Santa Clara, CA (US); David William Burns, San Jose, CA (US); Srinivasan Kodaganallur Ganapathi, Palo Alto, CA (US); Philip Jason Stephanou, Mountain View, CA (US); Nicholas Ian Buchan, San Jose, CA (US)

(72) Inventors: Kurt Edward Petersen, Milpitas, CA (US); Ravindra V. Shenoy, Dublin, CA (US); Justin Phelps Black, Santa Clara, CA (US); David William Burns, San Jose, CA (US); Srinivasan Kodaganallur Ganapathi, Palo Alto, CA (US); Philip Jason Stephanou, Mountain View, CA (US); Nicholas Ian Buchan, San Jose, CA (US)

(73) Assignee: QUALCOMM MEMS TECHNOLOGIES, INC., San Diego, CA (US)

(21) Appl. No.: 13/221,717

(22) Filed: Aug. 30, 2011

(51) Int. Cl. G06T 1/00; H01L 23/15; H01L 21/78; H01L 21/52

(52) U.S. Cl. 345/501; 438/118; 257/692; 438/113; 257/E23.009; 257/E21.5; 257/E21.599

(57) ABSTRACT

This disclosure provides systems, methods and apparatus for glass packaging of integrated circuit (IC) and electromechanical systems (EMS) devices. In one aspect, fabricating a glass package includes joining a cover glass panel to a glass substrate panel, and singulating the joined panels to form individual glass packages, each including one or more encapsulated devices and one or more signal transmission pathways. In another aspect, a glass package may include a glass substrate, a cover glass and one or more devices encapsulated between the glass substrate and the cover glass.

### TECHNICAL FIELD

This disclosure relates to structures and processes for glass packaging of electromechanical systems and integrated circuit devices.

### DESCRIPTION OF THE RELATED TECHNOLOGY

Electromechanical systems (EMS) include devices having electrical and mechanical elements, actuators, transducers, sensors, optical components (including mirrors) and electronics. Electromechanical systems can be manufactured at a variety of scales including, but not limited to, microscales and nanoscales. For example, microelectromechanical systems (MEMS) devices can include structures having sizes ranging from about a micron to hundreds of microns or more. Nanoelectromechanical systems (NEMS) devices can include structures having sizes smaller than a micron including, for example, sizes smaller than several hundred nanometers. Electromechanical elements may be created using deposition, etching, lithography, and/or other micromachining processes that etch away parts of substrates and/or deposited material layers, or that add layers to form electrical and electromechanical devices.

One type of EMS device is called an interferometric modulator (IMOD). The term interferometric modulator or interferometric light modulator refers to a device that selectively absorbs and/or reflects light using the principles of optical interference. In some implementations, an interferometric modulator may include a pair of conductive plates, one or both of which may be transparent and/or reflective, wholly or in part, and capable of relative motion upon application of an appropriate electrical signal. For example, one plate may include a stationary layer deposited on a substrate and the other plate may include a reflective membrane separated from the stationary layer by an air gap. The position of one plate in relation to another can change the optical interference of light incident on the interferometric modulator. Interferometric modulator devices have a wide range of applications, and are anticipated to be used in improving existing products and creating new products, especially those with display capabilities.

Packaging protects the functional units of the system from the environment, provides mechanical support for the system components, and provides an interface for electrical interconnections.

### SUMMARY

The systems, methods and devices of the disclosure each have several innovative aspects, no single one of which is solely responsible for the desirable attributes disclosed herein.

One innovative aspect of the subject matter described in this disclosure can be implemented in methods of packaging devices. In some implementations, the methods can include attaching an integrated circuit (IC) device to bond pads on a glass substrate such that the IC device is in electrical communication with an electromechanical systems (EMS) device fabricated on the glass substrate. Further, a cover glass can be aligned with the glass substrate such that the cover glass covers the EMS device and the IC device. The cover glass can be joined to the glass substrate to form a seal wholly or partially surrounding at least one of the EMS device and the IC device.

In some implementations, joining the cover glass to the glass substrate includes forming a metal-to-metal bond between a metal joining ring on the cover glass and a metal joining ring on the glass substrate. A metal-to-metal bond can include, for example, one or more of a eutectic alloy, a non-eutectic alloy, a solder material, or an intermetallic compound. In some implementations, the metal joining ring on the cover glass and the metal joining on the glass substrate differ in width by at least about 50 microns. The metal-to-metal bond can include a fillet joint. In some implementations, the methods can further include plating the cover glass to simultaneously form metal components of a cover glass, including one or more of through-glass via interconnects, metal joining rings, bond pads and conductive routing. A metal joining ring can be formed on the glass substrate during fabrication of the EMS device.

In some implementations, joining the cover glass to the glass substrate includes forming an epoxy bond between the cover glass and the glass substrate. In some implementations, joining the cover glass to the glass substrate includes forming a glass frit bond between the cover glass and the glass substrate. Joining the cover glass to the glass substrate can include simultaneously joining the cover glass to the glass substrate and establishing an electrically conductive pathway between conductive traces on the cover glass and conductive traces on the glass substrate.

Another innovative aspect of the subject matter described in this disclosure can be implemented in an apparatus formed by attaching an IC device to bond pads on a glass substrate such that the IC device is in electrical communication with an EMS device fabricated on the glass substrate. A cover glass can be aligned with the glass substrate such that the cover glass covers the EMS device and the IC device. The cover glass can be joined to the glass substrate to form a seal wholly or partially surrounding at least one of the EMS device and the IC device.

Another innovative aspect of the subject matter described in this disclosure can be implemented in methods of forming individual glass packages. In some implementations, the methods can include aligning a glass substrate panel including a plurality of device units with a cover glass panel including a plurality of cover glass units, joining the cover glass panel to the glass substrate panel, and singulating the joined glass substrate and cover glass panels to form a plurality of individual glass packages. Each of the plurality of individual glass packages can include a cover glass sealed to a glass substrate, a device disposed within a cavity between the cover glass and the glass substrate, and a signal transmission pathway between the device and an exterior of the individual glass package. In some implementations, joining the glass substrate panel to the cover glass panel includes forming a plurality of joining rings, each of which can seal a cover glass unit to a device unit.

In some implementations the methods can include forming a plurality of recesses and through-glass via holes in the cover glass panel. In some implementations, the methods can include metalizing the cover glass panel to form the plurality of cover glass units. Each cover glass unit can includes a metal joining ring surrounding a recess, a through-glass via interconnect, a bond pad on a surface of the cover glass panel and electrical routing from the through-glass via interconnect to the bond pad.

Details of one or more implementations of the subject matter described in this specification are set forth in the accompanying drawings and the description below. Although the examples provided in this disclosure are primarily described in terms of electromechanical systems (EMS) and microelectromechanical systems (MEMS)-based displays, the concepts provided herein may apply to other types of displays, such as liquid crystal displays, organic light-emitting diode (“OLED”) displays and field emission displays. Other features, aspects, and advantages will become apparent from the description, the figures and the claims. Note that the relative dimensions of the following figures may not be drawn to scale.

### BRIEF DESCRIPTION OF THE DRAWINGS

FIG. 1 shows an example of an isometric view depicting two adjacent pixels in a series of pixels of an interferometric modulator (IMOD) display device.

FIG. 2 shows an example of a system block diagram illustrating an electronic device incorporating a 3×3 interferometric modulator display.

FIG. 3 shows an example of a diagram illustrating movable reflective layer position versus applied voltage for the interferometric modulator of FIG. 1.

FIG. 4 shows an example of a table illustrating various states of an interferometric modulator when various common and segment voltages are applied.

FIG. 5A shows an example of a diagram illustrating a frame of display data in the 3×3 interferometric modulator display of FIG. 2.

FIG. 5B shows an example of a timing diagram for common and segment signals that may be used to write the frame of display data illustrated in FIG. 5A.

FIG. 6A shows an example of a partial cross-section of the interferometric modulator display of FIG. 1.

FIGS. 6B-6E show examples of cross-sections of varying implementations of interferometric modulators.

FIG. 7 shows an example of a flow diagram illustrating a manufacturing process for an interferometric modulator.

FIGS. 8A-8E show examples of cross-sectional schematic illustrations of various stages in a method of making an interferometric modulator.

FIG. 9 shows an example of a cross-sectional schematic illustration of a packaged device.

FIGS. 10A and 10B show examples of schematic illustrations of a top view of an integrated circuit (IC) device on a glass substrate.

FIGS. 11A and 11B show examples of cross-sectional schematic illustrations of a packaged IC device.

FIG. 11C shows an example of a cross-sectional schematic illustration of a packaged MEMS device.

FIGS. 12A and 12B show examples of schematic illustrations of a top view of an IC device and a MEMS device on a glass substrate.

FIGS. 13A-13E show examples of cross-sectional schematic illustrations of glass packages including a MEMS device and an IC device.

FIG. 14 shows an example of a cross-sectional schematic illustration of a glass package including a signal transmission pathway.

FIGS. 15A-17B show examples of schematic illustrations of exploded and isometric views of glass-encapsulated IC and MEMS devices including through-glass via interconnects and a port.

FIGS. 18A-18H show examples of schematic illustrations of top views of sealed glass packages.

FIGS. 19A-19E show examples of schematic illustrations of isometric views of glass-encapsulated MEMS devices including fluid access to a MEMS device.

FIG. 20 shows an example of a schematic illustration of an isometric view depicting a portion of a glass package including peripheral through-glass via interconnects.

FIGS. 21A-21C show examples of schematic illustrations of isometric cross-sectional views of through-glass via interconnects having various opening shapes.

FIG. 22 shows an example of a schematic illustration of a top view of a portion of a package including an array of non-peripheral multi-trace through-glass vias.

FIGS. 23A-23C show examples of schematic illustrations of sidewall metallization patterns of through-glass vias interconnects.

FIGS. 24A-24D show examples of cross-sectional schematic illustrations of through glass via holes and interconnects.

FIGS. 25A and 25B show examples of schematic illustrations of exploded and isometric views of glass-encapsulated IC and MEMS devices connected to a flat flexible connector.

FIGS. 25C and 25D show examples of schematic illustrations of exploded and isometric views of a glass-encapsulated MEMS device connected to a flat flexible connector.

FIG. 26 shows an example of a flow diagram illustrating a batch level manufacturing process for a glass package.

FIGS. 27A-27C show examples of schematic illustrations of various stages of a batch level process of fabricating individual dies including encapsulated devices.

FIGS. 28A and 28B shows examples of flow diagrams illustrating processes for forming joined glass substrate and cover glass sub-panels.

FIGS. 29A-34B show examples of cross-sectional and plan views of schematic illustrations of various stages in a method of encapsulating devices in a glass package.

FIG. 35 shows an example of a flow diagram illustrating a manufacturing process for a cover glass panel including through-glass via interconnects.

FIGS. 36A and 36B show examples of cross-sectional schematic illustrations of metal joining rings including solder bonds.

FIGS. 37A and 37B show examples of cross-sectional schematic illustrations of a glass package including a coating.

FIG. 38 shows an example of a flow diagram illustrating a process for coating glass packages.

FIGS. 39A and 39B show examples of system block diagrams illustrating a display device that includes a plurality of interferometric modulators.

Like reference numbers and designations in the various drawings indicate like elements.

### DETAILED DESCRIPTION

The following description is directed to certain implementations for the purposes of describing the innovative aspects of this disclosure. However, a person having ordinary skill in the art will readily recognize that the teachings herein can be applied in a multitude of different ways. The described implementations may be implemented in any device or system that can be configured to display an image, whether in motion (e.g., video) or stationary (e.g., still image), and whether textual, graphical or pictorial. More particularly, it is contemplated that the described implementations may be included in or associated with a variety of electronic devices such as, but not limited to: mobile telephones, multimedia Internet enabled cellular telephones, mobile television receivers, wireless devices, smartphones, Bluetooth® devices, personal data assistants (PDAs), wireless electronic mail receivers, hand-held or portable computers, netbooks, notebooks, smartbooks, tablets, printers, copiers, scanners, facsimile devices, GPS receivers/navigators, cameras, MP3 players, camcorders, game consoles, wrist watches, clocks, calculators, television monitors, flat panel displays, electronic reading devices (i.e., e-readers), computer monitors, auto displays (including odometer and speedometer displays, etc.), cockpit controls and/or displays, camera view displays (such as the display of a rear view camera in a vehicle), electronic photographs, electronic billboards or signs, projectors, architectural structures, microwaves, refrigerators, stereo systems, cassette recorders or players, DVD players, CD players, VCRs, radios, portable memory chips, washers, dryers, washer/dryers, parking meters, packaging (such as in electromechanical systems (EMS), microelectromechanical systems (MEMS) and non-MEMS applications), aesthetic structures (e.g., display of images on a piece of jewelry) and a variety of EMS devices. The teachings herein also can be used in non-display applications such as, but not limited to, electronic switching devices, radio frequency filters, sensors, accelerometers, gyroscopes, motion-sensing devices, magnetometers, inertial components for consumer electronics, parts of consumer electronics products, varactors, liquid crystal devices, electrophoretic devices, drive schemes, manufacturing processes and electronic test equipment. Thus, the teachings are not intended to be limited to the implementations depicted solely in the Figures, but instead have wide applicability as will be readily apparent to one having ordinary skill in the art.

Some implementations described herein relate to packaging of electromechanical systems (EMS) and integrated circuit (IC) devices. Some implementations described herein relate to glass packages including one or more IC and EMS devices encapsulated between a cover glass and a glass substrate. In some implementations, a glass substrate is a substrate on which an MEMS or other EMS device is fabricated as well as, with the cover glass, a package for the device. In some implementations, a glass substrate is a substrate on which an IC device is attached or fabricated, as well as, with the cover glass, a package for the device. In some implementations, a glass package including an EMS and/or IC device is configured to be directly attached to a printed circuit board (PCB) or other integration substrate by standard surface mount technology.

In some implementations, a glass package includes one or more pads configured to attach to a flexible connector. A flexible connector, such as a flat flexible connector, can be used to electrically connect a device within the glass package to an electrical component, such as an integrated circuit (IC) device or PCB, outside the glass package. In some implementations, the electrical component is at a location remote from the glass package.

In some implementations, a glass package includes an electrical connection from an encapsulated device to an exterior surface of the package. The electrical connection can include through-glass via interconnects through a cover glass and/or glass substrate, and conductive traces formed on one or more surfaces of a cover glass and/or glass substrate.

In some implementations, a glass package includes a non-electrical signal transmission pathway between an encapsulated device and the exterior of the package. For example, a non-electrical signal transmission pathway can include one or more of a fluid access pathway, a light transmissive pathway, and a thermally transmissive pathway. In some implementations, a glass package includes a coating, such as a polymer, non-organic dielectric, or metal coating, on one or more exterior surfaces of the glass package. A coating can be used to increase opacity, provide package markings, provide a uniform package appearance, increase package visibility, increase package durability, increase scratch resistance of the package, increase shock resistance of the package, impart hermeticity to the package, provide electrical isolation package, provide heat transfer to or from the package and provide thermal isolation of the package.

In some implementations, methods of fabricating glass packages described herein include joining a cover glass panel to a glass substrate panel. A glass substrate panel can have tens to hundreds of thousands or more EMS or IC devices fabricated thereon or attached thereto. A cover glass panel can have tens to hundreds of thousands or more recesses configured to accommodate such devices. Once joined, the cover glass and glass substrate panels can be singulated to form individual glass packages, each including one or more encapsulated devices. In some implementations, all or most of the processing to fabricate or attach devices, to form electrical connections on or through a glass package, and to form other signal transmission pathways on or through a glass package, occurs at the panel level.

Particular implementations of the subject matter described in this disclosure can be implemented to realize one or more of the following potential advantages. A glass package can provide low cost, small size, and low profile devices. In some implementations, batch level processing methods can be used to eliminate or reduce die-level processing. Advantages of encapsulation and packaging in a batch process at a panel or sub-panel level include a large number of units fabricated in parallel in the batch process, thus reducing costs per unit as compared to individual die-level processing. The use of batch processes such as lithography, etching and plating over a large substrate in some implementations allows tighter tolerances and reduces die-to-die variation. The formation of through-glass interconnects and other metal components of a package in a single plating process stage can reduce costs per package. In some implementations, smaller and/or more reliably packaged devices can be fabricated. Smaller devices can result in a larger number of units fabricated in parallel in the batch process. In some implementations, package-related stresses on a MEMS or other device can be reduced or eliminated. For example, in some implementations, concerns related to molding-related process stresses on a device can be eliminated by providing a glass package with surface mount pads without molding.

An example of a suitable EMS or MEMS device, to which the described implementations may apply, is a reflective display device. Reflective display devices can incorporate interferometric modulators (IMODs) to selectively absorb and/or reflect light incident thereon using principles of optical interference. IMODs can include an absorber, a reflector that is movable with respect to the absorber, and an optical resonant cavity defined between the absorber and the reflector. The reflector can be moved to two or more different positions, which can change the size of the optical resonant cavity and thereby affect the reflectance of the interferometric modulator. The reflectance spectrums of IMODs can create fairly broad spectral bands which can be shifted across the visible wavelengths to generate different colors. The position of the spectral band can be adjusted by changing the thickness of the optical resonant cavity. One way of changing the optical resonant cavity is by changing the position of the reflector.

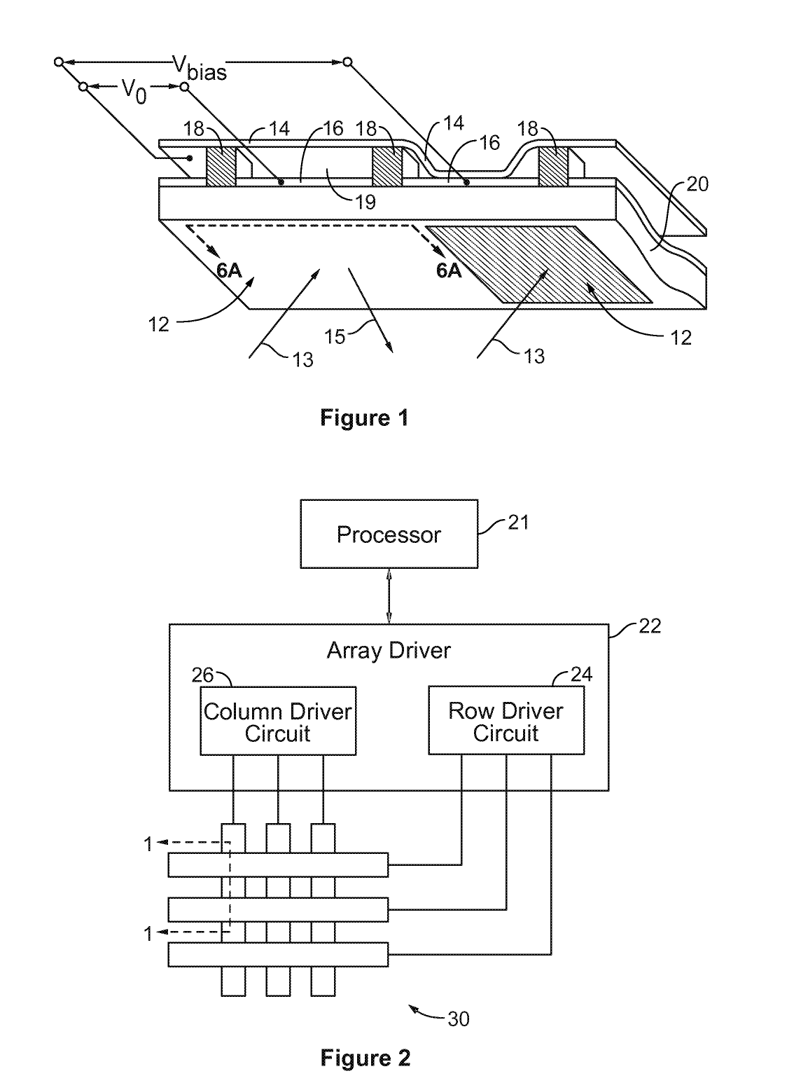

FIG. 1 shows an example of an isometric view depicting two adjacent pixels in a series of pixels of an interferometric modulator (IMOD) display device. The IMOD display device includes one or more interferometric MEMS display elements. In these devices, the pixels of the MEMS display elements can be in either a bright or dark state. In the bright (“relaxed,” “open” or “on”) state, the display element reflects a large portion of incident visible light, e.g., to a user. Conversely, in the dark (“actuated,” “closed” or “off”) state, the display element reflects little incident visible light. In some implementations, the light reflectance properties of the on and off states may be reversed. MEMS pixels can be configured to reflect predominantly at particular wavelengths allowing for a color display in addition to black and white.

The IMOD display device can include a row/column array of IMODs. Each IMOD can include a pair of reflective layers, i.e., a movable reflective layer and a fixed partially reflective layer, positioned at a variable and controllable distance from each other to form an air gap (also referred to as an optical gap or cavity). The movable reflective layer may be moved between at least two positions. In a first position, i.e., a relaxed position, the movable reflective layer can be positioned at a relatively large distance from the fixed partially reflective layer. In a second position, i.e., an actuated position, the movable reflective layer can be positioned more closely to the partially reflective layer. Incident light that reflects from the two layers can interfere constructively or destructively depending on the position of the movable reflective layer, producing either an overall reflective or non-reflective state for each pixel. In some implementations, the IMOD may be in a reflective state when unactuated, reflecting light within the visible spectrum, and may be in a dark state when unactuated, reflecting light outside of the visible range (e.g., infrared light). In some other implementations, however, an IMOD may be in a dark state when unactuated, and in a reflective state when actuated. In some implementations, the introduction of an applied voltage can drive the pixels to change states. In some other implementations, an applied charge can drive the pixels to change states.

The depicted portion of the pixel array in FIG. 1 includes two adjacent interferometric modulators 12. In the IMOD 12 on the left (as illustrated), a movable reflective layer 14 is illustrated in a relaxed position at a predetermined distance from an optical stack 16, which includes a partially reflective layer. The voltage V₀ applied across the IMOD 12 on the left is insufficient to cause actuation of the movable reflective layer 14. In the IMOD 12 on the right, the movable reflective layer 14 is illustrated in an actuated position near or adjacent the optical stack 16. The voltage V_{bias} applied across the IMOD 12 on the right is sufficient to maintain the movable reflective layer 14 in the actuated position.

In FIG. 1, the reflective properties of pixels 12 are generally illustrated with arrows 13 indicating light incident upon the pixels 12, and light 15 reflecting from the pixel 12 on the left. Although not illustrated in detail, it will be understood by one having ordinary skill in the art that most of the light 13 incident upon the pixels 12 will be transmitted through the transparent substrate 20, toward the optical stack 16. A portion of the light incident upon the optical stack 16 will be transmitted through the partially reflective layer of the optical stack 16, and a portion will be reflected back through the transparent substrate 20. The portion of light 13 that is transmitted through the optical stack 16 will be reflected at the movable reflective layer 14, back toward (and through) the transparent substrate 20. Interference (constructive or destructive) between the light reflected from the partially reflective layer of the optical stack 16 and the light reflected from the movable reflective layer 14 will determine the wavelength(s) of light 15 reflected from the pixel 12.

The optical stack 16 can include a single layer or several layers. The layer(s) can include one or more of an electrode layer, a partially reflective and partially transmissive layer and a transparent dielectric layer. In some implementations, the optical stack 16 is electrically conductive, partially transparent and partially reflective, and may be fabricated, for example, by depositing one or more of the above layers onto a transparent substrate 20. The electrode layer can be formed from a variety of materials, such as various metals, for example indium tin oxide (ITO). The partially reflective layer can be formed from a variety of materials that are partially reflective, such as various metals, such as chromium (Cr), semiconductors, and dielectrics. The partially reflective layer can be formed of one or more layers of materials, and each of the layers can be formed of a single material or a combination of materials. In some implementations, the optical stack 16 can include a single semi-transparent thickness of metal or semiconductor which serves as both an optical absorber and conductor, while different, more conductive layers or portions (e.g., of the optical stack 16 or of other structures of the IMOD) can serve to bus signals between IMOD pixels. The optical stack 16 also can include one or more insulating or dielectric layers covering one or more conductive layers or a conductive/absorptive layer.

In some implementations, the layer(s) of the optical stack 16 can be patterned into parallel strips, and may form row electrodes in a display device as described further below. As will be understood by one having skill in the art, the term “patterned” is used herein to refer to masking as well as etching processes. In some implementations, a highly conductive and reflective material, such as aluminum (Al), may be used for the movable reflective layer 14, and these strips may form column electrodes in a display device. The movable reflective layer 14 may be formed as a series of parallel strips of a deposited metal layer or layers (orthogonal to the row electrodes of the optical stack 16) to form columns deposited on top of posts 18 and an intervening sacrificial material deposited between the posts 18. When the sacrificial material is etched away, a defined gap 19, or optical cavity, can be formed between the movable reflective layer 14 and the optical stack 16. In some implementations, the spacing between posts 18 may be approximately 1-1000 um, while the gap 19 may be approximately less than 10,000 Angstroms (Å).

In some implementations, each pixel of the IMOD, whether in the actuated or relaxed state, is essentially a capacitor formed by the fixed and moving reflective layers. When no voltage is applied, the movable reflective layer 14 remains in a mechanically relaxed state, as illustrated by the pixel 12 on the left in FIG. 1, with the gap 19 between the movable reflective layer 14 and optical stack 16. However, when a potential difference, e.g., voltage, is applied to at least one of a selected row and column, the capacitor formed at the intersection of the row and column electrodes at the corresponding pixel becomes charged, and electrostatic forces pull the electrodes together. If the applied voltage exceeds a threshold, the movable reflective layer 14 can deform and move near or against the optical stack 16. A dielectric layer (not shown) within the optical stack 16 may prevent shorting and control the separation distance between the layers 14 and 16, as illustrated by the actuated pixel 12 on the right in FIG. 1. The behavior is the same regardless of the polarity of the applied potential difference. Though a series of pixels in an array may be referred to in some instances as “rows” or “columns,” a person having ordinary skill in the art will readily understand that referring to one direction as a “row” and another as a “column” is arbitrary. Restated, in some orientations, the rows can be considered columns, and the columns considered to be rows. Furthermore, the display elements may be evenly arranged in orthogonal rows and columns (an “array”), or arranged in non-linear configurations, for example, having certain positional offsets with respect to one another (a “mosaic”). The terms “array” and “mosaic” may refer to either configuration. Thus, although the display is referred to as including an “array” or “mosaic,” the elements themselves need not be arranged orthogonally to one another, or disposed in an even distribution, in any instance, but may include arrangements having asymmetric shapes and unevenly distributed elements.

FIG. 2 shows an example of a system block diagram illustrating an electronic device incorporating a 3×3 interferometric modulator display. The electronic device includes a processor 21 that may be configured to execute one or more software modules. In addition to executing an operating system, the processor 21 may be configured to execute one or more software applications, including a web browser, a telephone application, an email program, or any other software application.

The processor 21 can be configured to communicate with an array driver 22. The array driver 22 can include a row driver circuit 24 and a column driver circuit 26 that provide signals to, e.g., a display array or panel 30. The cross section of the IMOD display device illustrated in FIG. 1 is shown by the lines 1-1 in FIG. 2. Although FIG. 2 illustrates a 3×3 array of IMODs for the sake of clarity, the display array 30 may contain a very large number of IMODs, and may have a different number of IMODs in rows than in columns, and vice versa.

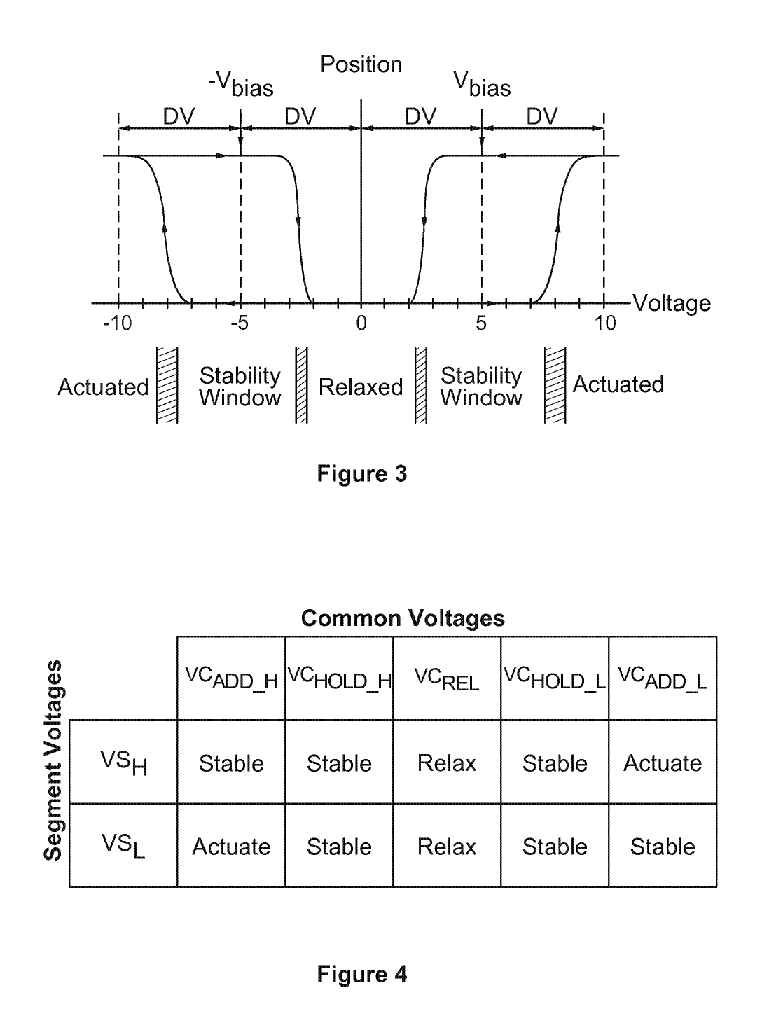

FIG. 3 shows an example of a diagram illustrating movable reflective layer position versus applied voltage for the interferometric modulator of FIG. 1. For MEMS interferometric modulators, the row/column (i.e., common/segment) write procedure may take advantage of a hysteresis property of these devices as illustrated in FIG. 3. An interferometric modulator may use, for example, about a 10-volt potential difference to cause the movable reflective layer, or mirror, to change from the relaxed state to the actuated state. When the voltage is reduced from that value, the movable reflective layer maintains its state as the voltage drops back below, e.g., 10-volts, however, the movable reflective layer does not relax completely until the voltage drops below 2-volts. Thus, a range of voltage, approximately 3 to 7-volts, as shown in FIG. 3, exists where there is a window of applied voltage within which the device is stable in either the relaxed or actuated state. This is referred to herein as the “hysteresis window” or “stability window.” For a display array 30 having the hysteresis characteristics of FIG. 3, the row/column write procedure can be designed to address one or more rows at a time, such that during the addressing of a given row, pixels in the addressed row that are to be actuated are exposed to a voltage difference of about 10-volts, and pixels that are to be relaxed are exposed to a voltage difference of near zero volts. After addressing, the pixels are exposed to a steady state or bias voltage difference of approximately 5-volts such that they remain in the previous strobing state. In this example, after being addressed, each pixel sees a potential difference within the “stability window” of about 3-7-volts. This hysteresis property feature enables the pixel design, e.g., illustrated in FIG. 1, to remain stable in either an actuated or relaxed pre-existing state under the same applied voltage conditions. Since each IMOD pixel, whether in the actuated or relaxed state, is essentially a capacitor formed by the fixed and moving reflective layers, this stable state can be held at a steady voltage within the hysteresis window without substantially consuming or losing power. Moreover, essentially little or no current flows into the IMOD pixel if the applied voltage potential remains substantially fixed.

In some implementations, a frame of an image may be created by applying data signals in the form of “segment” voltages along the set of column electrodes, in accordance with the desired change (if any) to the state of the pixels in a given row. Each row of the array can be addressed in turn, such that the frame is written one row at a time. To write the desired data to the pixels in a first row, segment voltages corresponding to the desired state of the pixels in the first row can be applied on the column electrodes, and a first row pulse in the form of a specific “common” voltage or signal can be applied to the first row electrode. The set of segment voltages can then be changed to correspond to the desired change (if any) to the state of the pixels in the second row, and a second common voltage can be applied to the second row electrode. In some implementations, the pixels in the first row are unaffected by the change in the segment voltages applied along the column electrodes, and remain in the state they were set to during the first common voltage row pulse. This process may be repeated for the entire series of rows, or alternatively, columns, in a sequential fashion to produce the image frame. The frames can be refreshed and/or updated with new image data by continually repeating this process at some desired number of frames per second.

The combination of segment and common signals applied across each pixel (that is, the potential difference across each pixel) determines the resulting state of each pixel. FIG. 4 shows an example of a table illustrating various states of an interferometric modulator when various common and segment voltages are applied. As will be readily understood by one having ordinary skill in the art, the “segment” voltages can be applied to either the column electrodes or the row electrodes, and the “common” voltages can be applied to the other of the column electrodes or the row electrodes.

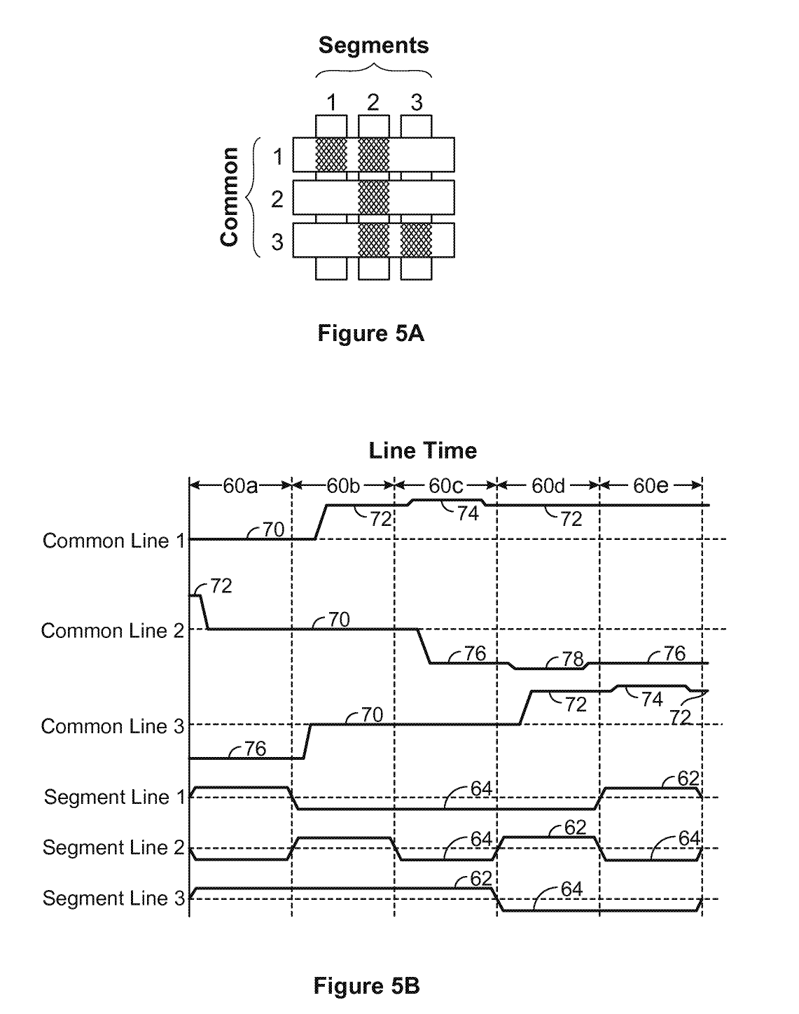

As illustrated in FIG. 4 (as well as in the timing diagram shown in FIG. 5B), when a release voltage VC_{REL} is applied along a common line, all interferometric modulator elements along the common line will be placed in a relaxed state, alternatively referred to as a released or unactuated state, regardless of the voltage applied along the segment lines, i.e., high segment voltage VS_{H} and low segment voltage VS_{L}. In particular, when the release voltage VC_{REL} is applied along a common line, the potential voltage across the modulator (alternatively referred to as a pixel voltage) is within the relaxation window (see FIG. 3, also referred to as a release window) both when the high segment voltage VS_{H} and the low segment voltage VS_{L} are applied along the corresponding segment line for that pixel.

When a hold voltage is applied on a common line, such as a high hold voltage VC_{HOLD}_{_{—}}_{H} or a low hold voltage VC_{HOLD}_{_{—}}_{L}, the state of the interferometric modulator will remain constant. For example, a relaxed IMOD will remain in a relaxed position, and an actuated IMOD will remain in an actuated position. The hold voltages can be selected such that the pixel voltage will remain within a stability window both when the high segment voltage VS_{H} and the low segment voltage VS_{L} are applied along the corresponding segment line. Thus, the segment voltage swing, i.e., the difference between the high VS_{H} and low segment voltage VS_{L}, is less than the width of either the positive or the negative stability window.

When an addressing, or actuation, voltage is applied on a common line, such as a high addressing voltage VC_{ADD}_{_{—}}_{H} or a low addressing voltage VC_{ADD}_{_{—}}_{L}, data can be selectively written to the modulators along that line by application of segment voltages along the respective segment lines. The segment voltages may be selected such that actuation is dependent upon the segment voltage applied. When an addressing voltage is applied along a common line, application of one segment voltage will result in a pixel voltage within a stability window, causing the pixel to remain unactuated. In contrast, application of the other segment voltage will result in a pixel voltage beyond the stability window, resulting in actuation of the pixel. The particular segment voltage which causes actuation can vary depending upon which addressing voltage is used. In some implementations, when the high addressing voltage VC_{ADD}_{_{—}}_{H} is applied along the common line, application of the high segment voltage VS_{H} can cause a modulator to remain in its current position, while application of the low segment voltage VS_{L} can cause actuation of the modulator. As a corollary, the effect of the segment voltages can be the opposite when a low addressing voltage VC_{ADD}_{_{—}}_{L} is applied, with high segment voltage VS_{H} causing actuation of the modulator, and low segment voltage VS_{L} having no effect (i.e., remaining stable) on the state of the modulator.

In some implementations, hold voltages, address voltages, and segment voltages may be used which produce the same polarity potential difference across the modulators. In some other implementations, signals can be used which alternate the polarity of the potential difference of the modulators. Alternation of the polarity across the modulators (that is, alternation of the polarity of write procedures) may reduce or inhibit charge accumulation which could occur after repeated write operations of a single polarity.

FIG. 5A shows an example of a diagram illustrating a frame of display data in the 3×3 interferometric modulator display of FIG. 2. FIG. 5B shows an example of a timing diagram for common and segment signals that may be used to write the frame of display data illustrated in FIG. 5A. The signals can be applied to the, e.g., 3×3 array of FIG. 2, which will ultimately result in the line time 60e display arrangement illustrated in FIG. 5A. The actuated modulators in FIG. 5A are in a dark-state, i.e., where a substantial portion of the reflected light is outside of the visible spectrum so as to result in a dark appearance to, e.g., a viewer. Prior to writing the frame illustrated in FIG. 5A, the pixels can be in any state, but the write procedure illustrated in the timing diagram of FIG. 5B presumes that each modulator has been released and resides in an unactuated state before the first line time 60a.

During the first line time 60a: a release voltage 70 is applied on common line 1; the voltage applied on common line 2 begins at a high hold voltage 72 and moves to a release voltage 70; and a low hold voltage 76 is applied along common line 3. Thus, the modulators (common 1, segment 1), (1,2) and (1,3) along common line 1 remain in a relaxed, or unactuated, state for the duration of the first line time 60a, the modulators (2,1), (2,2) and (2,3) along common line 2 will move to a relaxed state, and the modulators (3,1), (3,2) and (3,3) along common line 3 will remain in their previous state. With reference to FIG. 4, the segment voltages applied along segment lines 1, 2 and 3 will have no effect on the state of the interferometric modulators, as none of common lines 1, 2 or 3 are being exposed to voltage levels causing actuation during line time 60a (i.e., VC_{REL}-relax and VC_{HOLD}_{_{—}}_{L}-stable).

During the second line time 60b, the voltage on common line 1 moves to a high hold voltage 72, and all modulators along common line 1 remain in a relaxed state regardless of the segment voltage applied because no addressing, or actuation, voltage was applied on the common line 1. The modulators along common line 2 remain in a relaxed state due to the application of the release voltage 70, and the modulators (3,1), (3,2) and (3,3) along common line 3 will relax when the voltage along common line 3 moves to a release voltage 70.

During the third line time 60c, common line 1 is addressed by applying a high address voltage 74 on common line 1. Because a low segment voltage 64 is applied along segment lines 1 and 2 during the application of this address voltage, the pixel voltage across modulators (1,1) and (1,2) is greater than the high end of the positive stability window (i.e., the voltage differential exceeded a predefined threshold) of the modulators, and the modulators (1,1) and (1,2) are actuated. Conversely, because a high segment voltage 62 is applied along segment line 3, the pixel voltage across modulator (1,3) is less than that of modulators (1,1) and (1,2), and remains within the positive stability window of the modulator; modulator (1,3) thus remains relaxed. Also during line time 60c, the voltage along common line 2 decreases to a low hold voltage 76, and the voltage along common line 3 remains at a release voltage 70, leaving the modulators along common lines 2 and 3 in a relaxed position.

During the fourth line time 60d, the voltage on common line 1 returns to a high hold voltage 72, leaving the modulators along common line 1 in their respective addressed states. The voltage on common line 2 is decreased to a low address voltage 78. Because a high segment voltage 62 is applied along segment line 2, the pixel voltage across modulator (2,2) is below the lower end of the negative stability window of the modulator, causing the modulator (2,2) to actuate. Conversely, because a low segment voltage 64 is applied along segment lines 1 and 3, the modulators (2,1) and (2,3) remain in a relaxed position. The voltage on common line 3 increases to a high hold voltage 72, leaving the modulators along common line 3 in a relaxed state.

Finally, during the fifth line time 60e, the voltage on common line 1 remains at high hold voltage 72, and the voltage on common line 2 remains at a low hold voltage 76, leaving the modulators along common lines 1 and 2 in their respective addressed states. The voltage on common line 3 increases to a high address voltage 74 to address the modulators along common line 3. As a low segment voltage 64 is applied on segment lines 2 and 3, the modulators (3,2) and (3,3) actuate, while the high segment voltage 62 applied along segment line 1 causes modulator (3,1) to remain in a relaxed position. Thus, at the end of the fifth line time 60e, the 3×3 pixel array is in the state shown in FIG. 5A, and will remain in that state as long as the hold voltages are applied along the common lines, regardless of variations in the segment voltage which may occur when modulators along other common lines (not shown) are being addressed.

In the timing diagram of FIG. 5B, a given write procedure (i.e., line times 60a-60e) can include the use of either high hold and address voltages, or low hold and address voltages. Once the write procedure has been completed for a given common line (and the common voltage is set to the hold voltage having the same polarity as the actuation voltage), the pixel voltage remains within a given stability window, and does not pass through the relaxation window until a release voltage is applied on that common line. Furthermore, as each modulator is released as part of the write procedure prior to addressing the modulator, the actuation time of a modulator, rather than the release time, may determine the necessary line time. Specifically, in implementations in which the release time of a modulator is greater than the actuation time, the release voltage may be applied for longer than a single line time, as depicted in FIG. 5B. In some other implementations, voltages applied along common lines or segment lines may vary to account for variations in the actuation and release voltages of different modulators, such as modulators of different colors.

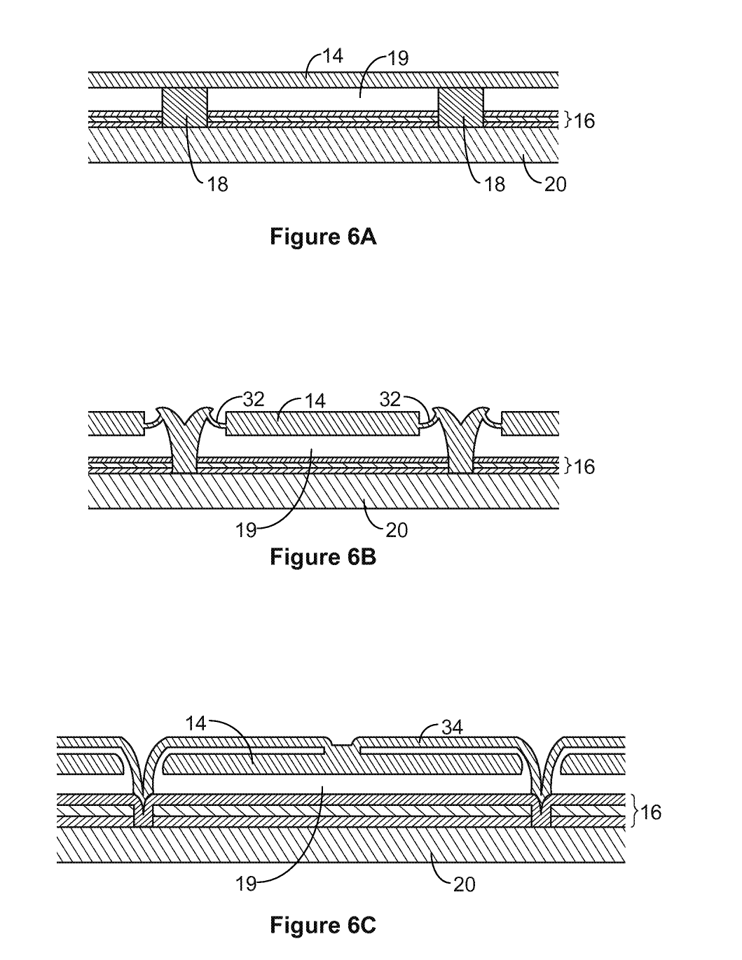

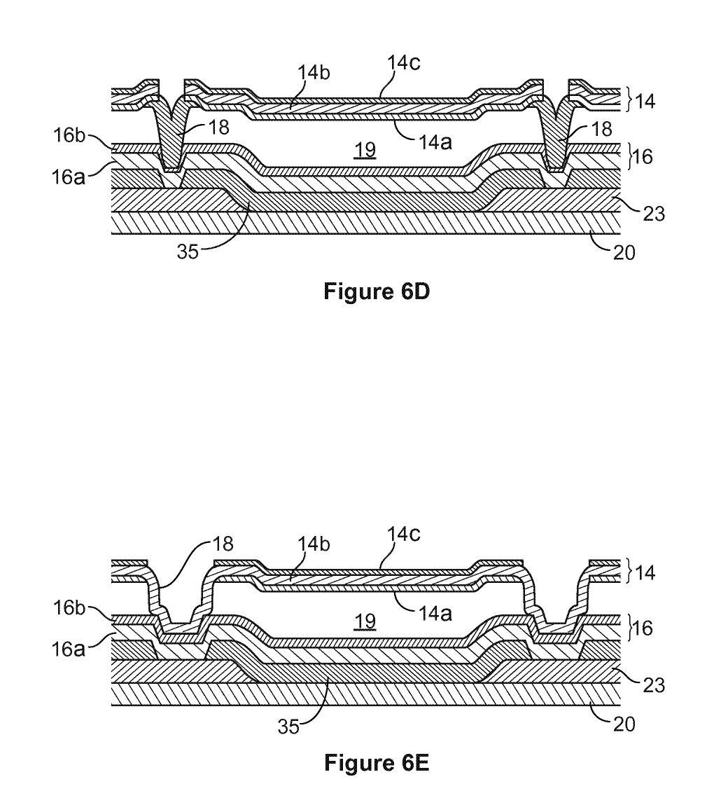

The details of the structure of interferometric modulators that operate in accordance with the principles set forth above may vary widely. For example, FIGS. 6A-6E show examples of cross-sections of varying implementations of interferometric modulators, including the movable reflective layer 14 and its supporting structures. FIG. 6A shows an example of a partial cross-section of the interferometric modulator display of FIG. 1, where a strip of metal material, i.e., the movable reflective layer 14 is deposited on supports 18 extending orthogonally from the substrate 20. In FIG. 6B, the movable reflective layer 14 of each IMOD is generally square or rectangular in shape and attached to supports at or near the corners, on tethers 32. In FIG. 6C, the movable reflective layer 14 is generally square or rectangular in shape and suspended from a deformable layer 34, which may include a flexible metal. The deformable layer 34 can connect, directly or indirectly, to the substrate 20 around the perimeter of the movable reflective layer 14. These connections are herein referred to as support posts. The implementation shown in FIG. 6C has additional benefits deriving from the decoupling of the optical functions of the movable reflective layer 14 from its mechanical functions, which are carried out by the deformable layer 34. This decoupling allows the structural design and materials used for the reflective layer 14 and those used for the deformable layer 34 to be optimized independently of one another.

FIG. 6D shows another example of an IMOD, where the movable reflective layer 14 includes a reflective sub-layer 14a. The movable reflective layer 14 rests on a support structure, such as support posts 18. The support posts 18 provide separation of the movable reflective layer 14 from the lower stationary electrode (i.e., part of the optical stack 16 in the illustrated IMOD) so that a gap 19 is formed between the movable reflective layer 14 and the optical stack 16, for example when the movable reflective layer 14 is in a relaxed position. The movable reflective layer 14 also can include a conductive layer 14c, which may be configured to serve as an electrode, and a support layer 14b. In this example, the conductive layer 14c is disposed on one side of the support layer 14b, distal from the substrate 20, and the reflective sub-layer 14a is disposed on the other side of the support layer 14b, proximal to the substrate 20. In some implementations, the reflective sub-layer 14a can be conductive and can be disposed between the support layer 14b and the optical stack 16. The support layer 14b can include one or more layers of a dielectric material, for example, silicon oxynitride (SiON) or silicon dioxide (SiO₂). In some implementations, the support layer 14b can be a stack of layers, such as, for example, a SiO₂/SiON/SiO₂ tri-layer stack. Either or both of the reflective sub-layer 14a and the conductive layer 14c can include, e.g., an aluminum (Al) alloy with about 0.5% copper (Cu), or another reflective metallic material. Employing conductive layers 14a, 14c above and below the dielectric support layer 14b can balance stresses and provide enhanced conduction. In some implementations, the reflective sub-layer 14a and the conductive layer 14c can be formed of different materials for a variety of design purposes, such as achieving specific stress profiles within the movable reflective layer 14.

As illustrated in FIG. 6D, some implementations also can include a black mask structure 23. The black mask structure 23 can be formed in optically inactive regions (e.g., between pixels or under posts 18) to absorb ambient or stray light. The black mask structure 23 also can improve the optical properties of a display device by inhibiting light from being reflected from or transmitted through inactive portions of the display, thereby increasing the contrast ratio. Additionally, the black mask structure 23 can be conductive and be configured to function as an electrical bussing layer. In some implementations, the row electrodes can be connected to the black mask structure 23 to reduce the resistance of the connected row electrode. The black mask structure 23 can be formed using a variety of methods, including deposition and patterning techniques. The black mask structure 23 can include one or more layers. For example, in some implementations, the black mask structure 23 includes a molybdenum-chromium (MoCr) layer that serves as an optical absorber, a SiO₂ layer, and an aluminum alloy that serves as a reflector and a bussing layer, with a thickness in the range of about 30-80 Å, 500-1000 Å, and 500-6000 Å, respectively. The one or more layers can be patterned using a variety of techniques, including photolithography and dry etching, including, for example, carbon tetrafluoride (CFO and/or oxygen (O₂) for the MoCr and SiO₂ layers and chlorine (Cl₂) and/or boron trichloride (BCl₃) for the aluminum alloy layer. In some implementations, the black mask 23 can be an etalon or interferometric stack structure. In such interferometric stack black mask structures 23, the conductive absorbers can be used to transmit or bus signals between lower, stationary electrodes in the optical stack 16 of each row or column. In some implementations, a spacer layer 35 can serve to generally electrically isolate the absorber layer 16a from the conductive layers in the black mask 23.

FIG. 6E shows another example of an IMOD, where the movable reflective layer 14 is self-supporting. In contrast with FIG. 6D, the implementation of FIG. 6E does not include support posts 18. Instead, the movable reflective layer 14 contacts the underlying optical stack 16 at multiple locations, and the curvature of the movable reflective layer 14 provides sufficient support that the movable reflective layer 14 returns to the unactuated position of FIG. 6E when the voltage across the interferometric modulator is insufficient to cause actuation. The optical stack 16, which may contain a plurality of several different layers, is shown here for clarity including an optical absorber 16a, and a dielectric 16b. In some implementations, the optical absorber 16a may serve both as a fixed electrode and as a partially reflective layer.

In implementations such as those shown in FIGS. 6A-6E, the IMODs function as direct-view devices, in which images are viewed from the front side of the transparent substrate 20, i.e., the side opposite to that upon which the modulator is arranged. In these implementations, the back portions of the device (that is, any portion of the display device behind the movable reflective layer 14, including, for example, the deformable layer 34 illustrated in FIG. 6C) can be configured and operated upon without impacting or negatively affecting the image quality of the display device, because the reflective layer 14 optically shields those portions of the device. For example, in some implementations a bus structure (not illustrated) can be included behind the movable reflective layer 14 which provides the ability to separate the optical properties of the modulator from the electromechanical properties of the modulator, such as voltage addressing and the movements that result from such addressing. Additionally, the implementations of FIGS. 6A-6E can simplify processing, such as, e.g., patterning.

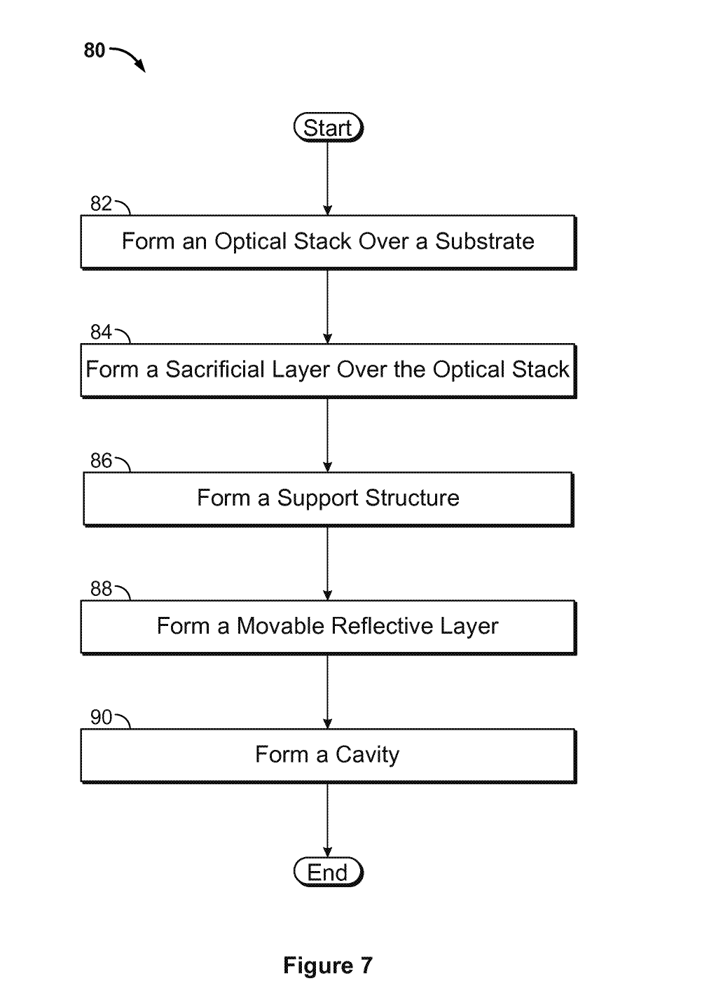

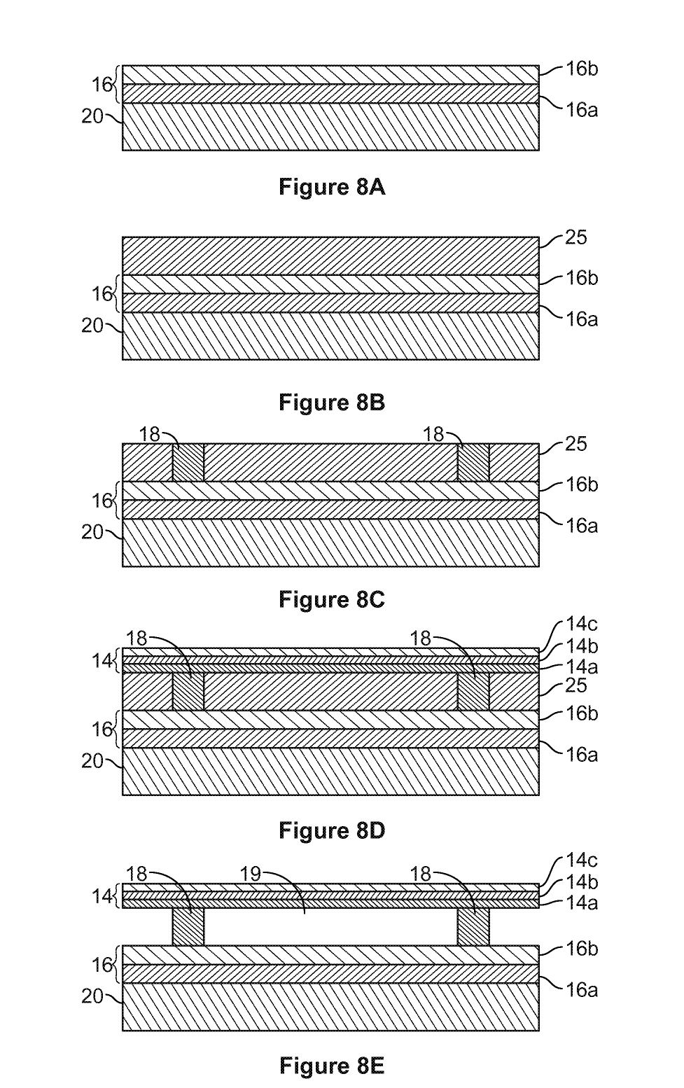

FIG. 7 shows an example of a flow diagram illustrating a manufacturing process 80 for an interferometric modulator, and FIGS. 8A-8E show examples of cross-sectional schematic illustrations of corresponding stages of such a manufacturing process 80. In some implementations, the manufacturing process 80 can be implemented to manufacture, e.g., interferometric modulators of the general type illustrated in FIGS. 1 and 6, in addition to other blocks not shown in FIG. 7. With reference to FIGS. 1, 6 and 7, the process 80 begins at block 82 with the formation of the optical stack 16 over the substrate 20. FIG. 8A illustrates such an optical stack 16 formed over the substrate 20. The substrate 20 may be a transparent substrate such as glass or plastic, it may be flexible or relatively stiff and unbending, and may have been subjected to prior preparation processes, e.g., cleaning, to facilitate efficient formation of the optical stack 16. As discussed above, the optical stack 16 can be electrically conductive, partially transparent and partially reflective and may be fabricated, for example, by depositing one or more layers having the desired properties onto the transparent substrate 20. In FIG. 8A, the optical stack 16 includes a multilayer structure having sub-layers 16a and 16b, although more or fewer sub-layers may be included in some other implementations. In some implementations, one of the sub-layers 16a, 16b can be configured with both optically absorptive and conductive properties, such as the combined conductor/absorber sub-layer 16a. Additionally, one or more of the sub-layers 16a, 16b can be patterned into parallel strips, and may form row electrodes in a display device. Such patterning can be performed by a masking and etching process or another suitable process known in the art. In some implementations, one of the sub-layers 16a, 16b can be an insulating or dielectric layer, such as sub-layer 16b that is deposited over one or more metal layers (e.g., one or more reflective and/or conductive layers). In addition, the optical stack 16 can be patterned into individual and parallel strips that form the rows of the display.

The process 80 continues at block 84 with the formation of a sacrificial layer 25 over the optical stack 16. The sacrificial layer 25 is later removed (e.g., at block 90) to form the cavity 19 and thus the sacrificial layer 25 is not shown in the resulting interferometric modulators 12 illustrated in FIG. 1. FIG. 8B illustrates a partially fabricated device including a sacrificial layer 25 formed over the optical stack 16. The formation of the sacrificial layer 25 over the optical stack 16 may include deposition of a xenon difluoride (XeF₂)-etchable material such as molybdenum (Mo) or amorphous silicon (Si), in a thickness selected to provide, after subsequent removal, a gap or cavity 19 (see also FIGS. 1 and 8E) having a desired design size. Deposition of the sacrificial material may be carried out using deposition techniques such as physical vapor deposition (PVD, e.g., sputtering), plasma-enhanced chemical vapor deposition (PECVD), thermal chemical vapor deposition (thermal CVD), or spin-coating.

The process 80 continues at block 86 with the formation of a support structure e.g., a post 18 as illustrated in FIGS. 1, 6 and 8C. The formation of the post 18 may include patterning the sacrificial layer 25 to form a support structure aperture, then depositing a material (e.g., a polymer or an inorganic material, e.g., silicon oxide) into the aperture to form the post 18, using a deposition method such as PVD, PECVD, thermal CVD, or spin-coating. In some implementations, the support structure aperture formed in the sacrificial layer can extend through both the sacrificial layer 25 and the optical stack 16 to the underlying substrate 20, so that the lower end of the post 18 contacts the substrate 20 as illustrated in FIG. 6A. Alternatively, as depicted in FIG. 8C, the aperture formed in the sacrificial layer 25 can extend through the sacrificial layer 25, but not through the optical stack 16. For example, FIG. 8E illustrates the lower ends of the support posts 18 in contact with an upper surface of the optical stack 16. The post 18, or other support structures, may be formed by depositing a layer of support structure material over the sacrificial layer 25 and patterning portions of the support structure material located away from apertures in the sacrificial layer 25. The support structures may be located within the apertures, as illustrated in FIG. 8C, but also can, at least partially, extend over a portion of the sacrificial layer 25. As noted above, the patterning of the sacrificial layer 25 and/or the support posts 18 can be performed by a patterning and etching process, but also may be performed by alternative etching methods.

The process 80 continues at block 88 with the formation of a movable reflective layer or membrane such as the movable reflective layer 14 illustrated in FIGS. 1, 6 and 8D. The movable reflective layer 14 may be formed by employing one or more deposition steps, e.g., reflective layer (e.g., aluminum, aluminum alloy) deposition, along with one or more patterning, masking, and/or etching steps. The movable reflective layer 14 can be electrically conductive, and referred to as an electrically conductive layer. In some implementations, the movable reflective layer 14 may include a plurality of sub-layers 14a, 14b, 14c as shown in FIG. 8D. In some implementations, one or more of the sub-layers, such as sub-layers 14a, 14c, may include highly reflective sub-layers selected for their optical properties, and another sub-layer 14b may include a mechanical sub-layer selected for its mechanical properties. Since the sacrificial layer 25 is still present in the partially fabricated interferometric modulator formed at block 88, the movable reflective layer 14 is typically not movable at this stage. A partially fabricated IMOD that contains a sacrificial layer 25 also may be referred to herein as an “unreleased” IMOD. As described above in connection with FIG. 1, the movable reflective layer 14 can be patterned into individual and parallel strips that form the columns of the display.

The process 80 continues at block 90 with the formation of a cavity, e.g., cavity 19 as illustrated in FIGS. 1, 6 and 8E. The cavity 19 may be formed by exposing the sacrificial material 25 (deposited at block 84) to an etchant. For example, an etchable sacrificial material such as Mo or amorphous Si may be removed by dry chemical etching, e.g., by exposing the sacrificial layer 25 to a gaseous or vaporous etchant, such as vapors derived from solid XeF₂ for a period of time that is effective to remove the desired amount of material, typically selectively removed relative to the structures surrounding the cavity 19. Other etching methods, e.g. wet etching and/or plasma etching, also may be used. Since the sacrificial layer 25 is removed during block 90, the movable reflective layer 14 is typically movable after this stage. After removal of the sacrificial material 25, the resulting fully or partially fabricated IMOD may be referred to herein as a “released” IMOD.

Implementations described herein relate to glass packaging of EMS devices, including IMODs, IC devices and other devices. In some implementations, a cover glass is sealed against a glass substrate, with an EMS and/or IC device situated between the glass substrate and cover glass. The sealed glass substrate and cover glass may provide the entire packaging for the device. The packaged devices can include dies embellished with leads and/or pads for connecting the device to another package, directly to a printed wiring board or flex tape, or for stacked or multi-substrate configurations. While implementations of the packages and methods of fabrication are described chiefly in the context of glass packaging of MEMS and IC devices, the packages and methods are not so limited and may be applied in other contexts.

As used herein, a glass package is a package including a cover glass attached to a glass substrate to encapsulate a device between the cover glass and the glass substrate. In some implementations, the glass packages described herein are all-glass packages, without any non-glass substrates or lids such as plastic, ceramic or metal substrates or lids, packaging the device. In some implementations, an all-glass package can encapsulate a separately packaged device, such as a silicon chip. In some implementations, the glass packages described herein are suitable for surface mounting and/or deployment in a consumer product without any overmolding or other further packaging.

Implementations described herein relate to glass packages including a glass substrate, a cover glass, and one or more devices encapsulated between the glass substrate and the cover glass, and one or more signal transmission pathways between an encapsulated device and the package exterior.

The glass packaging described herein can be used to package a variety of device sizes. For example, a packaged device can be 5 mm or less, 10 mm or less, and sometimes even greater than 10 mm. Glass packages encapsulating pressure sensors, gyroscopes, accelerometers, for example, may have length and width dimensions each less than 10 mm, or even less than 5 mm. A glass package including a display device, for example, device may have length and width dimensions of greater than about 10 mm.

In some implementations, a length of the cover glass may be about 1 to 10 mm, or about 1 to 5 mm, and a width of the cover glass may be about 1 to 10 mm, or about 1 to 5 mm. In various implementations, the cover glass is about 50 to 700 microns thick, about 100 to 300 microns thick, about 300 to 500 microns thick, or about 500 microns thick. The cover glass may be or include, for example, a borosilicate glass, a soda lime glass, quartz, Pyrex, or other suitable glass material. The cover glass may be transparent or non-transparent. For example, the cover glass may be frosted, painted, or otherwise made opaque.

In some implementations, a length of the glass substrate may be about 1 to 10 mm, or about 1 to 5 mm, and a width of the substrate may be about 1 to 10 mm, or about 1 to 5 mm. In various implementations, the glass substrate is about 100 to 700 microns thick, about 100 to 300 microns thick, about 300 to 500 microns thick, or about 500 microns thick. The glass substrate may be or include, for example, a borosilicate glass, a soda lime glass, quartz, Pyrex, or other suitable glass material. The glass substrate may be transparent or non-transparent. For example, the glass substrate may be frosted, painted, or otherwise made opaque.

In some implementations, the length and/or the width of the cover glass may be the same or approximately the same as the length and/or the width of the glass substrate. In some other implementations, the length and/or the width of the cover glass may be different than the length and/or the width of the glass substrate. For example, one or the other of the cover glass and glass substrate has a dimension larger than the corresponding dimension of the cover glass and glass substrate such that the glass package includes a ledge.

The cover glass and glass substrate each have surfaces that lie interior to the glass package and surfaces that lie exterior to the glass package. An interior surface of a cover glass can face an interior surface of a glass substrate. One or both of a cover glass and a glass substrate can include one or more recesses in an interior surface to accommodate one or more devices, such as an EMS and/or an integrated circuit device. An interior surface of a glass substrate can be joined to an interior surface of the cover glass. The cover glass and glass substrate can be joined with an interface such as an epoxy, a glass frit, or a metal. In some implementations, a joined cover glass and glass substrate forms a glass package to encapsulate a device.

A glass package can include one or more sides. In some implementations, a glass package includes a first surface that is an exterior surface of a cover glass, a second surface that is an exterior surface of a glass substrate, and one or more sides between the first and second surfaces.

A signal transmission pathway between one or more devices encapsulated in a glass package and an exterior of the package can provide a pathway for one or more of electrical, pressure, light, fluid, and thermal signals. For example, a signal transmission pathway for pressure can include a port in one or both of a cover glass or glass substrate. In another example, a signal transmission pathway for light can include a transparent region in one or both of a cover glass or glass substrate.

An electrical connection between a device and an exterior of a glass package encapsulating the device can include any electrical component, including conductive traces (also referred to as conductive lines or leads), conductive vias and conductive pads. Conductive traces can be formed on one or more surfaces of a cover glass and/or glass substrate, including on any interior, exterior or side surface. Conductive lines and vias can be formed in one or more of a cover glass and glass substrate. In some implementations, an electrical connection includes a through-glass via interconnect that extends from an interior surface of a cover glass to an exterior surface of the cover glass. In some implementations, an electrical connection includes a through-glass via that extends from an interior surface of a glass substrate to an exterior surface of the glass substrate.

Conductive pads, also referred to as bond pads or contact pads, can be formed on one or more surfaces of a cover glass and/or glass substrate, including on any interior, exterior or side surface. In some implementations, a glass-encapsulated device includes one or more conductive pads on an exterior surface to which a connection can be wire bonding, soldering, or flip-chip attached and that can be configured for connection to external components such as printed circuit boards (PCBs), ICs, passive components and the like. In some implementations, a glass package includes one or more conductive pads configured to provide a connection point for flex tape. A glass package can include one or more electrically inactive, or dummy, bond pads on an exterior surface that are configured to bond to dummy solder balls or other electrically inactive joints.

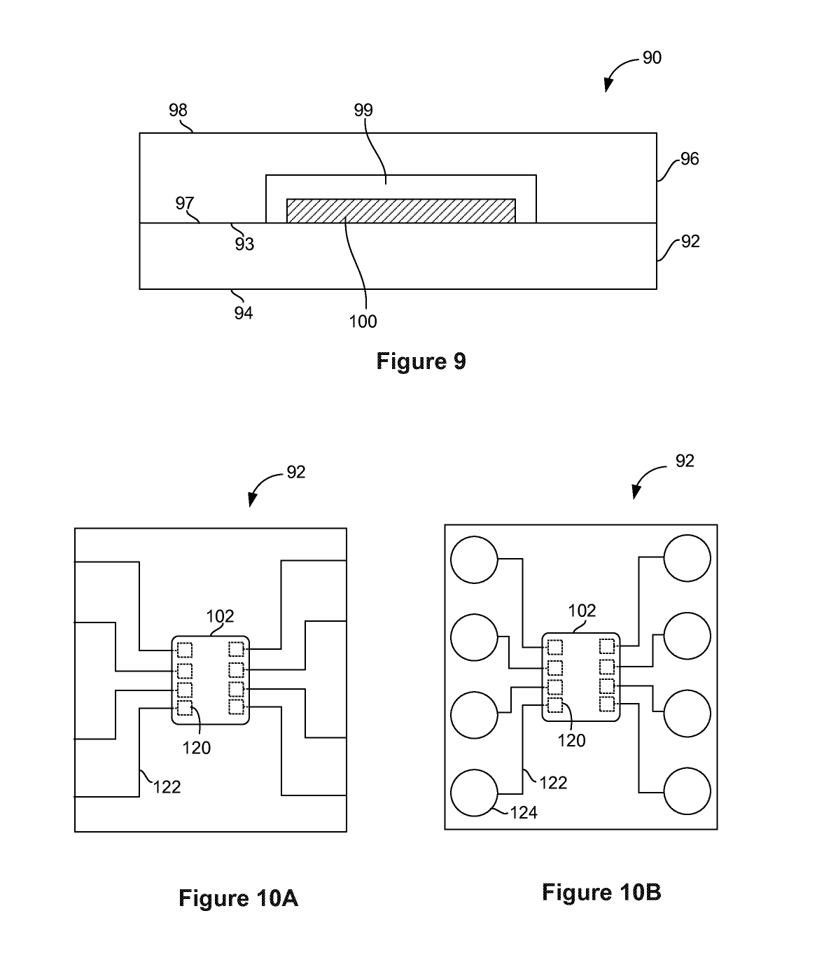

These and other aspects of glass packages and related fabrication methods are described below with reference to FIGS. 9-38.

FIG. 9 shows an example of a cross-sectional schematic illustration of a packaged device. In the example of FIG. 9, a glass package 90 includes a glass substrate 92 and a cover glass 96, with a device 100 disposed between glass substrate 92 and cover glass 96. In the example of FIG. 9, the glass substrate 92 includes opposing interior and exterior surfaces, interior surface 93 and exterior surface 94, and the cover glass 96 includes opposing interior and exterior surfaces, interior surface 97 and exterior surface 98. A recess 99 in the interior surface 97 of the cover glass 96 accommodates the device 100. The interior surface 93 of the glass substrate 92 can be sealed to the interior surface 97 of the cover glass 96. A seal between the glass substrate 92 and the cover glass 96 can be hermetic or non-hermetic according to the desired implementation. The glass package 90 also can include one or more electrical connections (not shown) from the device 100 to the package exterior. In some implementations, in addition to or instead of electrical connections, the glass package 90 can include a signal transmission pathway between the device 100 and an atmosphere outside the package 90 for other types of signals including, for example, pressure, light and thermal signals.

The device 100 can be any type of device, including any EMS device, such as a MEMS device, a nanoelectromechanical systems (NEMS) device, or an IC device. In some implementations, the device 100 can be a separate package, for example, a complementary metal oxide semiconductor (CMOS) device formed on a silicon substrate. In some implementations, the device 100 is formed on the interior surface 93 of the glass substrate 92. For example, the device 100 can be a MEMS device or an on-glass low-temperature-polycrystalline thin-film transistor (LTPS-TFT) fabricated on the interior surface 93 of the glass substrate 92. As described further below, in some implementations, the glass package 90 can include multiple devices 100, for example a MEMS device and an associated application specific integrated circuit (ASIC) device. In another example, the glass package 90 can include multiple EMS sensors, such as accelerometers, gyroscopes, pressure sensors, acoustic sensors and the like, and one or more ASIC devices. In some implementations, one or more devices 100 can be fabricated on or attached to the cover glass 96.

Each of the cover glass 96 and the glass substrate 92 can be or include, for example, a borosilicate glass, a soda lime glass, quartz, Pyrex, or other suitable glass material. In some implementations, the cover glass 96 is between 50 microns and 700 microns thick. The depth and area of the recess 99 is sufficient to accommodate the device 100 to be packaged. The device 100 can be of arbitrary thickness and area. For example, in some implementations, devices having thicknesses of about 1-300 microns and areas of 1 square micron to tens of square millimeters can be packaged. In some implementations, a depth of the recess 99 is between about 20 microns and 350 microns. The glass substrate 92 can be, for example, between 300 and 700 microns thick. An overall thickness of the glass package 90 can range, for example, from about 300-1,500 microns.

In some implementations, a glass package 90 is suitable for surface mounting, for example, on a PCB or other integration substrate. Due to the relative stiffness of glass, in some implementations the glass package 90 can isolate the packaged device 100 from stresses generated by the PCB better than plastic or other types of package materials. The glass package 90 also can protect the device 100 from harsh chemical environments better than plastic in some implementations. In some implementations, the glass substrate 92 or the cover glass 96 is a glass component of a display panel.

In some implementations, the glass substrate 92 includes electrical pads and associated routing on its interior surface 93. The device 100 can be connected to the electrical pads by any appropriate type of bond including a flip-chip bond, bump bond or wire bond.

FIGS. 10A and 10B show examples of schematic illustrations of a top view of an IC device on a glass substrate. In the examples of FIGS. 10A and 10B, a glass substrate 92 includes IC bond pads 120 and conductive traces 122 on an interior surface of the glass substrate 92. The IC bond pads 120 can be metalized areas to which connections can be made by techniques such as wire bonding, soldering, or flip-chip attachment. An IC device 102, which can be a CMOS device, is bonded to the IC bond pads 120, with conductive traces 122 providing electrical connection from bond pads 120 to the exterior of the package. In the example of FIG. 10A, the conductive traces 122 lead to an edge of glass substrate 92; in the example of FIG. 10B conductive traces 122 lead to through-glass via interconnects 124, which provide connection to the exterior of a glass package.

As used herein, an IC device is any integrated collection of one or more electrical components including transistors, resistors, capacitors and diodes. In some implementations, an IC device is fabricated as a separate chip, which can be attached to one or more of a glass substrate or a cover glass of a glass package described herein. Any appropriate IC technology can be used, examples of which include but are not limited to transistor-transistor logic (TTL), CMOS, bipolar complementary metal oxide semiconductor (BiCMOS), laterally diffused metal oxide semiconductor (LDMOS), metal-oxide-semiconductor field-effect transistor (MOSFET) and the like. An IC device chip included in a package described herein can be between 50 and 300 microns thick in some implementations.

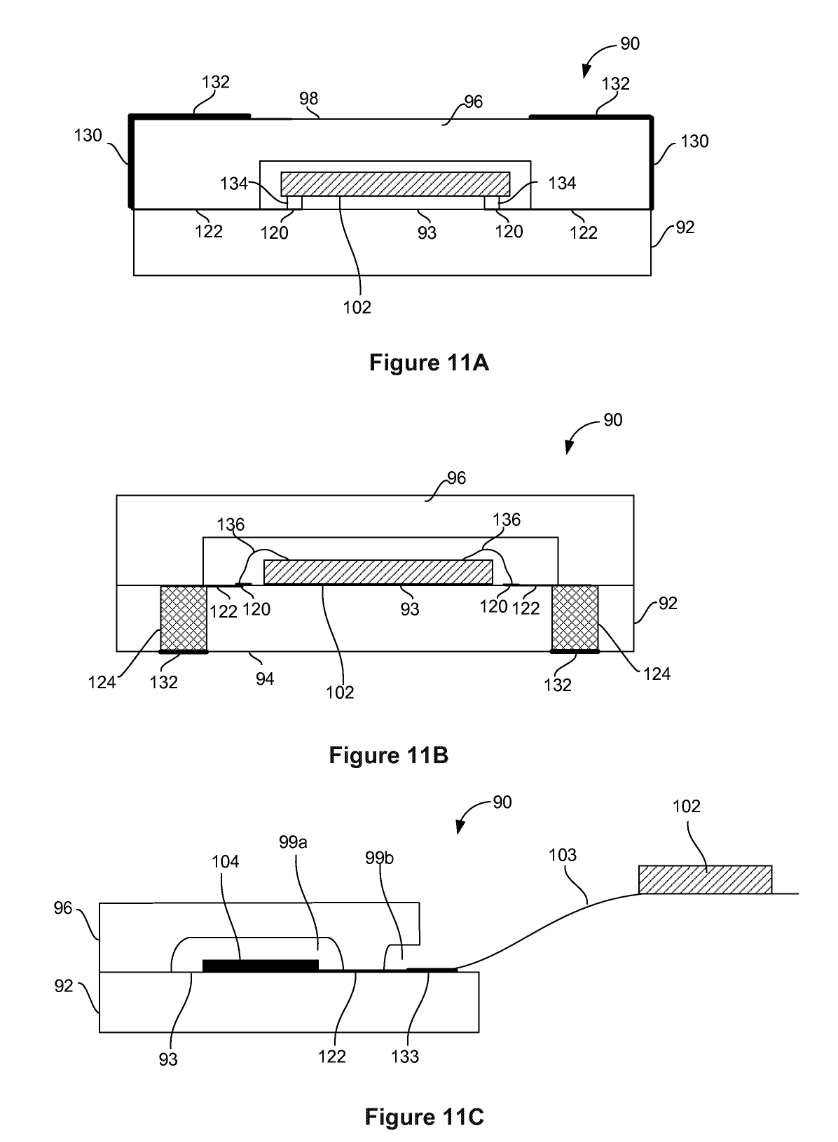

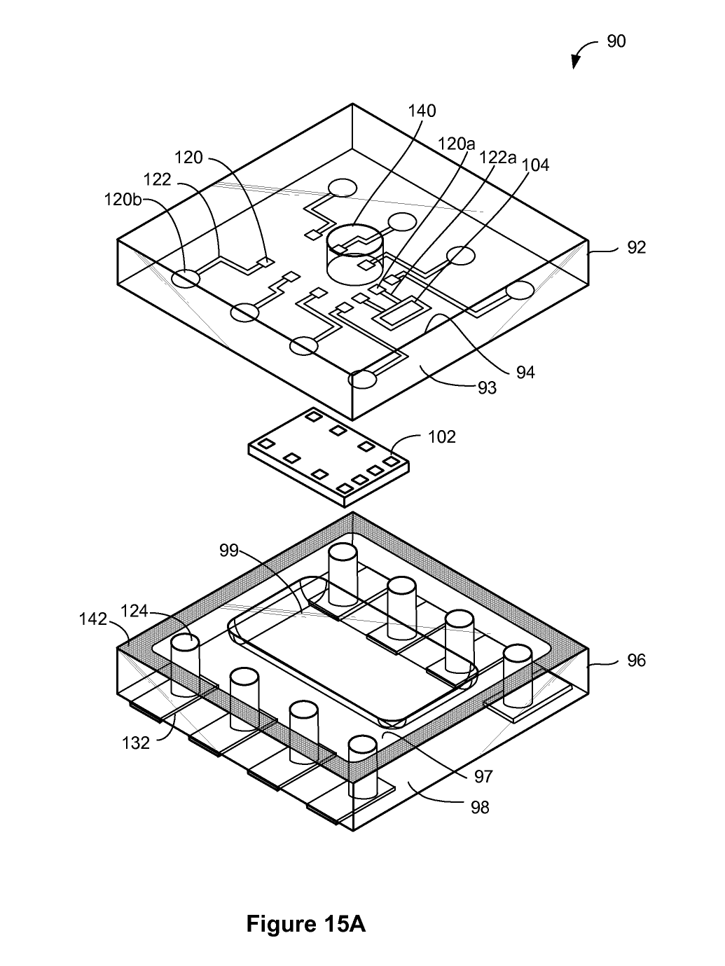

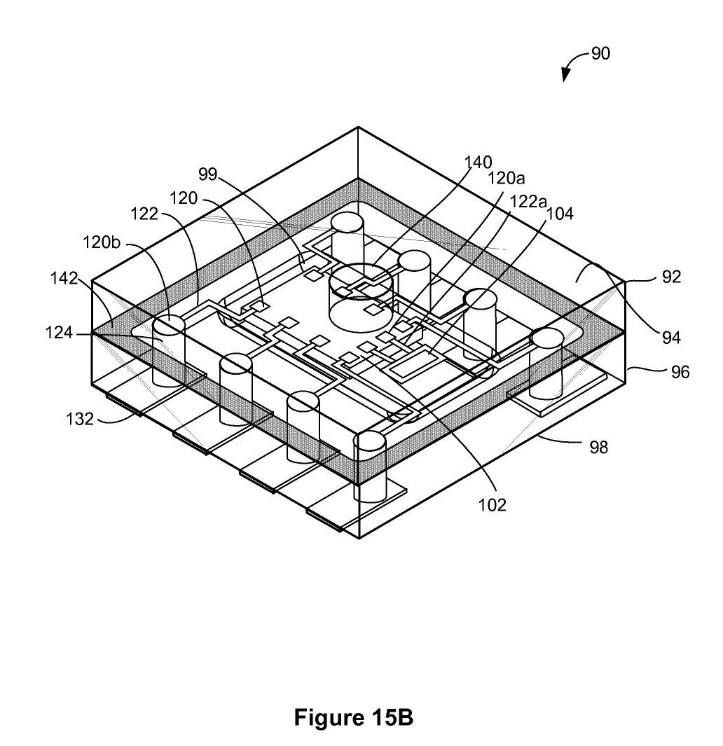

In some implementations, an electrical connection to a package exterior includes a connection to one or more bond pads or leads on an exterior surface of the package. Electrical connections to a package exterior can include any of plated, printed, screened, or dispensed conductive lines, and through-glass vias interconnects, including peripheral and non-peripheral through-glass via interconnects. An overview of various electrical connections are described below with respect to FIGS. 11A-11C, with further details discussed with respect to FIGS. 15A-25D.

FIGS. 11A and 11B show examples of cross-sectional schematic illustrations of a packaged integrated circuit (IC) device. FIG. 11C shows an example of a cross-sectional schematic illustration of a packaged MEMS device.

In the example of FIG. 11A, a glass package 90 includes an IC device 102 disposed between a glass substrate 92 and a cover glass 96. IC bond pads 120 and conductive traces 122 are on the interior surface 93 of the glass substrate 92. The IC device 102 is mechanically and electrically connected to the IC bond pads 120 by solder bonds 134. An underfill material (not depicted) may be disposed between the IC device 102 and the interior surface 93 of the glass substrate 92. The conductive traces 122 extend to the edge of the glass substrate 92, for example as depicted in FIG. 10A, and are connected to the conductive traces 130 that extend along side surfaces of the cover glass 96 to an exterior surface 98 of the cover glass 96. The conductive traces 130 connect to exterior pads 132 on the exterior surface 98 of the cover glass 96. The exterior pads 132 can be surface mount device (SMD) pads configured to connect to a PCB. In some implementations, the exterior pads 132 are configured for attachment to a “flex tape,” i.e., a tape or other flexible substrate material that supports one or more conductors and that provides electrical connection to one or more external electrical components such as ICs, PCBs and the like. In some implementations, an electrical connection is made between the IC device 102 and an exterior surface of the glass substrate 92, either in addition to or instead of the exterior surface 98 of the cover glass 96.

In some implementations, a glass package can include one or more through-glass via interconnects. In the example of FIG. 11B, a glass package 90 includes an IC device 102 disposed between a glass substrate 92 and a cover glass 96. IC bond pads 120 and conductive traces 122 are on an interior surface 93 of the glass substrate 92. The IC device 102 is electrically connected to the IC bond pads 120 by wire bonds 136. The conductive traces 122 are connected to through-glass via interconnects 124, which provide an electrical connection to exterior pads 132 on an exterior surface 94 of the glass substrate 92. The exterior pads 132 can be SMD pads configured to connect to a PCB or provide an electrical interface to a PCB or other device. The exterior pads 132 on the exterior surface 94 overlie the through-glass via interconnects 124 in the example of FIG. 11B. In alternate implementations (not shown), the exterior pads 132 on the exterior surface 94 are not directly aligned with the through-glass via interconnects 124 and can be electrically connected to the through-glass via interconnects 124 by conductive traces on the exterior surface 94. Also in the example of FIG. 11B, the through-glass via interconnects 124 extend through the glass substrate 92 to provide an electrical connection to the exterior surface 94 of the glass substrate 92; in alternate implementations (not shown) the cover glass 96 can include the through-glass via interconnects 124, either instead of or in addition to the through-glass via interconnects in the glass substrate 92.

In some implementations, a package is configured for attachment to a flexible connector, also referred to as a ribbon cable, a flexible flat cable, or a flex tape. For example, in some implementations, the exterior pads 132 depicted in FIGS. 11A and 11B can be configured for attachment to a flat flexible connector. In some implementations, a flat flexible connector attaches to the same surface of a glass substrate or cover glass on which a device is disposed. FIG. 11C shows an example of a glass package 90 attached to a flexible connector 103. The glass package 90 includes a MEMS device 104 encapsulated between a cover glass 96 and a glass substrate 92. The MEMS device 104 is formed on an interior surface 93 of the glass substrate 92, as are flex-attach pads 133, which are conductive pads configured to connect to the flexible connector 103. The cover glass 96 includes recesses 99a and 99b, with the MEMS device 104 disposed within a cavity formed by the recess 99a and the interior surface 93 and the flex-attach pads 133 disposed within an open cavity formed by the recess 99b and the interior surface 93. The MEMS device 104 is electrically connected to the flex-pads 133 by conductive traces 122. In the depicted implementation, an IC device 102 is connected to the flexible connector 103, such that the IC device 102 and the MEMS device 104 are electrically connected by the flat flexible connector, the flex-attach pads 133, and the conductive traces 122.

While FIGS. 11A-11C depict examples of electrical connections of a device to a package exterior, one having ordinary skill in the art will readily understand that any of the described features can be combined in any suitable combination or subcombination according to the desired implementation. Further details of implementations of electrical connections from a device to a package exterior are given further below with respect to FIGS. 15A-25D, including details of through-glass via interconnects and flexible connectors.

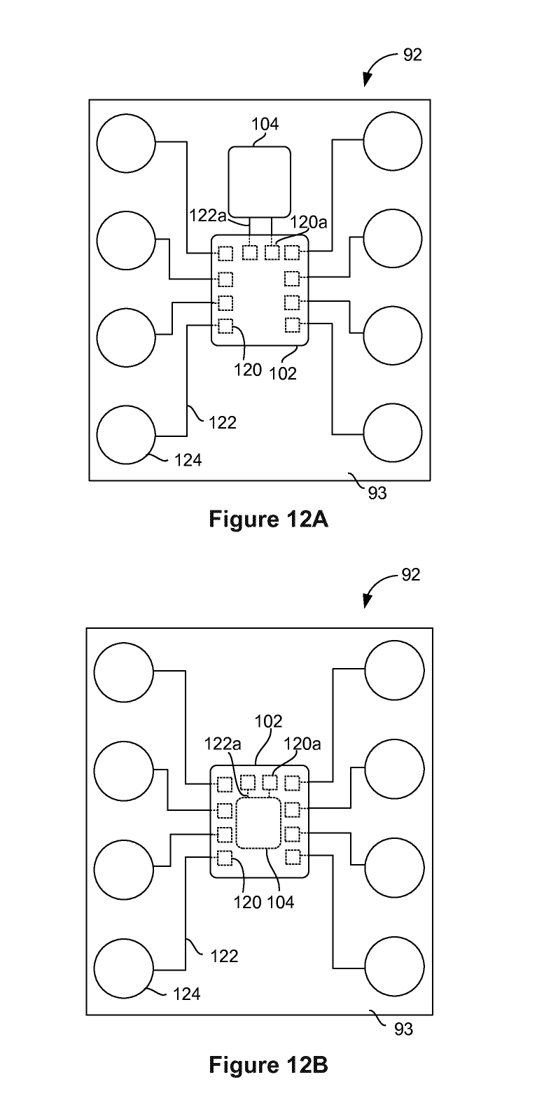

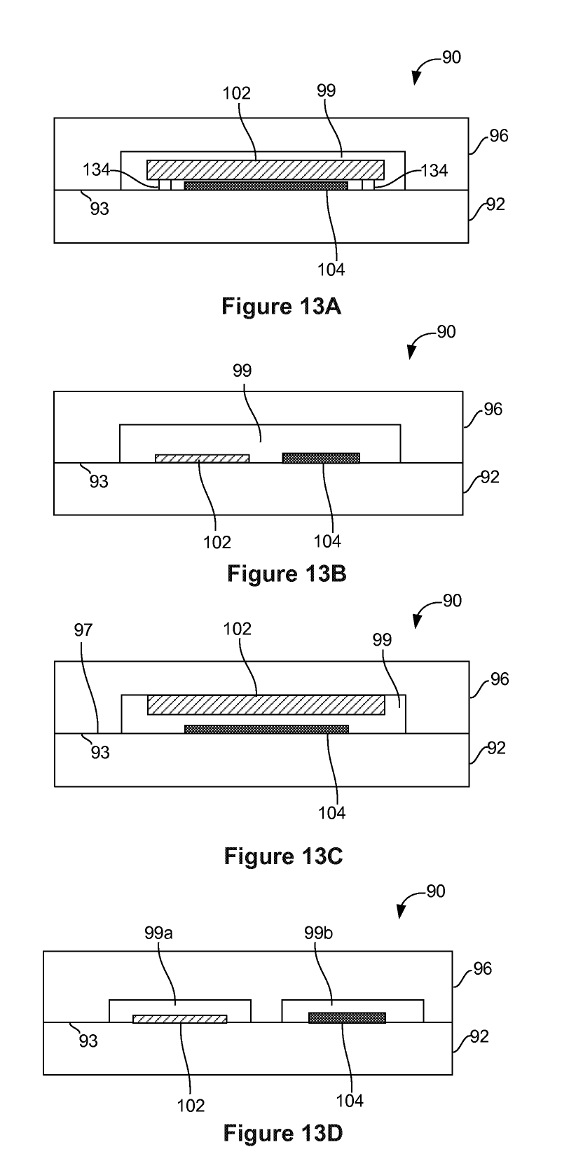

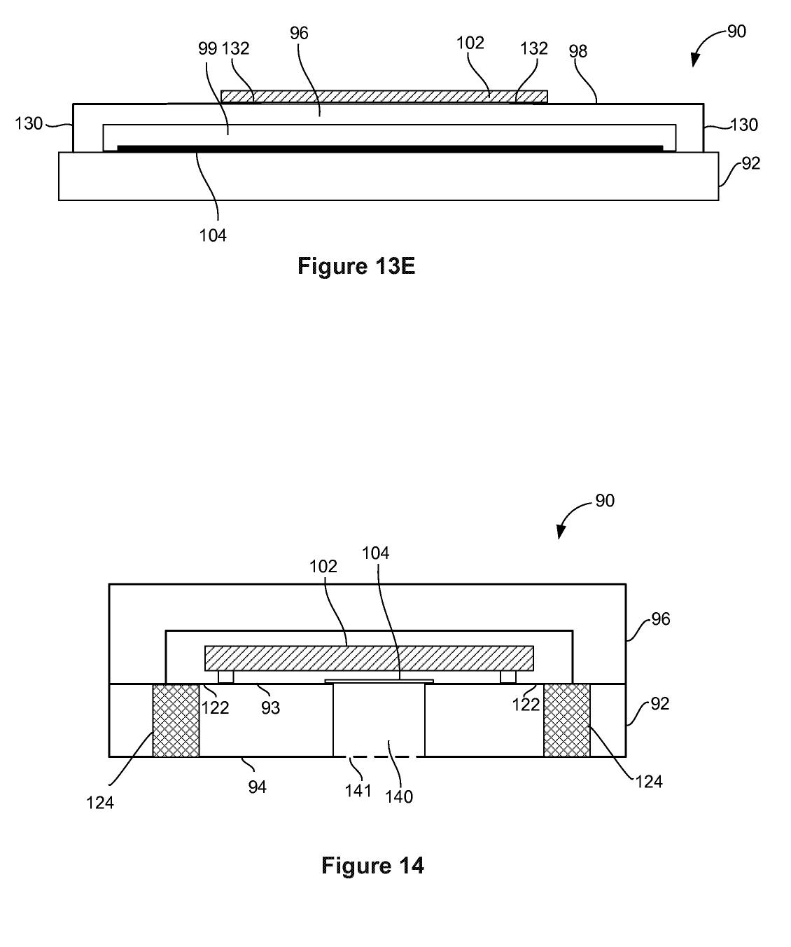

As indicated above, in some implementations, a glass package includes multiple devices. For example, a glass package can include a MEMS sensor and an associated ASIC configured to process signals from the sensor. In some implementations, a MEMS device is formed on an interior surface of a glass substrate. FIGS. 12A and 12B show examples of schematic illustrations of a top view of an IC device and a MEMS device on a glass substrate. In the examples of FIGS. 12A and 12B, a MEMS device 104 is fabricated on an interior surface 93 of a glass substrate 92. One or more conductive traces 122a electrically connect the MEMS device 104 to one or more IC bond pads 120a. An IC device 102 overlies and can be bonded to the IC bond pads 120 and the IC bond pads 120a, with conductive traces 122 providing electrical connection from the IC bond pads 120 to through-glass via interconnects 124, which provide connection to the exterior of the package. A package including both the MEMS device 104 and the IC device 102 can have the devices positioned in any appropriate arrangement. In the example of FIG. 12A, the IC device 102 is adjacent to the MEMS device 104. In the example of FIG. 12B, the IC device 102 overlies the MEMS device 104. Further examples of arrangements of the MEMS device 104 and the IC device 102 are depicted in FIGS. 13A-13E, described below.

FIGS. 13A-13E show examples of cross-sectional schematic illustrations of glass packages including a MEMS device and an IC device. In each of FIGS. 13A-13D, a glass package 90 includes an IC device 102 and a MEMS device 104 encapsulated between a glass substrate 92 and a cover glass 96. In the example of FIG. 13E, discussed further below, a glass package 90 includes a MEMS device 104 encapsulated between a glass substrate 92 and a cover glass 96, with an IC device 102 attached on an exterior surface 98 of the cover glass 96.

In the example of FIG. 13A, the glass package 90 includes the IC device 102 overlying the MEMS device 104. The MEMS device 104 is fabricated on an interior surface 93 of the glass substrate 92, with the IC device 102 attached by solder bonds 134 to IC bond pads 120 on the interior surface 93. The cover glass 96 covers the MEMS device 104 and the IC device 102. The IC device 102 and the MEMS device 104 are accommodated in a cavity defined by a recess 99 in the cover glass 96 and the interior surface 93 of the glass substrate 92. In some implementations, the IC device 102 and the MEMS device 104 can be electrically interconnected, for example, by connection to common pads as depicted in FIGS. 12A and 12B, or by other appropriate connections. The glass package 90 also can include an electrical connection (not depicted) from one or both of the IC device 102 and the MEMS device 104 to the package exterior. Examples of electrical connections are described above with reference to FIGS. 11A-11C, with further description of implementations given below with respect to FIGS. 15A-25D. In the example of FIG. 13B, the IC device 102 is adjacent to the MEMS device 104. In some implementations, one or both of the IC device 102 and the MEMS device 104 are fabricated on the interior surface 93 of the glass substrate 92, and accommodated by a recess 99 in the cover glass 96. In some implementations, one or both of the IC device 102 and the MEMS device 104 are separately packaged and attached to the interior surface 93 of the glass substrate 92 by solder bonding (not depicted), wire bonding (not depicted), or other appropriate attachment. The glass package 90 also can include an electrical connection (not depicted) from one or both of the IC device 102 and the MEMS device 104 to the package exterior.

In some implementations, one or more devices can be fabricated on or attached to the cover glass 96 of the glass package 90. In the example of FIG. 13C, the glass package 90 includes the IC device 102 on a surface of a recess 99 in an interior surface 97 of the cover glass 96. The IC device 102 can be attached to the surface of the recess 99 by solder bonds, wire bonds or other appropriate attachment technique, or be fabricated on the surface. The MEMS device 104 is on an interior surface 93 of the glass substrate 92. In some implementations, the IC device 102 and the MEMS device 104 can be electrically interconnected, for example, by connection to common pads or by other appropriate connection. The glass package 90 also can include an electrical connection (not depicted) from one or both of the IC device 102 and the MEMS device 104 to the package exterior. In the examples of FIGS. 13A-13C, the IC device 102 and the MEMS device 104 are housed within the recess 99 in the cover glass 96. In alternate implementations including multiple devices, the cover glass 96 can include multiple recesses isolating devices from each other. FIG. 13D shows an example of the glass package 90 including a recess 99a and a recess 99b formed in the cover glass 96. The IC device 102 can be disposed within a cavity defined by the recess 99a and an interior surface 93 of the glass substrate 92. The MEMS device 104 can be disposed within a cavity defined by the recess 99b and the interior surface 93 of glass substrate 92. In some implementations, the IC device 102 and the MEMS device 104 can be electrically interconnected, for example, by conductive traces (not shown) that extend between the cavities in which the devices are disposed.

In some implementations, the IC device 102 can be attached to an exterior surface of the cover glass 96 or the glass substrate 92 of the glass package 90. FIG. 13E shows an example of the IC device 102 attached to the glass package 90. The MEMS device 104 can be encapsulated between the cover glass 96 and the glass substrate 92, and connected by conductive traces 130 to exterior pads 132 on the exterior surface 98 of the cover glass 96. The IC device 102 can be attached to the exterior surface 98 of the cover glass 96 by solder bonds (not shown), and is electrically connected to conductive pads 132 on the exterior surface 98 such as by flip-chip bonding or wire bonding. The IC device 102 can be an ASIC configured to control the MEMS device 104.

In some implementations, a package includes a signal transmission pathway for non-electrical signals, such as acoustic, thermal and light signals. FIG. 14 shows an example of a cross-sectional schematic illustration of a glass package including a signal transmission pathway. In the example of FIG. 14, a glass package 90 includes an IC device 102 overlying a MEMS device 104. The IC device 102 is flip-chip attached to an interior surface 93 of a glass substrate 92. A port 140 in the glass substrate 92 provides an entrance for acoustic energy or another type of a signal. The MEMS device 104, which can be for example, a pressure sensor, a microphone, or a micro-speaker, is suspended over the port 140 on the interior surface 93. The MEMS device 104 can interact with an acoustic signal or other signal transmitted through the port 140, and/or generate a signal to be transmitted through the port 140. An exterior surface 94 of the glass substrate 92 can include multiple openings 141, which can be arranged as a grill, a grating or other pattern, into port 140. The glass package 90 also includes a signal transmission pathway for electrical signals, including conductive traces 122 and through-glass via interconnects 124.

Transmission pathways for electrical and non-electrical signals can be incorporated through, on, or around either or both of a cover glass and a glass substrate of a glass package according to the desired implementation. Placement of conductive traces, through-glass via interconnects, pads, or other components of an electrical pathway, and ports or other components of a non-electrical signal pathway can vary according to the desired implementation. In some implementations, for example, a port can be disposed above or adjacent to a MEMS device or other device to provide direct access between a package exterior and the device. In some implementations, for example, a port can be positioned such that access to a device is indirect, with one or more obstructions between the device and the package exterior. In some implementations, positioning of a port can be determined by considerations including a particular application of the packaged device, device sensitivity to a signal, and protecting a device and other internal components of a package from environmental materials or energies such as dirt, dicing fluid, light, thermal radiation, and the like.

In some implementations, through-glass via interconnects can be disposed in a cover glass, with one or more on-glass devices such as a MEMS device and/or on-glass low-temperature-polycrystalline thin-film transistor (LTPS-TFT) on a device substrate. This configuration can allow through-glass via interconnect fabrication to occur on a separate glass from MEMS and/or LTPS-TFT fabrication. In some implementations, through-glass vias interconnects can be disposed in a device substrate, with one or more on-glass devices such as a MEMS device and/or on-glass LTPS-TFT on a surface of the device substrate. This configuration can facilitate streamlined metallization operations, for example.

FIGS. 15A-17B show examples of schematic illustrations of exploded and isometric views of glass-encapsulated IC and MEMS devices including through-glass via interconnects and a port. First, FIGS. 15A and 15B show examples of an exploded view and an isometric view, respectively, of a glass package 90 including a cover glass 96, a glass substrate 92, an IC device 102 and a MEMS device 104. FIGS. 15A and 15B depict the package 90 with the glass substrate 92 on top and the cover glass 96 on bottom. The cover glass 96 includes an interior surface 97, an exterior surface 98, a recess 99 formed in the interior surface 97, and through-glass via interconnects 124. Exterior pads 132 on the exterior surface 98 provide an electrical interface for an external electrical connection.

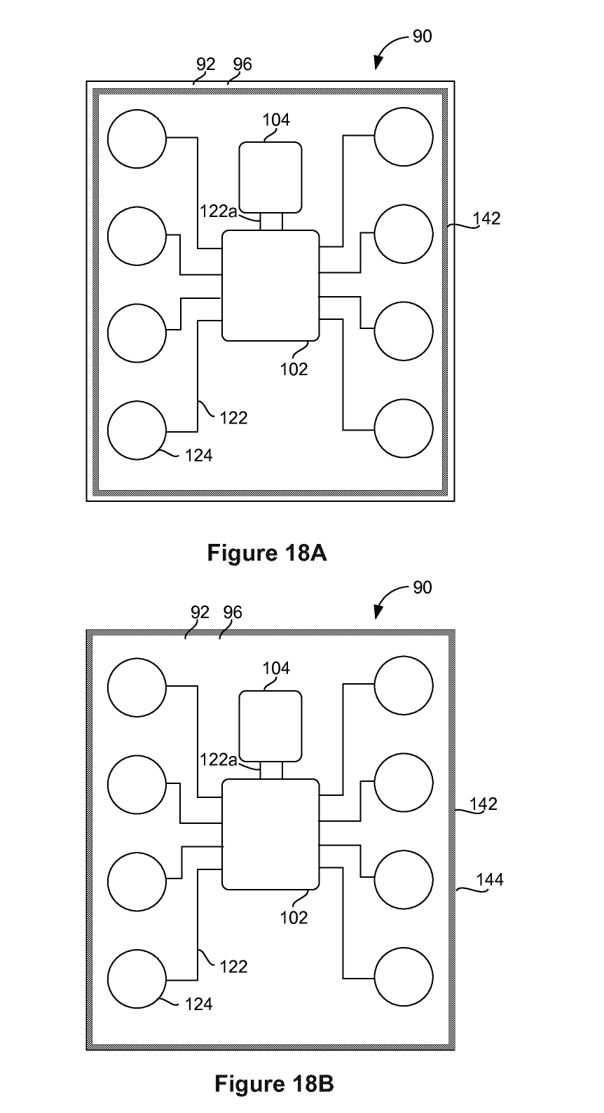

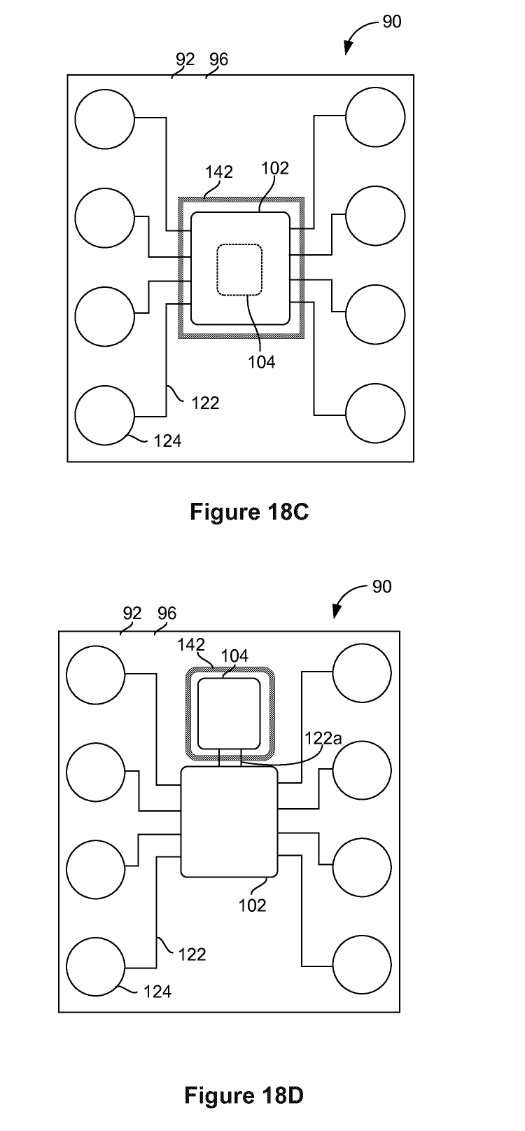

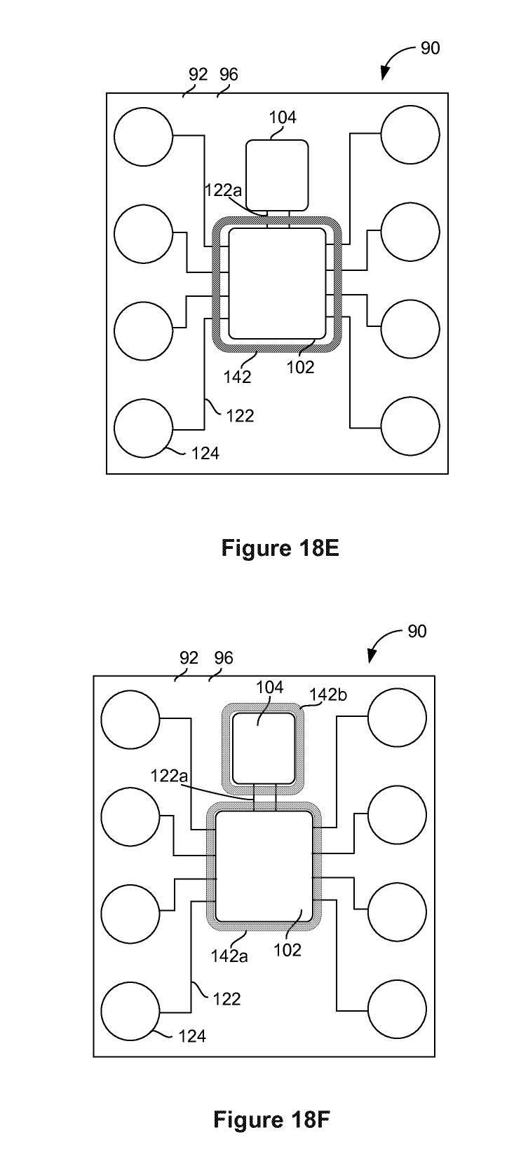

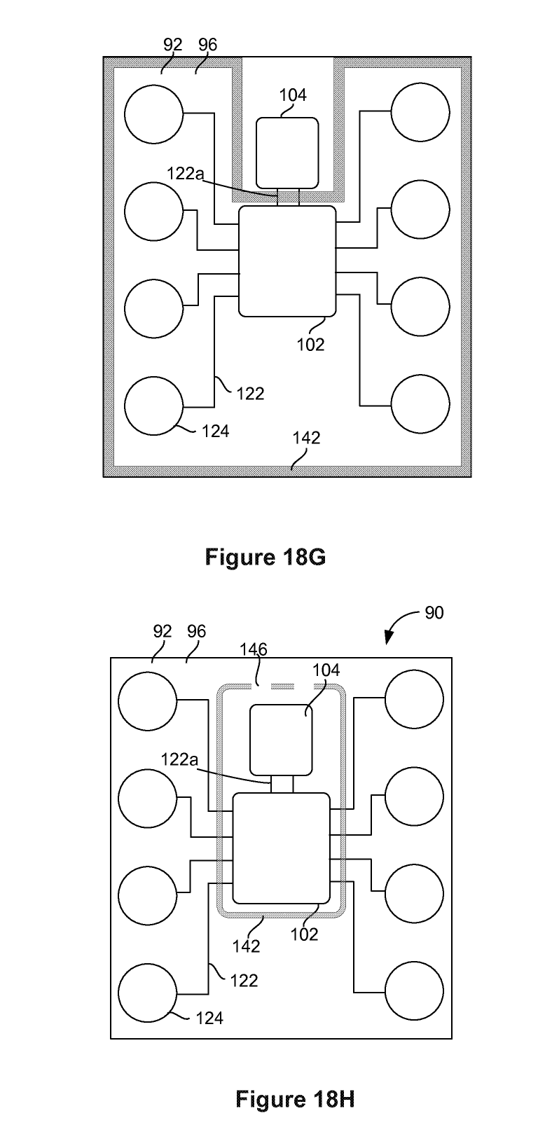

The glass substrate 92 includes an interior surface 93 and an exterior surface 94. A MEMS device 104, conductive traces 122 and 122a, IC bond pads 120 and 120a, and interconnect bond pads 120b are formed on the interior surface 93. The IC bond pads 120 and 120a provide a connection to the IC device 102, with conductive traces 122a electrically connecting the MEMS device 104 to the IC bond pads 120a, and the conductive traces 122 providing electrical connection from the IC bond pads 120 to interconnect bond pads 120b. Interconnect bond pads 120b provide a point of connection for the through-glass via interconnects 124 in the cover glass 96. The interconnect bond pads 120b and the through-glass via interconnects 124 can be joined by solder bonds or other appropriate type of bonds. In the example of FIGS. 15A and 15B, the glass substrate 92 includes a port 140 that provides a signal transmission pathway between the MEMS device 104 and the exterior of the glass package 90. A joining ring 142 surrounds the recess 99 and the through-glass via interconnects 124. The glass substrate 92 and the cover glass 96 are joined by a joining ring 142 and by bonds between the through-glass via interconnects 124 and the interconnect bond pads 120b. Further description of joining rings, including joining ring materials and placement is given below with respect to FIGS. 18A-18H.

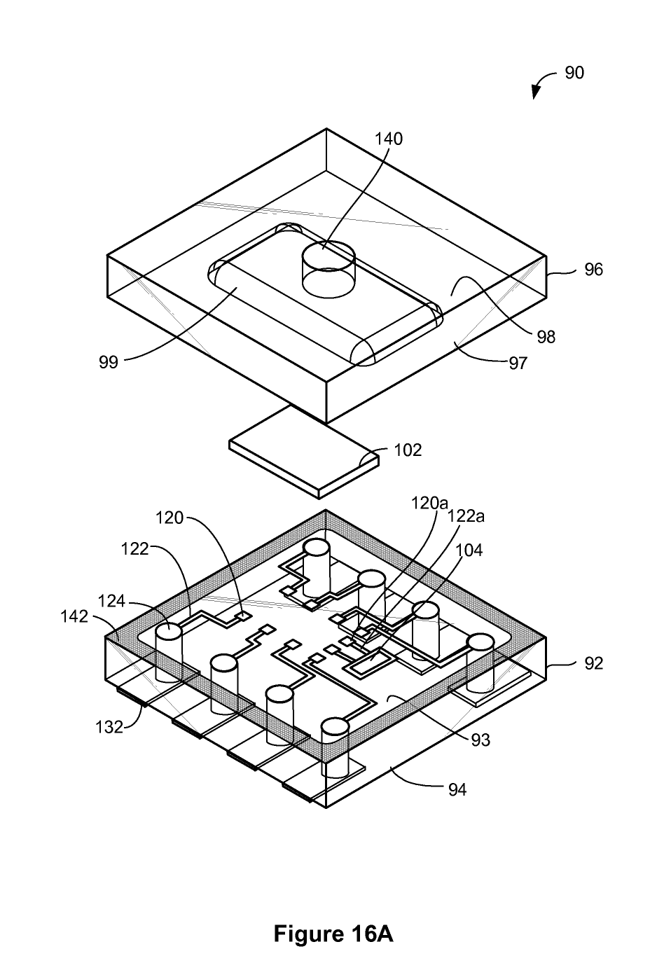

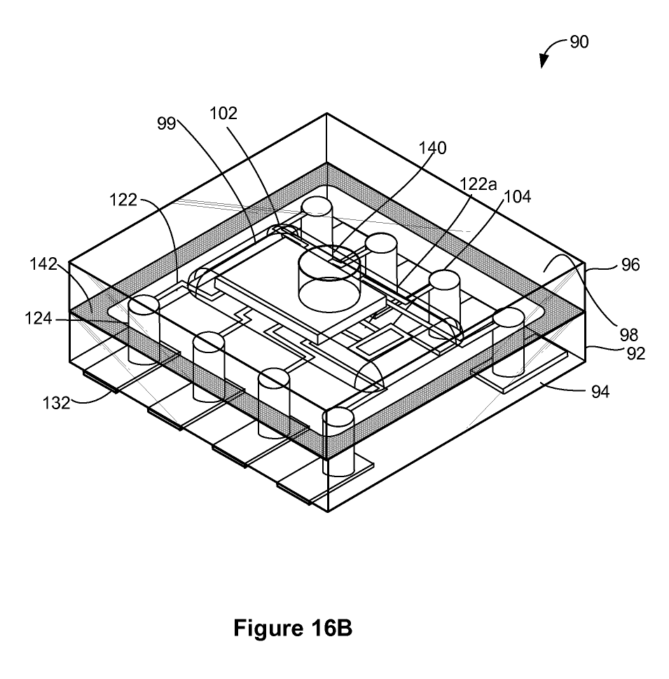

FIGS. 16A and 16B show examples of an exploded view and an isometric view, respectively, of a glass package 90 including a cover glass 96, a glass substrate 92, an IC device 102, and a MEMS device 104. FIGS. 16A and 16B depict the package 90 with the cover glass 96 on top and the glass substrate 92 on bottom. The cover glass 96 includes an interior surface 97, an exterior surface 98, a recess 99 formed in the interior surface 97, and through-glass via interconnects 124. In the example of FIGS. 16A and 16B, the cover glass 96 includes a port 140, but does not include any metallization for electrical connections. The port 140 opens into the recess 99 in the example of FIGS. 16A and 16B, though in some other implementations, it may be placed anywhere in the cover glass 96.

The glass substrate 92 includes an interior surface 93, an exterior surface 94, and through-glass via interconnects 124. A MEMS device 104, conductive traces 122 and 122a, and IC bond pads 120 and 120a are formed on the interior surface 93. IC bond pads 120 and 120a provide a connection to the IC device 102, with the conductive traces 122a electrically connecting the MEMS device 104 to the IC bond pads 120a, and the conductive traces 122 providing electrical connection from the IC bond pads 120 to the through-glass via interconnects 124. Exterior pads 132 on the exterior surface 94 connect to the through-glass via interconnects 124 and provide an electrical interface for an external electrical connection. A joining ring 142 surrounds the through-glass via interconnects 124. The joining ring 142 joins the glass substrate 92 and the cover glass 96, forming a hermetic or non-hermetic seal around the IC device 102 and the MEMS device 104.

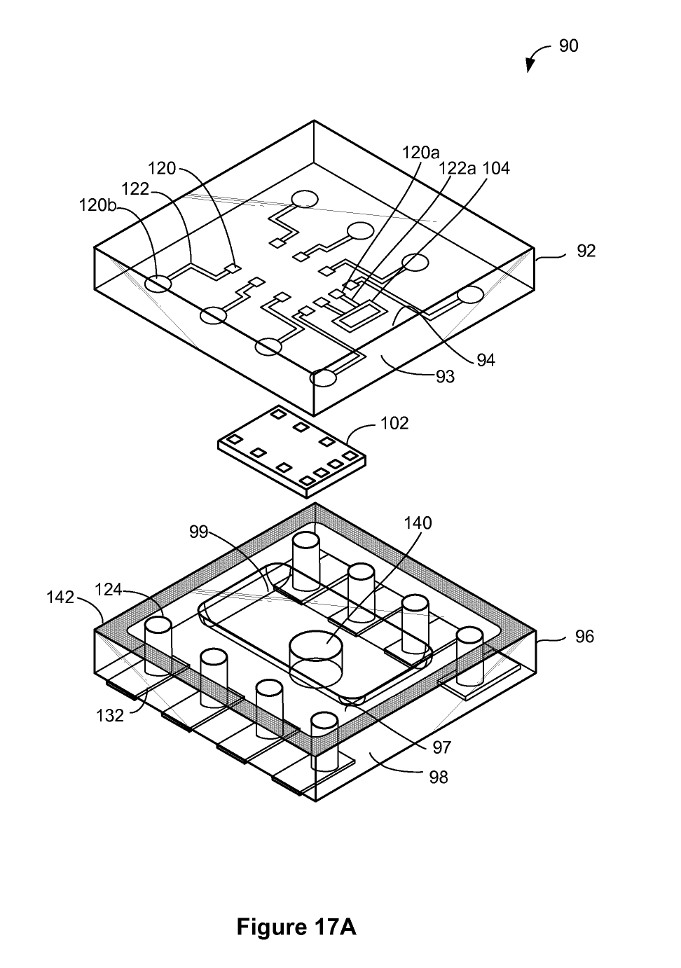

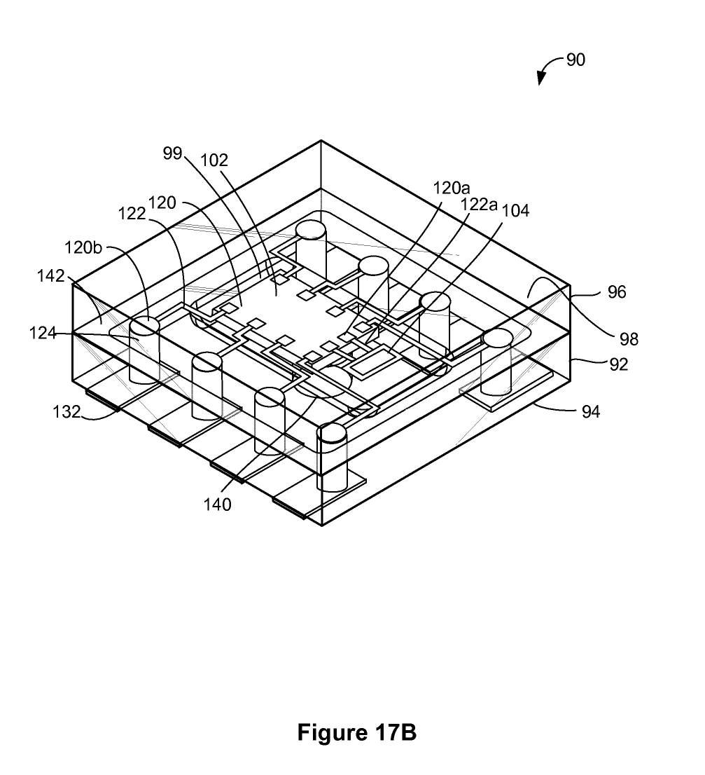

FIGS. 17A and 17B show examples of an exploded view and an isometric view, respectively, of a glass package 90 including a cover glass 96, a glass substrate 92, an IC device 102, and a MEMS device 104. FIGS. 17A and 17B depict the package 90 with the glass substrate 92 on top and the cover glass 96 on bottom. The cover glass 96 includes an interior surface 97, an exterior surface 98, a recess 99 formed in the interior surface 97, a port 140 providing a signal transmission pathway from the interior of glass package 90 to the exterior of glass package 90, and through-glass via interconnects 124. Exterior pads 132 on the exterior surface 98 provide an electrical interface for an external electrical connection. In the example of FIGS. 17A and 17B, the port 140 opens into the recess 99, though in some other implementations, it may be placed anywhere in the cover glass 96.

The glass substrate 92 includes an interior surface 93 and an exterior surface 94. A MEMS device 104, conductive traces 122 and 122a, IC bond pads 120 and 120a, and interconnect bond pads 120b are formed on the interior surface 93. The IC bond pads 120 and 120a provide a connection to the IC device 102, with the conductive traces 122a electrically connecting the MEMS device 104 to the IC bond pads 120a, and the conductive traces 122 providing electrical connection from the IC bond pads 120 to the interconnect bond pads 120b. The interconnect bond pads 120b provide a point of connection for the through-glass via interconnects 124 in the cover glass 96. The IC bond pads 120b and the through-glass via interconnects 124 can be joined by solder bonds or other appropriate type of bonds. A joining ring 142 surrounds the recess 99 and the through-glass via interconnects 124. The glass substrate 92 and the cover glass 96 are joined by the joining ring 142 as well as by bonds between the through-glass via interconnects 124 and the interconnect bond pads 120b.

In some implementations, a cover glass and a glass substrate can be sealed together using an intermediate material. For example, a cover glass and glass substrate can be sealed using an epoxy, including an ultraviolet (UV) curable epoxy or a heat-curable epoxy, a glass frit, or a metal. The intermediate material can contact an interior surface of a cover glass and an interior surface of a glass substrate to seal the cover glass and glass substrate together. In some implementations, a glass substrate, cover glass, or glass package includes one or more rings, referred to as bond rings or joining rings, of an epoxy, glass frit, or metal sealing material disposed between a cover glass and glass substrate. A joining ring can wholly or partially surround one or more of components of a partially or wholly fabricated package including one or more devices, recesses, or components of a conductive pathway. A joining ring can be shaped in any appropriate manner with example shapes including circles, ovals, rectangles, parallelograms and combinations thereof as well as irregular shapes. A joining ring can be continuous or can include breaks or other discontinuities according to the desired implementation. The joining ring can form a substantially hermetic seal or a non-hermetic seal according to the desired implementation. The term joining ring may be used to refer to a ring of sealing material formed on a cover glass or glass substrate prior to joining, as well as a ring of sealing material disposed between a cover glass and glass substrate after joining.

In some implementations, a joining ring includes an epoxy or other polymer adhesive. The width of an epoxy joining ring is sufficient to provide an adequate seal and can vary according to the desired implementation. In some implementations, a width of an epoxy joining ring is between about 50 microns and 1000 microns. In some implementations, an epoxy joining ring having a width of about 500 microns or greater provides a quasi-hermetic seal. In some other implementations, an epoxy joining ring provides a non-hermetic seal. A thickness of an epoxy joining ring can range from about 1-500 microns thick. In some implementations, a UV-curable or heat curable epoxy is used. Examples of UV-curable epoxies include XNR5570 and XNR5516 epoxies from Nagase ChemteX Corp., Osaka, Japan. An epoxy or other polymer adhesive can be screen printed or otherwise dispensed on one or both of a cover glass or glass substrate prior to joining the cover glass to the glass substrate. An epoxy seal can be formed when the cover glass and the glass substrate are then brought into contact and the epoxy is cured.

In some implementations, a joining ring includes a glass sealing material. In some implementations, a width of a glass joining ring is between about 20-500 microns. A thickness of a glass joining ring can range from about 0.1-100 microns thick. A glass joining ring can provide a hermetic seal or non-hermetic seal according to the desired implementation. A glass sealing material can be screen printed or otherwise dispensed on one or both of a cover glass or glass substrate prior to joining the cover glass to the glass substrate. A glass frit seal can be formed when the cover glass and the glass substrate are brought into contact under application of heat and/or pressure.

In some implementations, a joining ring includes a metal. A metal joining ring can be screen printed, plated or otherwise formed on a cover glass and glass substrate. Unlike epoxy and glass frit bonding, in which an epoxy or glass sealing material may be dispensed on only one of the glass substrate or cover glass prior to joining, corresponding metal joining rings are generally formed on each of the glass substrate and cover glass prior to joining to form a metal seal.

In some implementations, a joining ring includes a solderable metallurgy. Examples of solderable metallurgies include nickel/gold (Ni/Au), nickel/palladium (Ni/Pd), nickel/palladium/gold (Ni/Pd/Au), copper (Cu), palladium (Pd) and gold (Au). In some implementations, a joining ring includes a solder paste or preform. For example, a solder paste or preform can be printed on top of a joining ring including a solderable metallurgy.

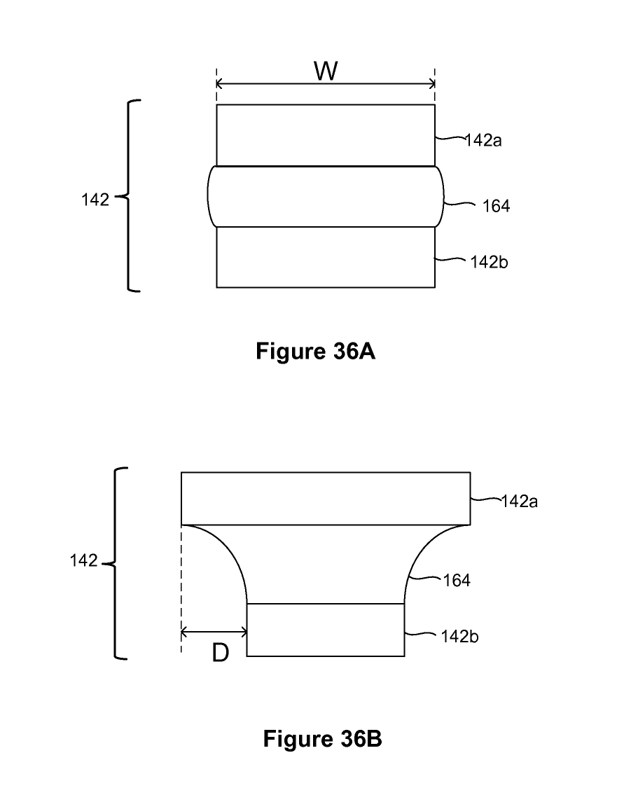

In some implementations, a joining ring includes a eutectic metallurgy. Examples of eutectic alloys that may be used include indium/bismuth (InBi), copper/tin (CuSn), copper/tin/bismuth (CuSnBi), copper/tin/indium (CuSnIn), and gold/tin (AuSn). The composition of a metal joining ring that seals two glass components together can depend on the particular metallurgical systems used for joining rings on the glass components and the particular joining process used according to the desired implementation. Further description of metal joining rings in glass-to-glass bonding is given below with respect to FIGS. 36A and 36B. In some implementations a metal joining ring between a cover glass and a glass substrate can be reinforced with epoxy or a polymer coating.

A joining ring can wholly or partially surround one or more of components of a glass package including one or more devices, recesses, or components of a conductive pathway. FIGS. 18A-18H show examples of schematic illustrations of top views of sealed glass packages. First, in FIG. 18A, a glass package 90, including an IC device 102 connected to a MEMS device 104 and associated electrical components, is shown. In the example of FIG. 18A, the electrical components include conductive traces 122 and 122a and through-glass via interconnects 124. For clarity, other components of the package 90, including any active or passive devices, or any conductive pads, non-electrical signal transmission pathways, and recesses as described above, are not shown. The IC device 102, the MEMS device 104 and the conductive traces 122 and 122a are encapsulated between a cover glass 96 overlying a glass substrate 92, with the through-glass via interconnects 124 extending through at least one of the glass substrate 92 and the cover glass 96 as described above with respect to FIGS. 15A-17B. In the example of FIG. 18A, a joining ring 142 extends continuously around the IC device 102, the MEMS device 104, the conductive traces 122 and 122a, and the through-glass via interconnects 124, near the periphery of the glass package 90. The joining ring 142 can be an epoxy, glass frit or metal ring, and can provide a hermetic or non-hermetic seal between the glass substrate 92 and the cover glass 96.

FIG. 18B shows a glass package 90 including a cover glass 96 sealed to a glass substrate 92 by a joining ring 142. In FIG. 18B, the joining ring 142 extends to a side edge 144 of the glass package 90, to surround the IC device 102, the MEMS device 104, the conductive traces 122 and 122a, and the through-glass via interconnects 124. In some implementations, forming the joining ring 142 that extends to a side edge 144 of the glass package 90 includes dicing through epoxy or other sealing material in a die singulation operation.

In some implementations, one or more components of a partially or wholly fabricated glass package including one or more devices, recesses, or components of a conductive pathway may be outside a joining ring of the glass package. FIG. 18C shows a glass package 90, including a cover glass 96 overlying a glass substrate 92, in which a joining ring 142 surrounds an IC device 102 and a MEMS device 104, with through-glass vias 124 outside of the joining ring 142. Conductive traces 122 traverse the joining ring 142. The conductive traces 122 can go under, above or through the joining ring 142. In implementations in which the joining ring 142 is a metal joining ring, the conductive traces 122 may be electrically insulated by a dielectric layer, such as an oxide or a nitride, to prevent shorting through the joining ring 142.

FIG. 18D shows a glass package 90, including a cover glass 96 overlying a glass substrate 92, and including a joining ring 142 that surrounds a MEMS device 104 but does not surround an IC device 102, conductive traces 122, or through-glass via interconnects 124. The conductive traces 122a traverse the joining ring 142. The conductive traces 122 can go under, above or through the joining ring 142. In implementations in which the joining ring 142 is a metal joining ring, the conductive traces 122a may be electrically insulated by a dielectric layer, such as an oxide or a nitride, to prevent shorting through the joining ring 142. In some implementations, the joining ring 142 provides a sealed mini-environment for the MEMS device 104. For example, a recess region (not shown) around the MEMS device 104 and within the joining ring 142 can include a vacuum or be at a prescribed pressure, including a sub-atmospheric pressure, an atmospheric pressure, or an above-atmospheric pressure, that differs from an ambient pressure. In some implementations, a mini-environment formed within the joining ring 142 can have a prescribed gas composition.

FIG. 18E shows a glass package 90, including a cover glass 96 overlying a glass substrate 92, and including a joining ring 142 that surrounds an IC device 102 but does not surround a MEMS device 104 or through-glass via interconnects 124. Conductive traces 122 and 122a traverse the joining ring 142 and can be insulated in implementations in which the joining ring 142 is a metal to prevent electrical shorting. In some implementations, the joining ring 142 provides a sealed mini-environment for the IC device 102. For example, a recess region (not shown) around the IC device 102 can include a vacuum or be at a prescribed pressure and gas composition. In some implementations, the joining ring 142 protects the IC device 102 from environmental conditions to which the MEMS device 104 is exposed. For example, in implementations in which a port (not shown) in the glass package 90 provides a signal transmission pathway between an exterior of the glass package 90 and the MEMS device 104, the joining ring 142 can prevent the IC device 102 from being exposed to exterior environmental conditions to which the MEMS device 104 is exposed.

FIG. 18F shows a glass package 90 that includes a cover glass 96 overlying a glass substrate 92. Separate joining rings 142a and 142b surround an IC device 102 and a MEMS device 104, respectively. In the depicted Figure, neither the joining ring 142a nor the joining ring 142b surrounds through-glass via interconnects 124. In some other implementations, one or both of the joining rings 142a and 142b can surround some or all of the through-glass via interconnects 124. The joining rings 142a and 142b can include the same or different sealing materials. For example, the joining rings 142a and 142b can each independently include glass, metal or epoxy sealing materials. Conductive traces 122a traverse the joining rings 142a and 142b and conductive traces 122 traverse the joining ring 142a. In implementations in which either or both of the joining ring 142a and joining ring 142b include metal, they can be insulated to prevent electrical shorting. In some implementations, one or both of the joining ring 142a and the joining ring 142b provides a sealed mini-environment for the IC device 102 and the MEMS device 104, respectively. A recess region (not shown) around the IC device 102 can include a vacuum, be at a prescribed pressure and/or include a prescribed gas composition. A separate recess region (not shown) around the MEMS device 104 can include a vacuum, be at a prescribed pressure and/or include a prescribed gas composition that is the same as or different from that of the recess region around the IC device 102.

FIG. 18G shows an example of a glass package 90 including a cover glass 96 overlying a glass substrate 92. In the depicted example, a joining ring 142 is disposed along a portion of the periphery of the glass package 90 and surrounds an IC device 102, conductive traces 122, and through-glass via interconnects 124. The joining ring 142 does not enclose a MEMS device 104 in the depicted implementation. In some other implementations, a separate joining ring can surround the MEMS device 104.

In some implementations, there can be one or more discontinuities in a joining ring. FIG. 18H shows an example of a glass package 90 including a cover glass 96 overlying a glass substrate 92. A joining ring 142, which surrounds an IC device 102, a MEMS device 104, and conductive traces 122a, is discontinuous having two slots 146. The slots 146 can, for example, permit access to the MEMS device 104. In some implementations, a signal transmission pathway between the MEMS device 104 and the exterior of the glass package 90 can include the slots 146. Conductive traces 122 traverse the joining ring 142, which can be electrically insulated in implementations in which it is a metal joining ring.

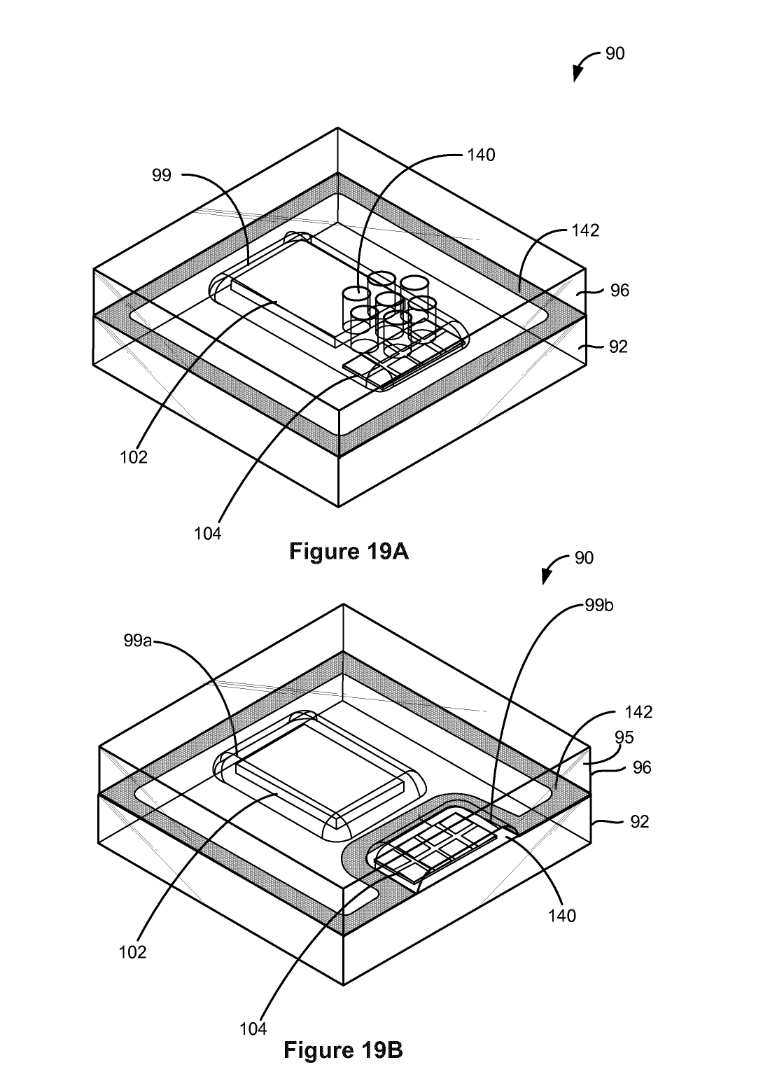

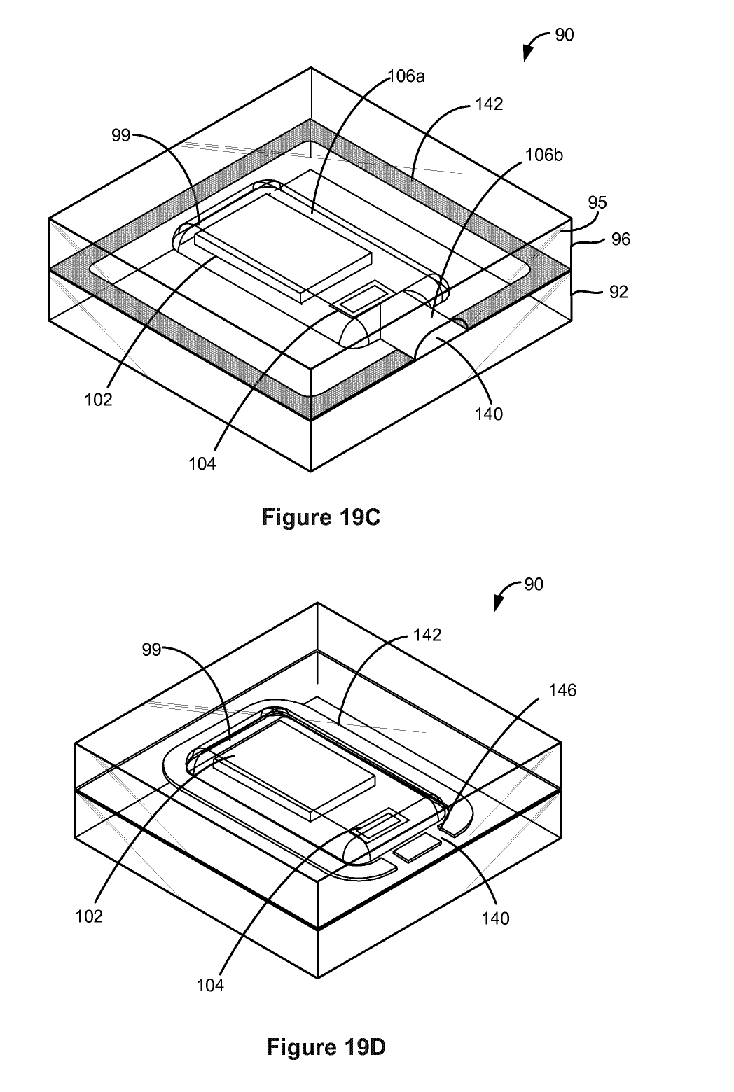

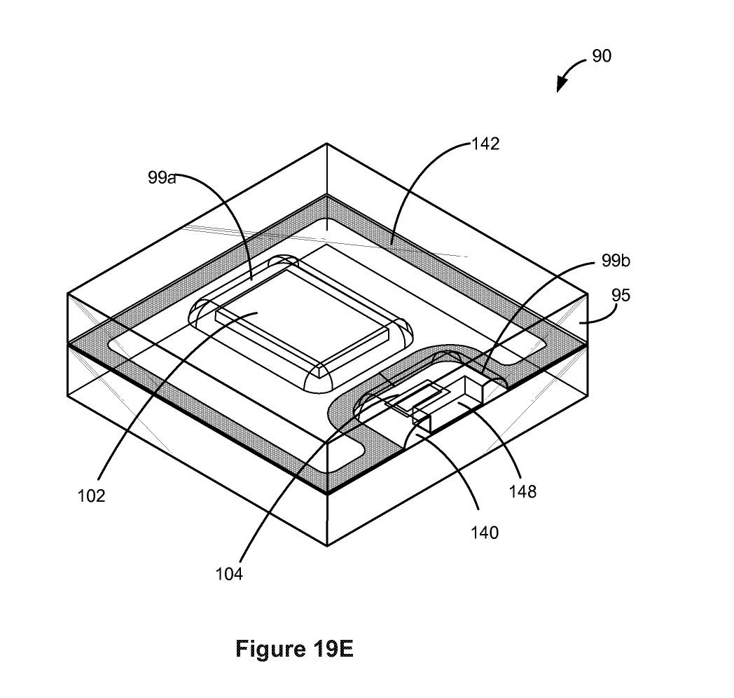

As indicated above, in some implementations, a glass package includes a signal transmission pathway between an encapsulated device and the package exterior. In some implementations, the signal transmission pathway provides fluid (i.e., gas and/or liquid) access between the package exterior and the device. For example, glass-encapsulated EMS devices including microphones, speakers and pressure sensors can include a pathway providing fluid access between the EMS device and the package exterior. Some examples of fluid access pathways are described above with respect to FIGS. 14-17B, with further examples described below with respect to FIGS. 19A-19E.

In some implementations, a package includes one or more holes extending through a cover glass or glass substrate to provide fluid access to a device. FIGS. 14, 15A and 15B, for example, show examples of the port 140 extending through the glass substrate 92 from the exterior surface 94 to the interior surface 93 and providing fluid access to and/or from the MEMS device 104, while FIGS. 16A-17B show examples of the port 140 extending through the cover glass 96 from the exterior surface 98 to the interior surface 97 and providing fluid access to and/or from the MEMS device 104. FIGS. 19A-19E show examples of schematic illustrations of isometric views of glass-encapsulated MEMS devices including fluid access to a MEMS device.

FIG. 19A shows an example of glass package 90 including a cover glass 96 sealed to a glass substrate 92 by a joining ring 142, with an IC device 102 and a MEMS device 104 encapsulated between the cover glass 96 and the glass substrate 92, within a recess 99 of the cover glass 96. The joining ring 142 extends around a periphery of the glass package 90. For clarity, other components of the package including electrical connections between the IC device 102 and the MEMS device 104 and to the exterior of the glass package 90 are not shown. An array of ports 140 extends through the cover glass 96 providing fluid access from the exterior of the glass package 90 to the MEMS device 104 such that a gas or liquid fluid can reach the device 104.

In some implementations, a recess in a cover glass or a glass substrate extends to a side edge of the cover glass or glass substrate to provide fluid access to a device accommodated by the recess. FIG. 19B shows an example of a glass package 90 including a cover glass 96 sealed to a glass substrate 92 by a joining ring 142, with an IC device 102 and a MEMS device 104 encapsulated between the cover glass 96 and the glass substrate 92. The IC device 102 is disposed within a recess 99a of the cover glass 96, with the MEMS device 104 disposed within a partially open recess 99b of the cover glass 96. For clarity, other components of the package including electrical connections between the IC device 102 and the MEMS device 104 and to the exterior of package 90 are not shown. The recess 99b extends to a side 95 of the glass package 90, providing a port 140 that allows fluid access between the MEMS device 104 and the exterior of the glass package 90. The joining ring 142 extends around a portion of the periphery of the glass package 90 and extends around the recess 99b to fully surround the IC device 102 and partially surround the MEMS device 104. The joining ring 142 isolates the IC device 102 from the fluid pathway provided by the port 140.

FIG. 19C shows an example of a glass package 90 including a cover glass 96 sealed to a glass substrate 92 by a joining ring 142, with an IC device 102 and a MEMS device 104 encapsulated between the cover glass 96 and the glass substrate 92. The IC device 102 and MEMS device 104 are disposed within a recess 99 of the cover glass 96. For clarity, other components of the package including electrical connections between the IC device 102 and the MEMS device 104 and to the exterior of package 90 are not shown. The recess 99 includes a main portion 106a to accommodate the IC device 102 and the MEMS device 104, and a narrowed portion 106b that extends to a side 95 of package 90, providing a port 140 that allows fluid access between the MEMS device 104 and the exterior of the glass package 90. The joining ring 142 in FIG. 19C is discontinuous, extending around most of the periphery of the glass package 90.

In some implementations, one or more slots in a joining ring can provide fluid access to a device. FIG. 19D shows an example of a glass package 90 including a cover glass 96 sealed to a glass substrate 92 by a joining ring 142, with an IC device 102 and a MEMS device 104 encapsulated between the cover glass 96 and the glass substrate 92. The IC device 102 and the MEMS device 104 are disposed within a recess 99 of the cover glass 96, with the joining ring 142 surrounding the recess 99. For clarity, other components of the package including electrical connections between the IC device 102 and the MEMS device 104 and to the exterior of package 90 are not shown. The joining ring 142 is discontinuous, with two slots 146 through the joining ring 142 defining a port 140 through which fluid can access the MEMS device 104.

In some implementations, fluid access can be partially obstructed, for example, to provide some protection for one or more devices in a glass package from dicing fluid, dirt, debris and other environmental conditions during fabrication or use. FIG. 19E shows an example of a glass package 90 including a cover glass 96 sealed to a glass substrate 92 by a joining ring 142, with an IC device 102 and a MEMS device 104 encapsulated between the cover glass 96 and the glass substrate 92. The IC device 102 is disposed within a recess 99a of the cover glass 96, with the MEMS device 104 disposed within a recess 99b of the cover glass 96. For clarity, other components of the package including electrical connections between the IC device 102 and the MEMS device 104 and to the exterior of the glass package 90 are not shown. The recess 99b extends to a side 95 of the glass package 90, providing a port 140 that allows fluid access between the MEMS device 104 and the exterior of the glass package 90. The joining ring 142 extends around a portion of the periphery of the glass package 90 as well as extending around the recess 99b to fully surround the IC device 102 and partially surround the MEMS device 104. The joining ring 142 isolates the IC device 102 from the fluid pathway provided by the port 140. The recess 99b includes a fence 148 at the side 95 of the glass package 90. The fence 148 sits between the MEMS device 104 and the side 95 of the glass package 90 and can provide some protection for the MEMS device 104 from dicing fluid, dirt, debris and other environmental conditions during fabrication or use.

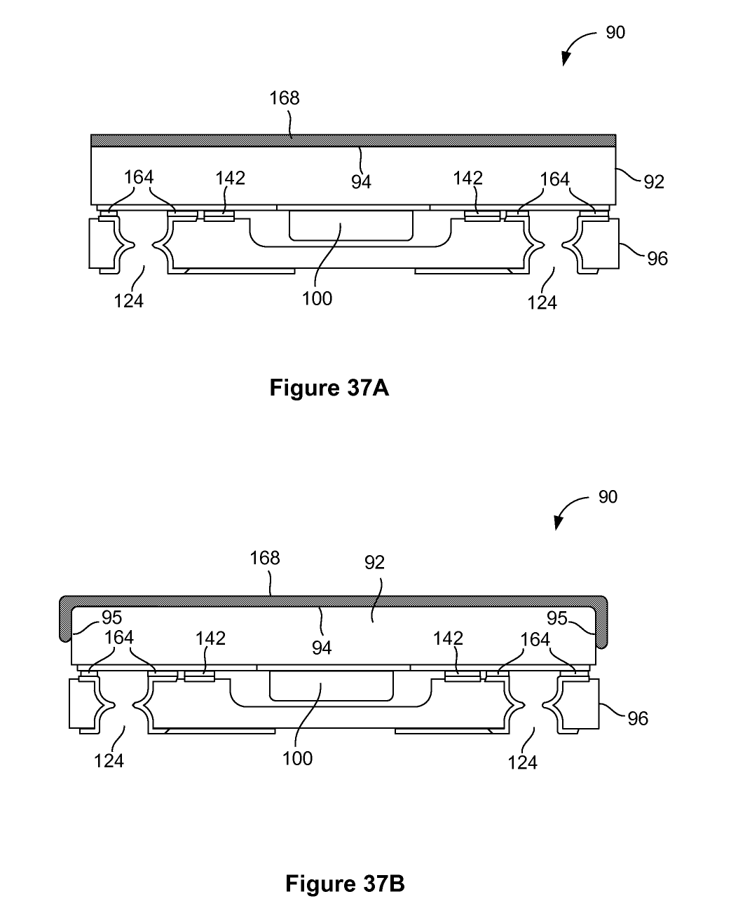

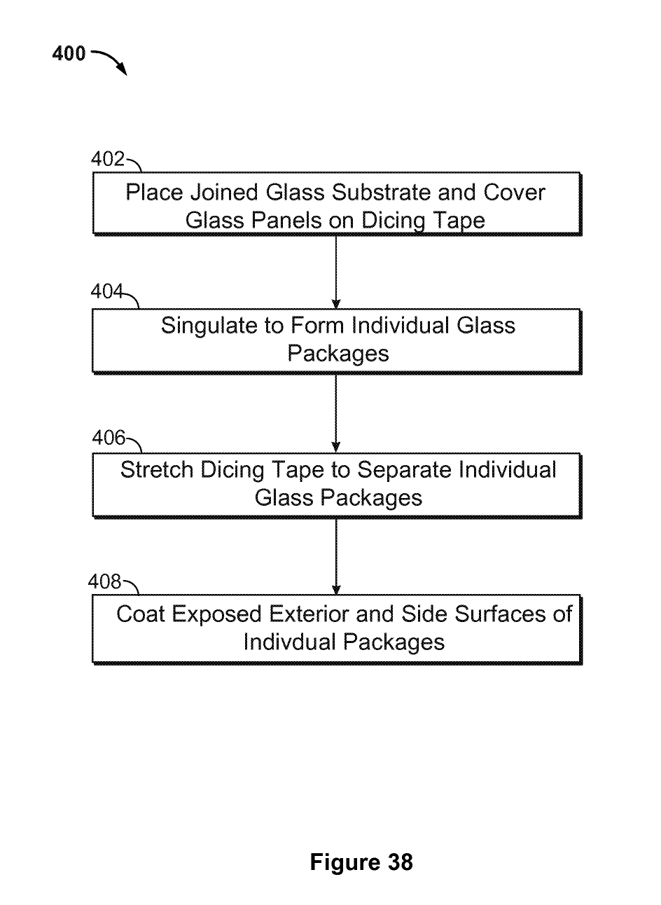

While FIGS. 19A-19E show examples of fluid access pathway, the glass packages described herein also can include other types of signal transmission pathways. For example, in some implementations, a signal transmission pathway is configured to transmit light. In some implementations, a light transmissive pathway can include an aperture through a glass substrate and/or a cover glass through which light can be transmitted. In some implementations, a light transmissive pathway can include a glass substrate and/or a cover glass having at least a region that is transparent at the desired wavelength or range of wavelengths. In some implementations, a glass substrate and/or a cover glass can be part of display panel. In some implementations, a glass substrate and/or a cover glass can include a polymer coating to tailor light transmission characteristics of the glass substrate and/or cover glass. Polymer coatings are discussed below with respect to FIGS. 37A-38.

In some implementations, a signal transmission pathway is configured to transmit thermal energy. In some implementations, a heat transmissive pathway can include a hole through a glass substrate and/or a cover glass through which heat can be transmitted. The hole can be unfilled or filled. In some implementations, the presence, absence and/or type of fill material can be selected to transmit thermal energy by one or more of conduction, convection and radiation according to the desired implementation. For example, in some implementations, a hole is filled with a thermally conductive material.

As indicated above, in some implementations, a glass package includes one or more electrical connections from a device encapsulated by the glass package to an exterior of the glass package. An electrical connection between a device and an exterior of a glass package can include any electrical component, including wire bonds, conductive traces, conductive vias and conductive pads. Conductive traces can be formed on any surface of a glass package, including any surface of a glass substrate and any surface of a cover glass. In some implementations, metals are used to form conductive traces. In some other implementations, conductive traces are formed using a non-metallic material such as a conductive polymer.

Examples of metals that can be used include copper (Cu), aluminum (Al), gold (Au), niobium (Nb), chromium (Cr), tantalum (Ta), nickel (Ni), tungsten (W), titanium (Ti), palladium (Pd), silver (Ag) and alloys and combinations thereof. Examples of plated metal layers include Cu, Cu/Ni/Au, Cu/Ni/Pd/Au, Ni/Au, Ni/Pd/Au, Ni alloy/Pd/Au, and Ni alloy/Au. In some implementations, a conductive trace includes a bilayer of a main conductive layer overlying an adhesion layer. Examples of adhesion layers include chromium (Cr), titanium (Ti), and niobium (Nb). Examples of bilayers include Cr/Cu, Cr/Au and Ti/W. Adhesion layers may have thicknesses of a few nanometers to several hundred nanometers or more. The thickness of a conductive trace, including an adhesion layer if present, can be between about 1,000 Angstroms (Å) and 10,000 Å according the desired implementation. A width of a conductive trace can vary, for example, from less than 10 microns wide to over 100 microns wide. In various implementations, spaces between adjacent conductive traces can vary from less than 10 microns to 500 microns or larger. Conductive traces can be patterned in any appropriate manner to provide a desired connection. If multiple conductive traces are formed, the pitch can vary according to the desired implementation.

In some implementations, a package includes one or more conductive pathways on a side surface of a cover glass and/or glass substrate. In some implementations a package includes conductive traces on a side surface of a glass substrate and/or cover glass. An example of a package including conductive traces on a side surface is shown in FIG. 11A, which depicts conductive traces 130 that extend along a side surface of the cover glass 96.

In some implementations, wire bonds, if present are located only on an interior of a glass package, such as the wire bond 136 depicted in FIG. 11B. In some implementations, conductive pathways from an interior to an exterior of a package include only through-glass via interconnects and/or conductive traces formed on a package surface. This can allow the glass package to be suitable for surface mounting and/or deployment in a consumer product without any overmolding or other further packaging.

In some implementations, a glass package can include one or more metal wires inserted through a heated cover glass or glass substrate. In some implementations, one or more of a glass substrate and a cover glass of a glass package includes one or more through-glass via interconnects, which also may be referred to as through-glass vias or conductive through-glass vias. In some implementations, a through-glass via interconnect includes one or more conductive pathways that extend through a glass substrate or cover glass, as described above. A conductive pathway of a through-glass via interconnect can include metalized sidewalls of a through-glass via hole, a conductive fill material in a through-glass via hole, metal pins or posts embedded within a glass material, or a combination of these according to the desired implementation.

In some implementations, a package includes interior through-glass via interconnects, also referred to as non-peripheral through-glass via interconnects. Examples of non-peripheral through-glass via interconnects are shown in FIGS. 15A-17B. The through-glass via interconnects 124 are located in the interior of the glass package 90 in each of these Figures, such that glass surrounds the through-glass via interconnects 124.

In some implementations, a glass package includes peripheral through-glass via interconnects. In some implementations, a peripheral through-glass via interconnect can include via openings in top and bottom surfaces of a glass substrate or cover glass, a sidewall recessed from one or more side surfaces of the glass substrate or the cover glass, and one or more conductive pathways extending along the sidewall from the top surface to the bottom surface. Each of the top and bottom surfaces can be, for example, an exterior or interior surface of the glass substrate or cover glass.

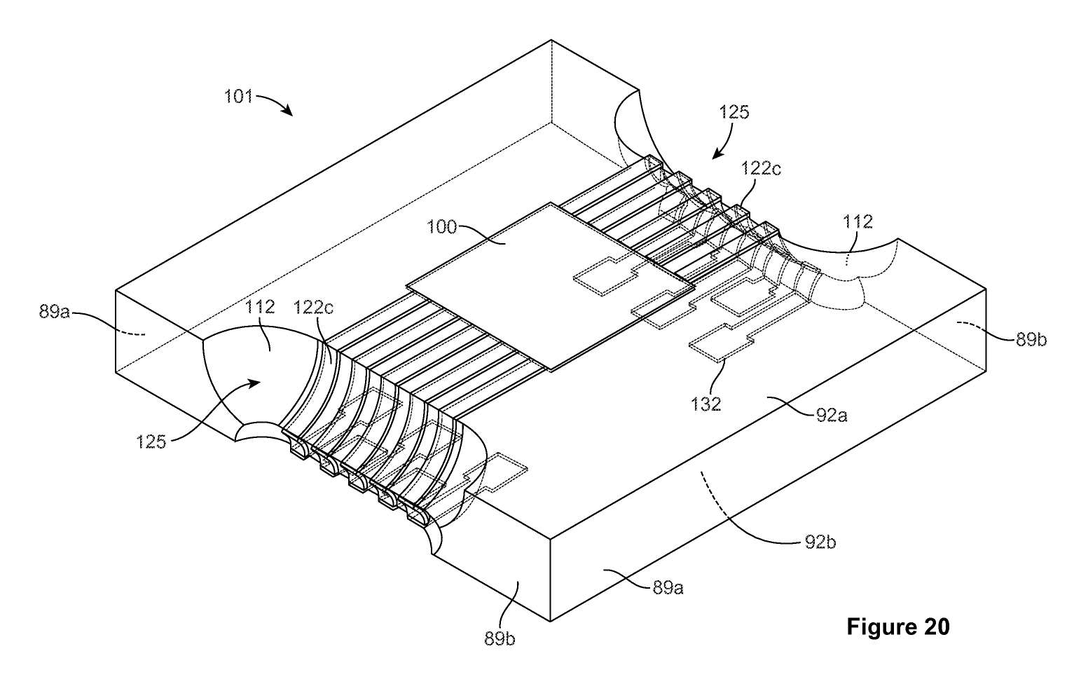

FIG. 20 shows an example of a schematic illustration of an isometric view depicting a portion of a glass package including peripheral through-glass via interconnects. A glass component 101 is a generally planar substrate having two major substantially parallel surfaces, top surface 92a and bottom surface 92b. The glass component 101 also has two sets of parallel peripheral surfaces, also referred to as side surfaces, peripheral surfaces 89a and peripheral surfaces 89b. Peripheral surfaces 89a and 89b are minor surfaces that are substantially perpendicular to top surface 92a and bottom surface 92b. A device 100 is attached to or formed on the top surface 92a of the glass component 101. The glass component 101 can be, for example, a glass substrate or a cover glass of a glass package as described above with reference to FIGS. 9-19E, with top surface 92a being an interior surface and bottom surface 92b being an exterior surface of the glass substrate or cover glass of the glass package. The device 100 can be an IC device, a MEMS or other EMS device, or any other type of device as described above.

The glass component 101 includes peripheral through-glass via interconnects 125. The peripheral through-glass via interconnects are multi-trace through-glass via interconnects, including multiple conductive traces 122c that extend between portions of the top surface 92a and the bottom surface 92b through the glass component 101. (For clarity, components behind glass surfaces in FIG. 20 are shown in dotted lines, though the glass component 101 can be transparent or non-transparent according to the desired implementation.) The peripheral through-glass via interconnects 125 are located on the periphery of the glass component 101, with each of the through-glass via interconnects 125 recessed from one of the peripheral surfaces 89b. Each of the peripheral through-glass via interconnects 125 includes a sidewall 112, with the conductive traces 122c extending along the sidewall 112. Each of the conductive traces 122c provides a separate conductive pathway between portions of the top surface 92a and the bottom surface 92b through glass component 101. In the example of FIG. 20, each of the conductive traces 122c provides a connection from the device 100 to an exterior pad 132 on the bottom surface 92b. Specifically, each of the conductive traces 122c extends from the peripheral through-glass via interconnect 125 to connect to the device 100 on the top surface 92a and extends from the through-glass via interconnect 125 to connect to the exterior pad 132 on the bottom surface 92b. The exterior pads 132 can allow for connections to a PCB or other substrate or device (not shown). As noted, in the example depicted, each of the through-glass via interconnects 125 includes the multiple conductive traces 122c, though in some other implementations as described further below, there may be a single conductive trace or other conductive pathway through a peripheral through-glass via. A peripheral through-glass via interconnect 125 can be included on any number of sides of a glass package including one, two, three, four or (if present) more sides. Multiple peripheral through-glass via interconnects 125 may be included on any one side of a glass package.

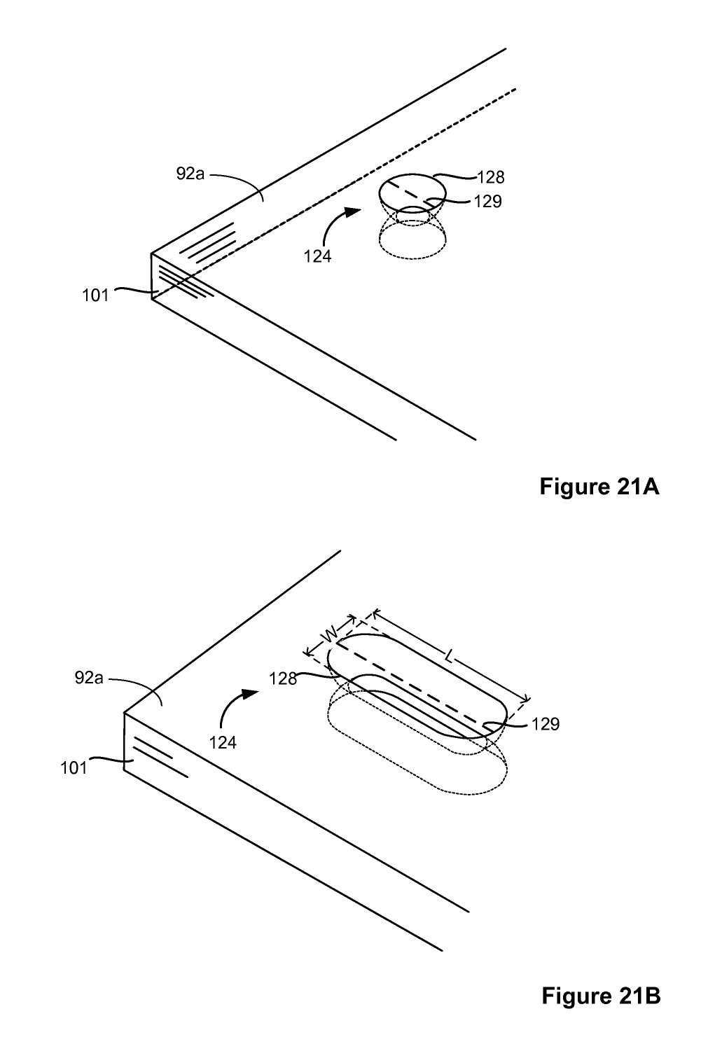

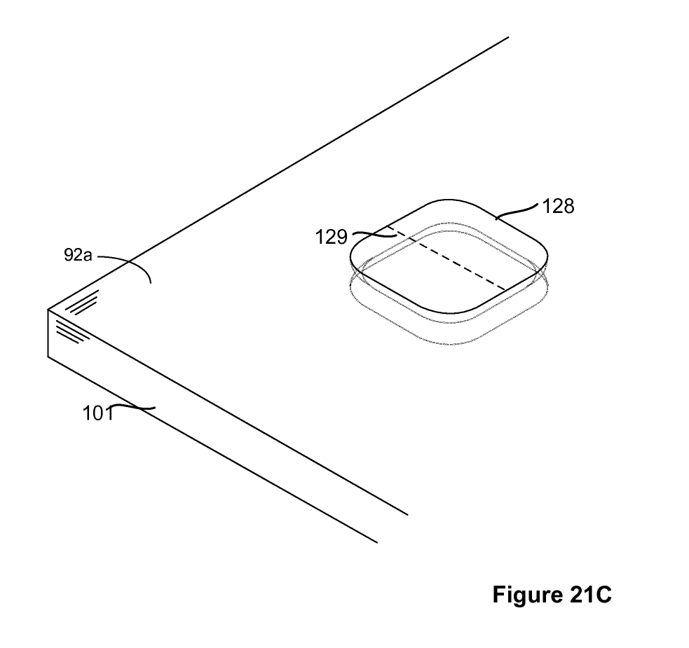

As described above, non-peripheral and peripheral through-glass via interconnects can include via openings in opposing parallel surfaces of a glass substrate or cover glass. FIGS. 21A-21C show examples of schematic illustrations of isometric cross-sectional views of through-glass via interconnects having various opening shapes.

In FIG. 21A, a glass component 101 includes a through-glass via interconnect 124 having an opening 128 in a top surface 92a of the glass component 101. The glass component 101 can be, for example, a glass substrate or cover glass of a glass package. (For clarity, metallization or other conductive pathway of the through-glass via interconnect 124 is not shown.) In the depicted example, the opening 128 is circular. A center line 129 of the opening 128 is indicated. In some implementations, the glass component 101 can be cut along the center line 129 to provide a semicircular opening of a peripheral through-glass via interconnect. In FIG. 21B, a glass component 101 includes a through-glass via interconnect 124 having an opening 128 in a top surface 92a of the glass component 101. The glass component 101 can be, for example, a glass substrate or cover glass of a glass package. (For clarity, metallization or other conductive pathway of the through-glass via interconnect 124 is not shown.) In the depicted example, opening 128 is slot-shaped. A slot-shaped via opening may be characterized as an elongated rectangle having rounded corners, with a longer dimension, length L, and a shorter dimension, width W. A center line 129 of the opening 128 is indicated. In some implementations, the glass component 101 can be cut along the center line 129 to provide a half-slot shaped opening of a peripheral through-glass via interconnect, with the half-slot shape referring in some implementations to the shape of a slot-shaped via opening separated into two portions. In FIG. 21C, a glass component 101 includes a through-glass via interconnect 124 having an opening 128 in a top surface 92a of the glass component 101. The glass component 101 can be, for example, a glass substrate or cover glass of a glass package. (For clarity, metallization or other conductive pathway of the through-glass via interconnect 124 is not shown.) In the depicted example, opening 128 is square-shaped with rounded corners. A center line 129 of the opening 128 is indicated. The glass component 101 can be cut along the center line 129 to provide a half-square shaped opening of a peripheral through-glass via interconnect. Via openings may be oval-shaped, half-oval shaped, circle-shaped, half-circle shaped, rectangular-shaped, square-shaped, half-square shaped, square-shaped with rounded corners, half-square shaped with rounded corners, etc. In some implementations, via openings have rounded edges with no sharp corners.

The number, shape and placement of through-glass via interconnects may vary according to implementation. For example, one or more peripheral through-glass via interconnects may be located on the periphery of one, two, three or more sides of a glass substrate or cover glass. In some implementations, a glass package can include one or more peripheral through-glass via interconnects in addition to one or more non-peripheral through-glass via interconnects. In some implementations, multiple through-glass via interconnects can be arranged in an array. The orientation of through-glass via interconnects can vary according to the desired implementation.

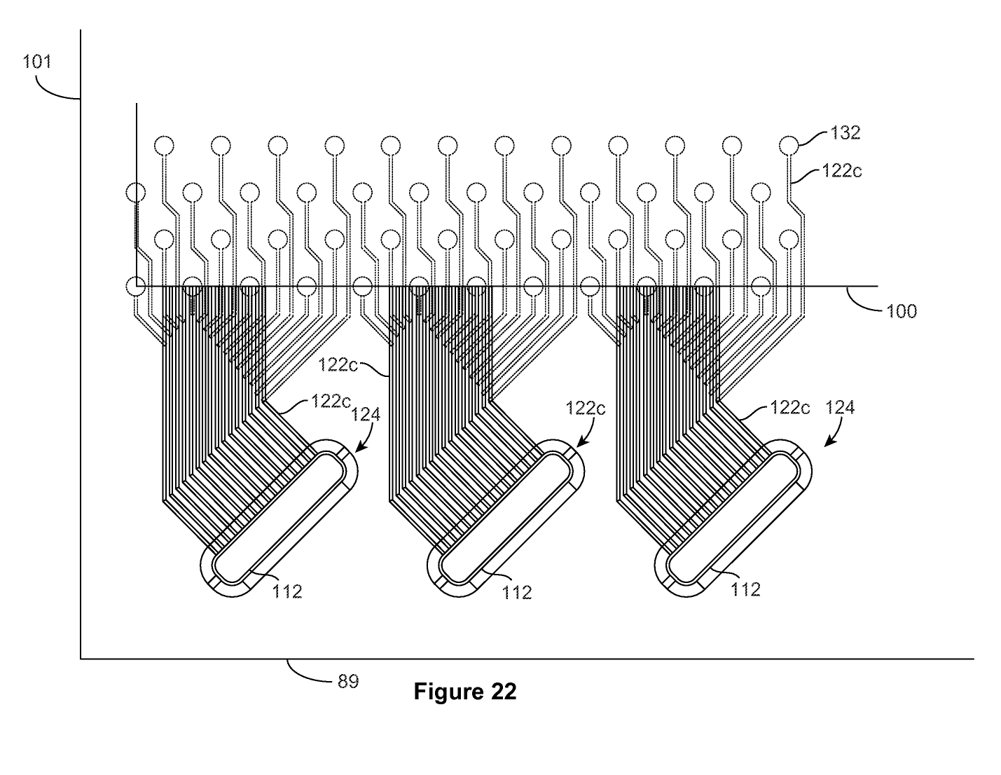

FIG. 22 shows an example of a schematic illustration of a top view of a portion of a package including an array of non-peripheral multi-trace through-glass vias. Through-glass via interconnects 124 are located in the interior of a glass component 101, which can be a glass substrate or a cover glass of a glass package, for example. Each through-glass via interconnect 124 includes a sidewall 112 and conductive traces 122c extending along sidewall 112. The conductive traces 122c extend from a device 100 on one side of glass component 101 to exterior pads 132 on the other side of the glass component 101. The device 100 can be an IC device, a MEMS or other EMS device, or any other type of device as described above.

The conductive traces 122c are continuous from the device 100 to the exterior pads 132. (A bottomside segment of each conductive trace 122c is obscured by a topside segment.) The shape and orientation of the through-glass via interconnects 124 with respect to a side surface can vary according to the desired implementation. In the example of FIG. 22, the through-glass via interconnects 124 are slot-shaped with the length of the slot non-parallel to a side surface 89 of the glass component 101. The conductive traces 122c also can be angled to extend from the through-glass via interconnects 124 to the device 100.

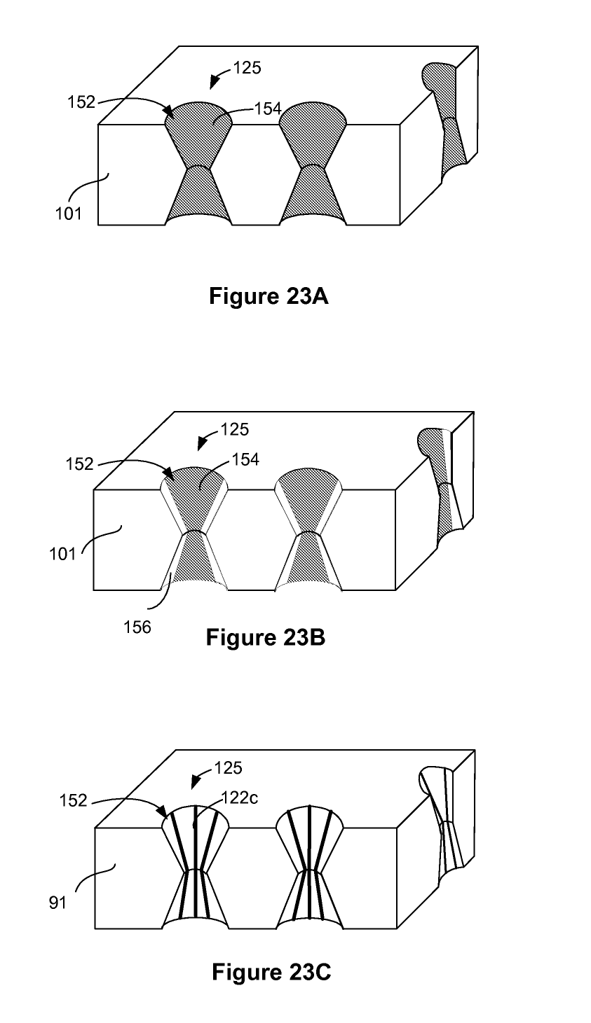

FIGS. 23A-23C show examples of schematic illustrations of sidewall metallization patterns of through-glass vias interconnects. (For clarity, sidewall metallization patterns of peripheral through-glass via interconnects 125 are depicted; these patterns can be implemented in non-peripheral through-glass via interconnects as well.) FIG. 23A depicts a schematic illustration of peripheral through-glass via interconnects 125 in a glass component 101, which can be a glass substrate or cover glass of a glass package. The peripheral through-glass via interconnects 125 each include a through-glass via hole 152 and a thin conductive film 154 coating the sidewalls of the through-glass via hole 152. Each thin conductive film 154 completely covers the sidewalls of the through-glass via hole and provides a single conductive pathway through the glass component 101.

FIG. 23B depicts a schematic illustration of peripheral through-glass via interconnects 125 in a glass component 101, which can be a glass substrate or cover glass of a glass package. In this example, the peripheral through-glass via interconnects 125 each include a through-glass via hole 152 and a thin conductive film 154 partially coating the sidewalls of the through-glass via hole 152. The thin conductive film 154 extends through the through-glass via hole 152 to provide a conductive pathway from the top of glass component 101 to the bottom of glass component 101. Portions 156 of the sidewalls of each of the through-glass via holes 152 are uncovered. For example, in some implementations, the portions 156 of the sidewalls are not metalized so that there is no metal in a dicing street. Each thin conductive film 154 provides a single conductive pathway through the glass component 101.

FIG. 23C depicts a schematic illustration of peripheral through-glass via interconnects 125 in a glass component 101, which can be a glass substrate or cover glass of a glass package. In this example, the peripheral through-glass via interconnects 125 each include a through-glass via hole 152 and multiple conductive traces 122c extending through the through-glass via hole 152. Each conductive trace 122c can provide an independent conductive pathway through the glass component 101, allowing multiple devices, pads or other electrically active components independent access to each peripheral through-glass via interconnect 125.

In some implementations, through-glass via holes are filled or partially filled by a metal, other conductive material, or a non-conductive material. In some other implementations, the interior of a through-glass via hole is left unfilled. If used, a filler material can be a metal, a metal paste, a solder, a solder paste, one or more solder balls, a glass-metal material, a polymer-metal material, a conductive polymer, a non-conductive polymer, an electrically conductive material, a non-conductive material, a thermally conductive material, a heat sink material, or a combination thereof. In some implementations, the filler material reduces the stress on a deposited thin film and/or plated layer. In some other implementations, a filler material seals the via holes to prevent transfer of liquids or gases through the via holes. A filler material may serve as a thermally conductive path to transfer heat from devices mounted on one side of a glass component to the other. In some implementations, in addition to or instead of sidewall metallization, a conductive pathway of a through-glass via interconnect includes a conductive filler material. In some implementations, one or more through-glass via holes can include a non-conductive filler material, such as a thermally conductive or sealing material. In some implementations, a through-glass via hole does not include a conductive pathway and is not used as a through-glass via interconnect, but can serve as a thermal transmission pathway or other pathway.

Cross-sectional profiles of through-glass via holes and through-glass via interconnects can vary according to the desired implementation. In some implementations, the through-glass via holes have sidewalls with a concave curvature extending from a planar glass substrate or cover glass surface to a point in the interior of the glass substrate or cover glass. In some implementations, the through-glass via holes have a tapered or v-shaped profile, with the sidewalls tapering from a larger via opening at one surface to a smaller via opening at the other surface. In some implementations, the through-glass via holes have a substantially uniform area throughout the glass substrate or cover glass, with the via holes having substantially straight, vertical sidewalls.

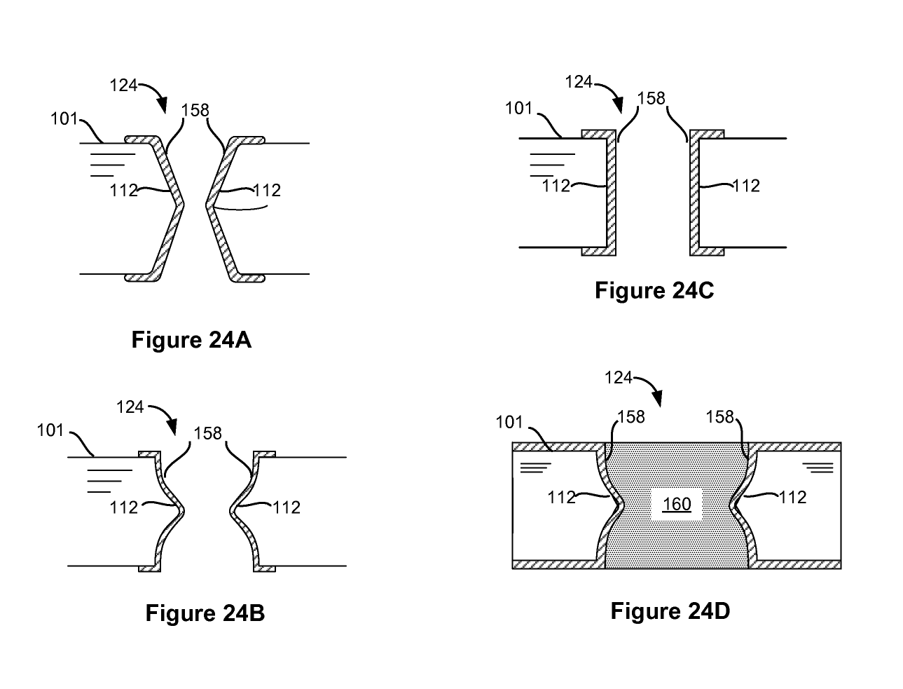

FIGS. 24A-24D show examples of cross-sectional schematic illustrations of through glass via holes and interconnects. FIG. 24A depicts a through-glass via interconnect 124 in a glass component 101. The glass component 101 can be a glass substrate or cover glass as described above. The through-glass via interconnect 124 includes a sidewall metallization layer 158 on through-glass via sidewalls 112. The sidewall metallization layer 158 can be, for example, one or more thin conductive films, one or more patterned conductive traces, etc. The sidewall metallization layer 158 is conformal to sidewalls 112. The sidewalls 112 have a double-sided, v-shaped profile, with tapered sidewalls extending from each surface to meet at a point in the interior of the glass component 101. In the example of FIG. 24B, a through-glass via interconnect 124 in a glass component 101 has sidewalls 112 with a concave curvature extending from each surface of the glass component 101 to a point in the interior of the glass component 101. The through-glass via interconnect 124 includes a sidewall metallization layer 158 that is conformal to the through-glass via sidewalls 112. In the example of FIG. 24C, a through-glass via interconnect 124 in a glass component 101 includes sidewalls 112 that are substantially straight, vertical sidewalls. The through-glass via interconnect 124 includes a sidewall metallization layer 158 that is conformal to the through-glass via sidewalls 112. FIG. 24D depicts a through-glass interconnect 124 in glass component 101. The through-glass via interconnect 124 includes sidewall metallization layer 158 and filler material 160. The filler material 160 fills the space between the sidewalls 112.

Additional details of through-glass via interconnects and methods of forming through-glass interconnects that may be used in accordance with various implementations are given in U.S. patent application Ser. No. 13/048,768, filed Mar. 15, 2011, and entitled “Thin Film Through-Glass Via And Methods For Forming Same,” and in U.S. patent application Ser. No. ______, filed concurrently with this application, and entitled “Die-Cut Through-Glass Via And Methods For Forming Same,” both of which are incorporated by reference herein.

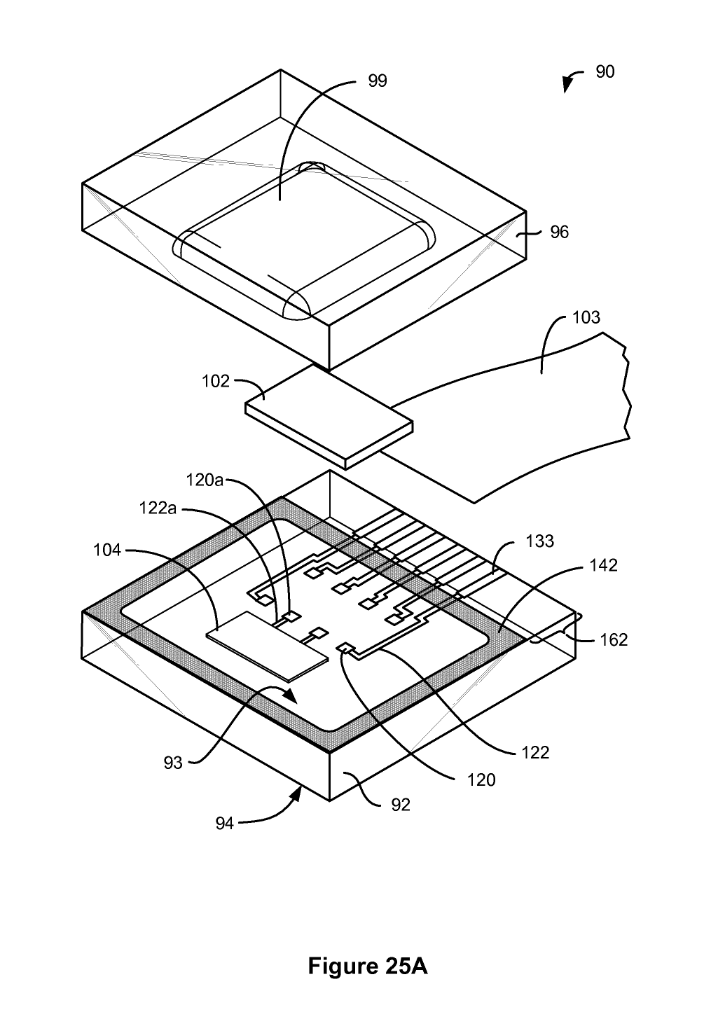

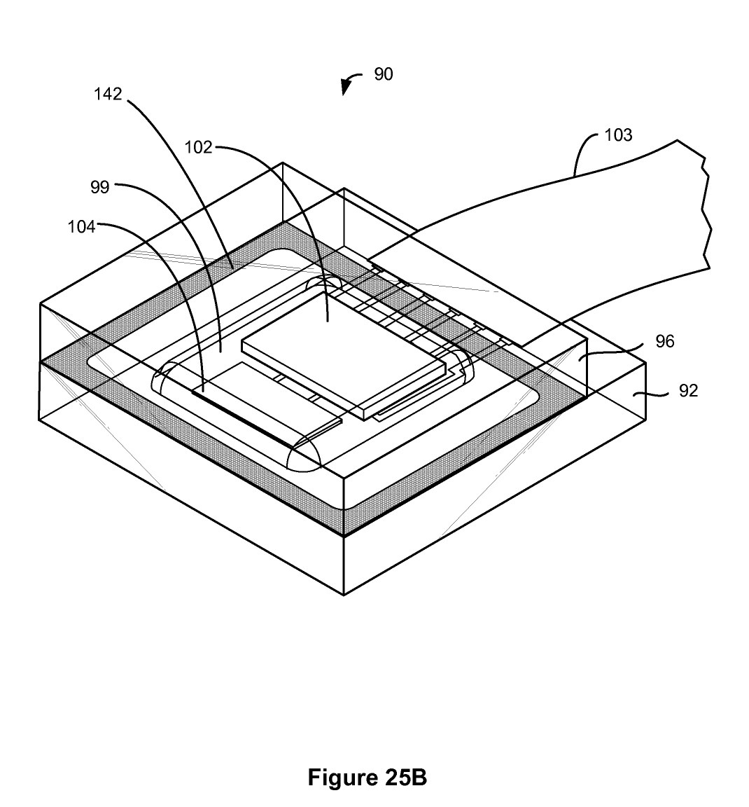

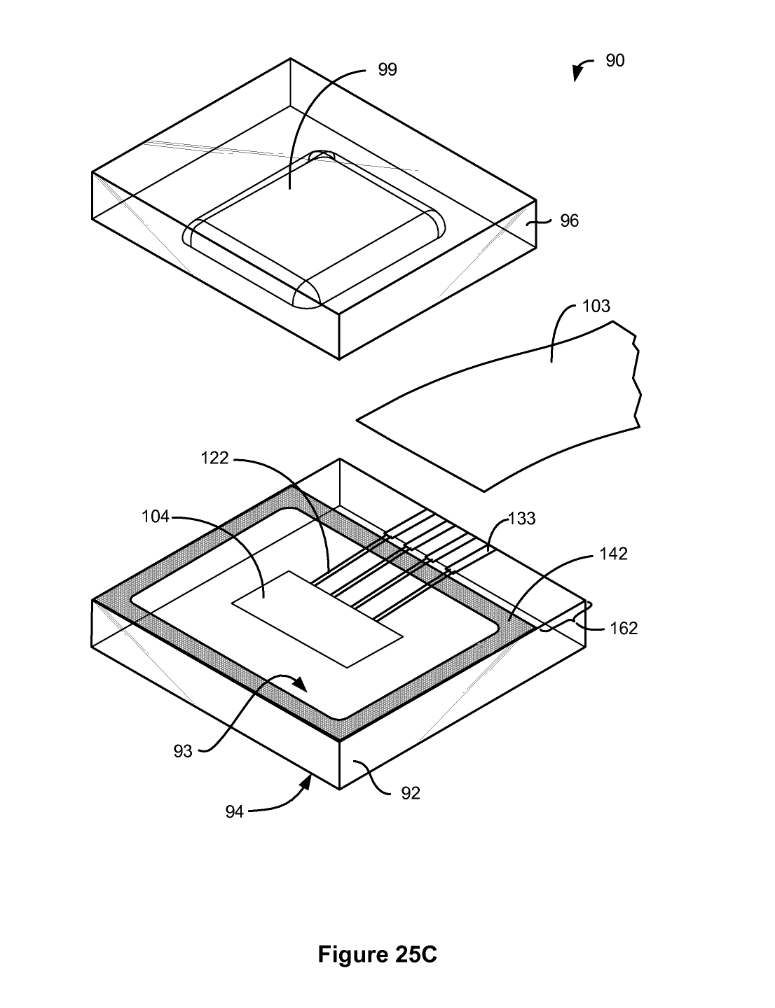

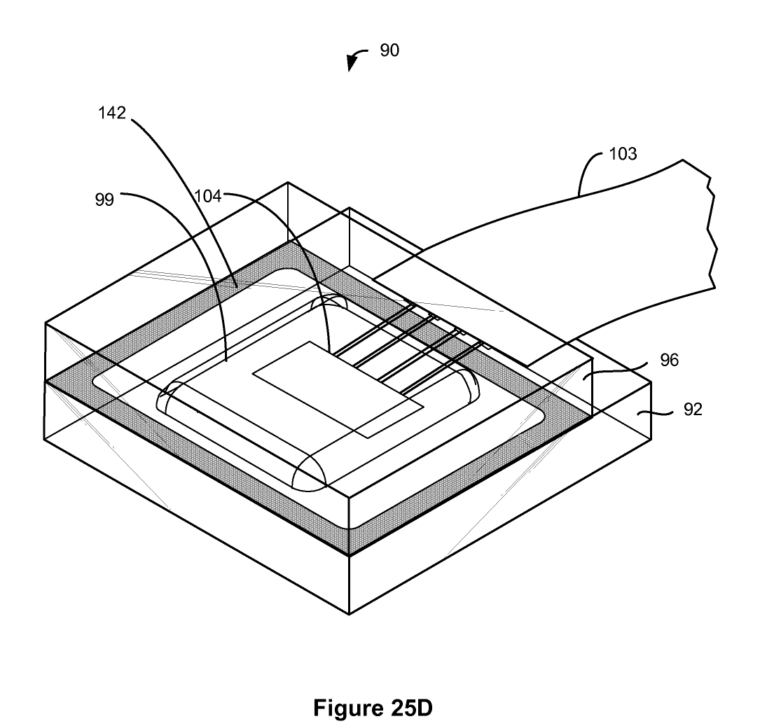

In some implementations, a glass package includes a flexible connector or is configured to connect to a flexible connector. A flexible connector also may be referred to as a ribbon cable, a flexible flat cable or a flex tape. A flexible connector may include a polymer film with embedded electrical connections, such as conducting wires or traces, running parallel to each other on the same flat plane. A flexible connector also may include flex pads at one end, and contacts at the other end, with the conducting wires or traces electrically connecting individual flex pads with individual contacts. One example of a glass package configured to attach to a flexible connector is described above with respect to FIG. 11C, with additional examples described below with respect to FIGS. 25A-25D. FIGS. 25A and 25B show examples of schematic illustrations of exploded and isometric views of glass-encapsulated IC and MEMS devices connected to a flexible connector.

A glass package 90 in the example of FIGS. 25A and 25B includes a cover glass 96, an IC device 102, a glass substrate 92, a MEMS device 104, and a joining ring 142. The cover glass 96 includes a recess 99 that accommodates the MEMS device 104 and the IC device 102.

The glass substrate 92 is generally a planar substrate having two substantially parallel surfaces, an interior surface 93 and an exterior surface 94. A ledge 162 having flex-attach pads 133 thereon allows for electrical connections to portions of the interior surface 93 that are enclosed by the cover glass 96. Conductive traces 122 on the interior surface 93 connect IC bond pads 120 to the flex-attach pads 133 on the ledge 162. The IC bond pads 120 may be used for connections to the IC device 102. The MEMS device 104 and the IC device 102 may be electrically connected to one or more of the flex-attach pads 133 directly or indirectly by the conductive traces 122 on the glass substrate 92. In the example shown, conductive traces 122a connect the MEMS device 104 to IC bond pads 120a and the IC bond pads 120a may be used for connections to the IC device 102. The particular arrangement of the electronic components associated with the glass substrate 92 is an example of one possible arrangement, with other arrangements possible.

In some implementations, portions of the conductive traces 122 that are exposed to the outside environment may be passivated. For example, the conductive traces 122 may be passivated with a passivation layer, such as a coating of an oxide or a nitride.

The glass package 90 shown in FIGS. 25A and 25B may further include a flexible connector 103. The flexible connector 103 may include flex pads (not shown). The flex pads may be configured to make contact with the flex-attach pads 133. In some implementations, the flex pads of the flexible connector 103 may be bonded to the flex-attach pads 133 of the glass package 90 with an anisotropic conductive film (ACF). In some other implementations, the flex pads of the flexible connector 103 may be bonded to the flex-attach pads 133 of the glass package 90 with solder. The contacts of the flexible connector 103 may be assembled in a socket or other connector, for example, for connection to a printed circuit board (PCB) or other electronic component.

In some implementations, the glass package 90 with the ledge 162 for connection to a flexible connector 103 may allow the glass package 90 to be located away from a PCB or other electronic component. This can allow the PCB or other electronic component to be located in a protected environment or can allow the glass package 90 to be located in a small enclosure, for example.

FIGS. 25C and 25D show examples of schematic illustrations of exploded and isometric views of a glass-encapsulated MEMS device connected to a flat flexible connector. A glass package 90 shown in FIGS. 25C and 25D includes a cover glass 96, a glass substrate 92, a MEMS device 104, and a joining ring 142. The cover glass 96 includes a recess 99 that accommodates MEMS device 104.

The glass substrate 92 is generally a planar substrate having two substantially parallel surfaces, an interior surface 93 and an exterior surface 94. A ledge 162 allows for electrical connections to portions of the interior surface 93 that enclosed by the cover glass 96. Conductive traces 122 on the interior surface 93 connect bond pads 120 to flex-attach pads 133. The MEMS device 104 may be electrically connected to one or more of the flex-attach pads 133 by the conductive traces 122 on the glass substrate 92. A flexible connector 103 may be bonded to the flex-attach pads 133 by an anisotropic conductive film (ACF) or solder, for example.

In some implementations, the flexible connector 103 can be attached to one or more IC devices (not shown). For example, the flexible connector 103 can be attached to one or more chip scale package (CSP) silicon dies for signal conditioning and formatting. This can allow further reduction of the dimensions of the glass package 90, as it does not accommodate an IC device. For example, a glass-packaged MEMS microspeaker can be located in the ear of a user, with associated control electronics in an IC device located outside the ear.

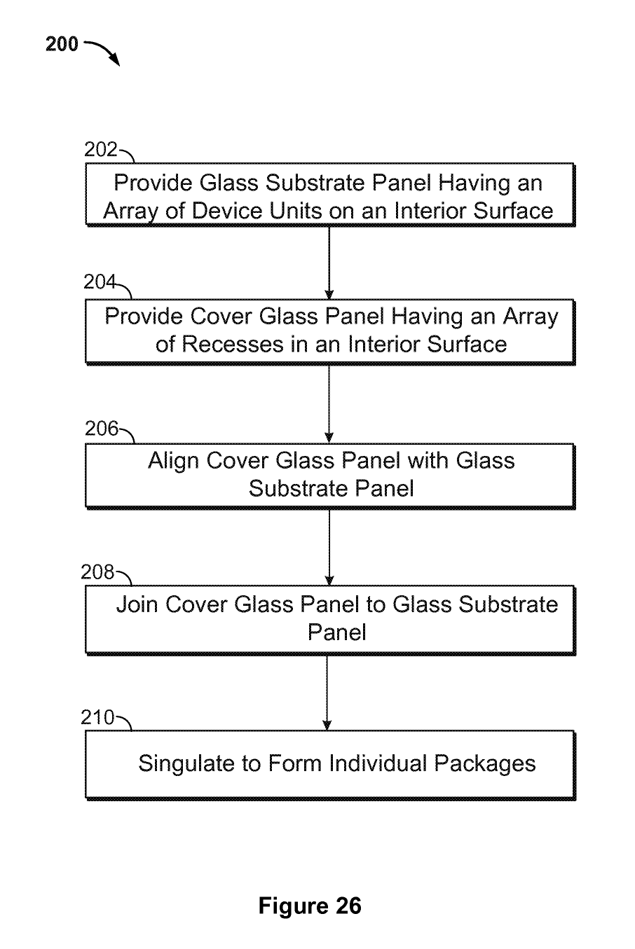

Implementations of methods of fabricating glass packages are described below with respect to FIGS. 26-38. In some implementations, methods of fabricating glass packages can be batch level processes. Batch level processes of fabricating glass packages refers to fabricating a plurality of glass packages simultaneously. For example, in some implementations, certain operations in a batch level encapsulation process are performed once for a plurality of devices, rather than performed separately for each device. In some implementations, a batch level process involves encapsulating a plurality of devices that are on a glass wafer, panel or other glass substrate prior to singulation of the glass wafer, panel or other glass substrate into individual dies.

FIG. 26 shows an example of a flow diagram illustrating a batch level manufacturing process for a glass package. The process 200 begins at block 202 with providing a glass substrate panel having an array of device units. A device unit can include one or more devices on an interior surface of a glass substrate as well associated components that are to be packaged with the one or more devices of the unit. It should be noted that the surface on which devices are fabricated and/or attached is referred to as an interior surface of the glass substrate panel as it will eventually form interior surfaces of one or more packages.

A glass substrate panel refers to a glass substrate that is configured to eventually be singulated. Glass substrate panels can include sub-panels cut from larger glass substrates. For example, in some implementations, a glass substrate panel can be a square or rectangular sub-panel cut from a larger panel of glass. In some implementations, a glass substrate panel can glass plate having an area on the order of four square meters. In some implementations, a glass substrate panel can be a round substrate with a diameter of 100 millimeters, 150 millimeters, or other appropriate diameter. In some implementations, a glass substrate panel thickness may be between about 300 and 700 microns, such as about 500 microns, though thicker or thinner substrates can be used according to the desired implementation.

As described above, devices such as IC devices and/or EMS devices can be fabricated on or otherwise attached to the interior surface of the glass substrate. In some implementations, for example, a glass substrate includes an array of EMS devices and associated IC devices, with the EMS devices fabricated on the glass substrate and the IC devices attached by flip-chip attachment. In some other implementations, for example, a glass substrate includes an array of EMS devices and associated IC devices, with the EMS devices and the IC devices fabricated on the glass substrate. In some other implementations, a glass substrate includes an array of EMS devices fabricated on or attached to the glass substrate with no IC devices, or an array of IC devices fabricated on or attached to the glass substrate with no EMS devices.

In addition to devices on the interior surface of the glass substrate panel, any number of other components such as joining rings, conductive traces, pads, traces, interconnects, ports, other signal transmission pathways and the like may be present on any surface of or through the glass substrate panel. Any number of devices can be arrayed on the glass substrate panel. For example, tens, hundreds, thousands or more devices may be on a single glass substrate panel. The devices and associated components may all be the same or may differ across the glass substrate panel according to the desired implementation.

The process 200 continues at block 204 with providing a cover glass panel having an array of recesses in an interior surface. As described above, a recess can be configured to accommodate one or more devices on a glass substrate according to the desired implementation. The cover glass panel can include additional features and components including joining rings, conductive traces, pads, interconnects, ports, other signal transmission pathways and the like.

A cover glass panel refers to a glass substrate that is configured to eventually be singulated. Cover glass panels include sub-panels cut from larger glass substrates. In some implementations, a cover glass panel can be approximately the same shape and area as the glass substrate panel to which it will be joined. In some implementations, a cover glass panel thickness may be between about 300 and 700 microns, such 500 microns, though thicker or thinner substrates can be used according to the desired implementation.

The process 200 continues at block 206 with alignment of the cover glass panel with the glass substrate panel. The cover glass panel is aligned with the glass substrate panel such that recesses configured to accommodate devices are each positioned over the one or more devices to be accommodated and other corresponding components on the cover glass panel and glass substrate panel are aligned. In some implementations, joining rings on the cover glass panel are aligned with corresponding joining rings on the glass substrate panel. For example, if the cover glass panel is to be joined to the glass substrate panel by solder bonding, metal joining rings of each device unit of the glass substrate panel can be aligned with corresponding metal joining rings on the cover glass panel. Aligning the cover glass panel and the device substrate panel can involve standard flip-chip placement techniques, including the use of alignment marks and the like.

The process 200 continues at block 208 with joining the cover glass panel to the glass substrate panel. In some implementations, after joining the cover glass panel to the glass substrate panel, the devices on the glass substrate panel are encapsulated between the cover glass panel and the glass substrate panel. Any appropriate method of joining the cover glass panel to the glass substrate panel can be used, with examples including solder bonding, adhesive bonding, and thermocompression bonding. Solder bonding involves contacting the cover glass panel and glass substrate panel to a solder paste or other solderable material in the presence of heat. One type of solder bonding that can be used is eutectic metal bonding, which involves forming a eutectic alloy layer between the cover glass panel and the glass substrate panel. This is discussed further below with respect to FIGS. 36A and 36B. Adhesive bonding involves contacting the cover glass panel and the glass substrate panel to an epoxy or other adhesive. Heat, radiation such as ultraviolet radiation or pressure may be applied to form the epoxy bond or other adhesive bond according to the desired implementation. Thermocompression bonding involves applying pressure and heat to components such as joining rings on the cover glass panel and glass substrate panel in an absence of an intermediate material.

Process conditions such as temperature and pressure during a joining process can vary according to the particular joining method and desired characteristics of the area surrounding an encapsulated device. For example, for solder bonding, including eutectic bonding, the joining temperature can range from about 100° C. to about 500° C. as appropriate. Example temperatures can be about 150° C. for indium/bismuth (InBi) eutectic, about 225° C. for CuSn eutectic and about 305° C. for AuSn.

In some implementations, the joining operation involves setting a defined pressure in the encapsulated area. This may involve pumping a gas in or out of a chamber in which the joining occurs to set the desired pressure. After the joining operation, the pressure in the encapsulated area to which the device is exposed can be below atmospheric, above atmospheric or at atmospheric pressure. The composition of the gas also can be tailored to a desired composition. For example, a desired inert gas and pressure to damp a proof mass of a MEMS accelerometer can be dialed in during the joining process. The process 200 continues at block 210 by singulating the joined cover glass and glass substrate panels to form individual glass packages, also referred to as dies, each glass package including one or more encapsulated devices and associated components.

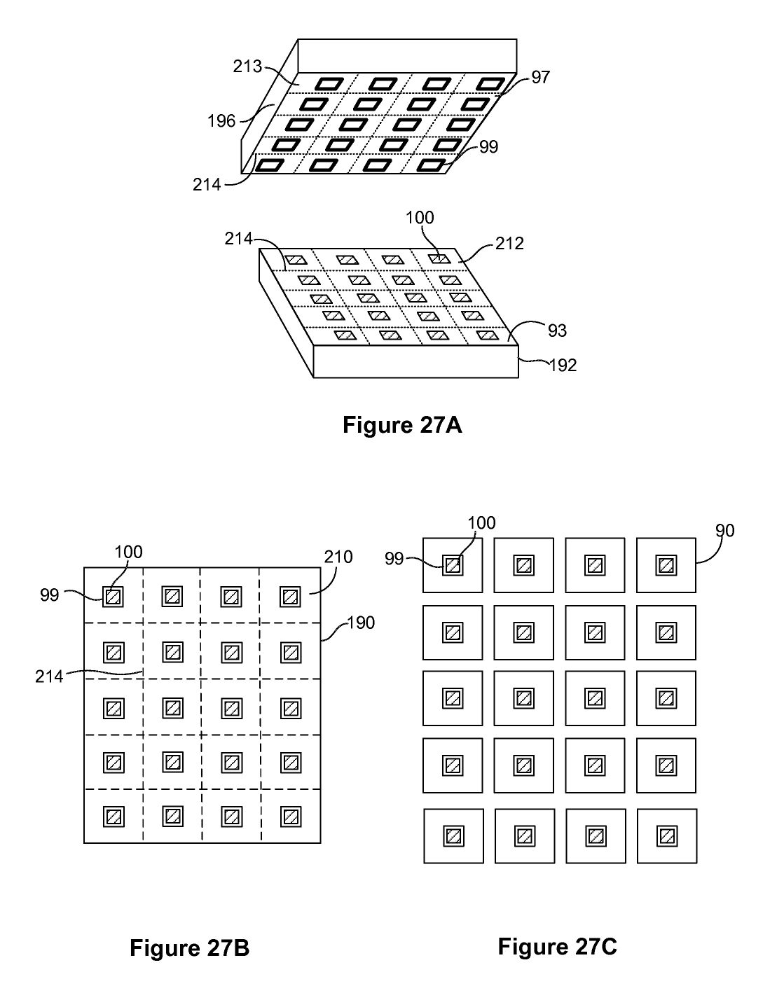

FIGS. 27A-27C show examples of schematic illustrations of various stages of a batch level process of fabricating individual dies including encapsulated devices. First, FIG. 27A shows an example of a simplified schematic illustration of a glass substrate panel 192 and a cover glass panel 196 prior to joining. In the example of FIG. 27A, device units 212 include devices 100 arrayed on an interior surface 93 of the glass substrate panel 192. As indicated above, the device units 212 also may include associated components (not shown) such as pads, traces, interconnects, ports and the like. The cover glass panel 196 includes cover glass units 213 each of which includes a recess 99 formed in an interior surface 97 of the cover glass panel 196. In some implementations, each device unit 213 includes multiple recesses. Boundary lines 214 indicate a boundary between adjacent device units 212, or between adjacent cover glass panel units 213, and desired cut locations in a singulation process.

FIG. 27B is a plan schematic depiction of joined glass substrate and cover glass panels prior to singulation. Joined panels 190 include encapsulated arrayed devices 100, with a recess 99 surrounding each device 100. FIG. 27C is a plan schematic depiction of singulated individual glass packages 90, each glass package 90 including a device 100 surrounded by a recess 99.

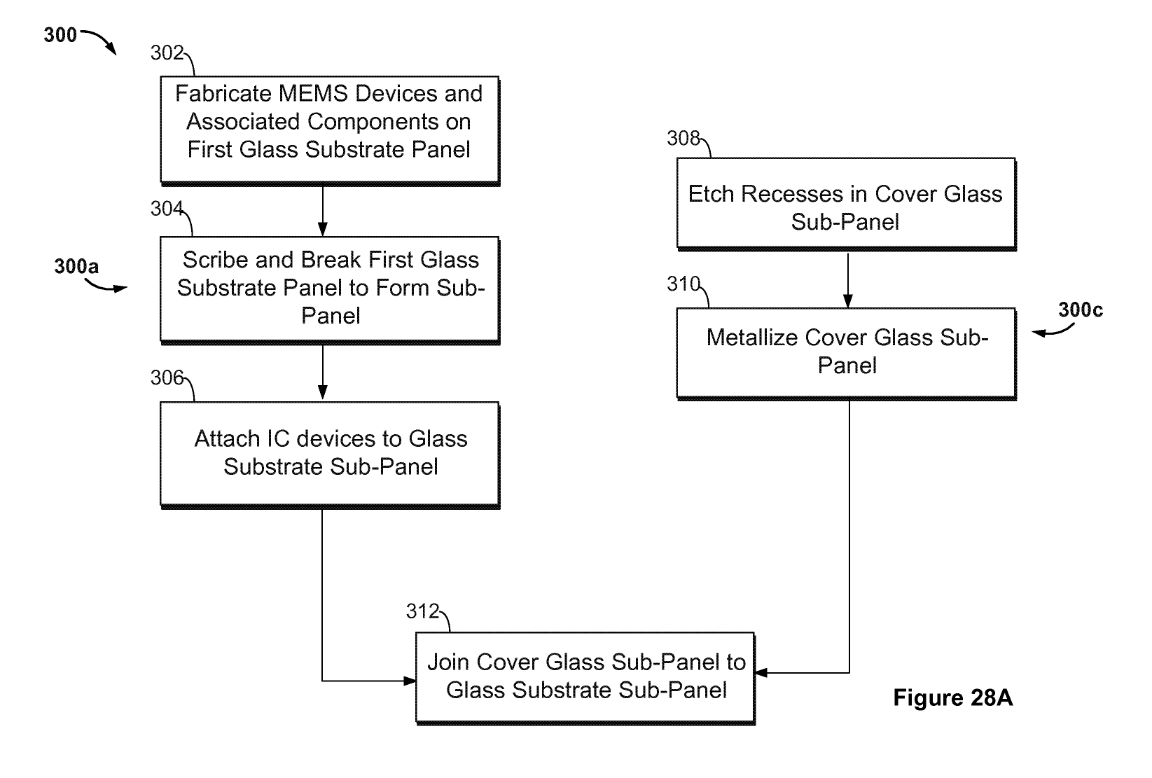

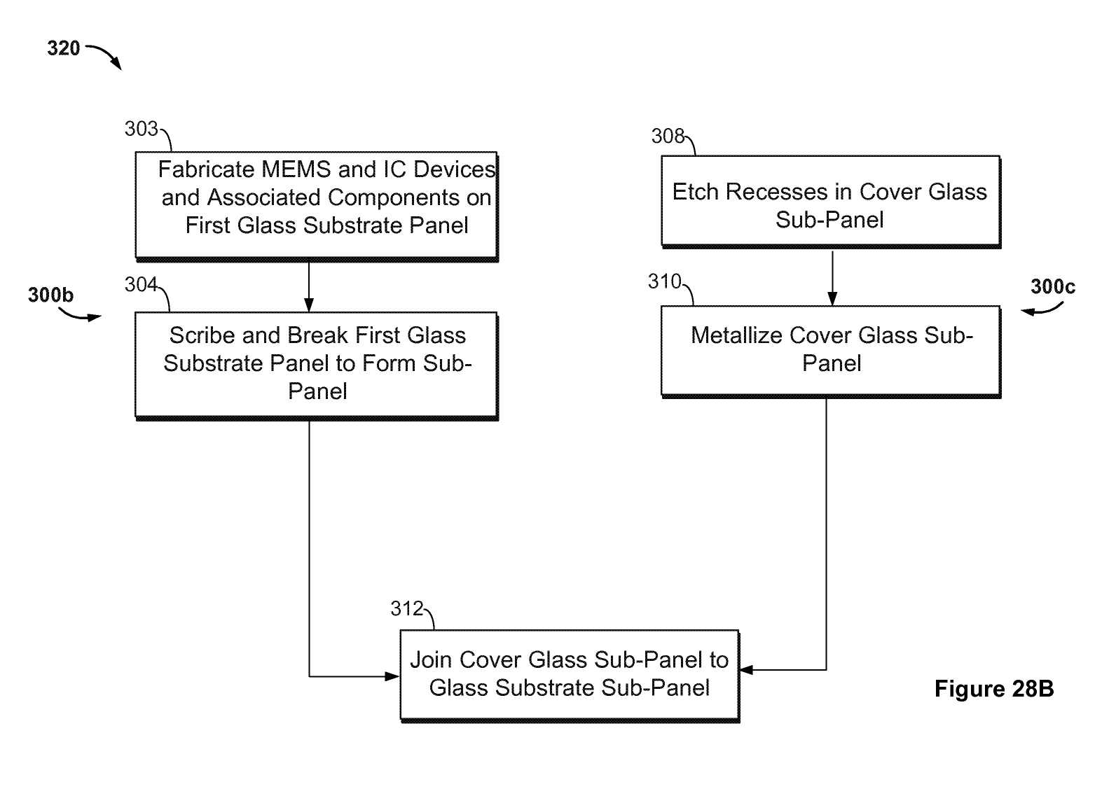

In some implementations, the glass substrate panel is a sub-panel of a larger panel. On-glass device fabrication can occur at a first panel level, with a joining operation occurring at a sub-panel level. FIGS. 28A and 28B shows examples of flow diagrams illustrating processes for forming joined glass substrate and cover glass sub-panels. In FIG. 28A, the process 300 includes parallel processes 300a and 300c, with the process 300a for forming a glass substrate sub-panel, and the process 300c for forming a cover glass sub-panel. The process 300a begins at block 302 with fabrication of MEMS devices and associated components on a first glass substrate panel. The fabrication process is unique to the particular MEMS devices fabricated. In some implementations, the MEMS devices can be built by deposition of various thin film layers on the first glass substrate panel, and selective patterning of the thin film layers to form the desired MEMS devices. An example of a fabrication process described above with respect to FIG. 7.

In another example of a fabrication process, MEMS accelerometers can be fabricated directly on a glass substrate, for example, by sequentially depositing a seed layer and a resist mask, plating through the resist mask, then stripping the resist and etching the unplated seed layer. This sequence can be repeated to build a device including, a plated proof mass and springs, layer by layer, with gaps for capacitance change sensing fabricated by plating copper (Cu) or another metal, then selectively etching the Cu layer, to release the plated proof mass. The proof mass and springs can be fabricated with nickel (Ni) or a nickel based alloy such as nickel manganese (NiMn).

Associated components including conductive traces, pads, through-glass via interconnects, and joining rings also can be fabricated in block 302. The fabrication of any associated component can be performed prior to, during or after fabrication of the MEMS devices. For example, joining rings can be plated during a plating operation in a MEMS device fabrication process. Examples of MEMS devices that can be fabricated include pressure sensors, microphones, speakers, accelerometers, gyroscopes, RF electrical filters, other electrical filters, medical devices, field sensing devices, and displays.

In some implementations, a first glass substrate panel can be sized such that the length and width dimensions, also referred to as the lateral dimensions, of the first glass substrate panel are each greater than 200 mm. In some implementations, the first glass substrate panel is rectangular. In some implementations, the lateral dimensions of the first glass panel can be at least 600 mm×800 mm. In some implementations, one or both of the width and length can be 1 meter or greater.

The process 300a continues at block 304 with scribing and breaking the first glass substrate panel to form a glass substrate sub-panel. In some implementations, the sub-panel has length and width dimensions both less than 200 mm. For example, a glass panel of 680 mm×880 mm can be divided into 20 sub-panels of 170 mm×176 mm. In some implementations, the sub-panel has lateral dimensions of greater than 200 mm. Standard scribe and break processes can be used. The process 300a continues at block 306 with attaching IC devices to the glass substrate sub-panel. Flip-chip attachment or other appropriate attachment processes can be used. This forms a glass substrate sub-panel having an array of MEMS devices and associated IC devices disposed on its interior surface. In some other implementations, operation 306 is not performed. For example, processes for fabricating packages that do not include IC devices enclosed within package cavities do not include operation 306.

The process 300c for forming a cover glass sub-panel starts at block 308 with etching recesses in a cover glass sub-panel. The term sub-panel is used to indicate that the cover glass sub-panel is the same size as the glass substrate sub-panel formed in operation 304 of the process 300a; the cover glass sub-panel may or may not be formed a larger panel according to the desired implementation. In the example of FIG. 28A, all cover glass processing takes place at the sub-panel level. In some implementations, the sub-panel has length and width dimensions both less than 200 mm. In some implementations, the sub-panel has lateral dimensions of greater than 200 mm. Wet or dry etching can be used to form recesses of the number and size to accommodate devices on a glass substrate sub-panel to which the cover glass sub-panel will be joined. In some implementations, other features such as through-glass via holes also can be etched or otherwise formed in the cover glass sub-panel.

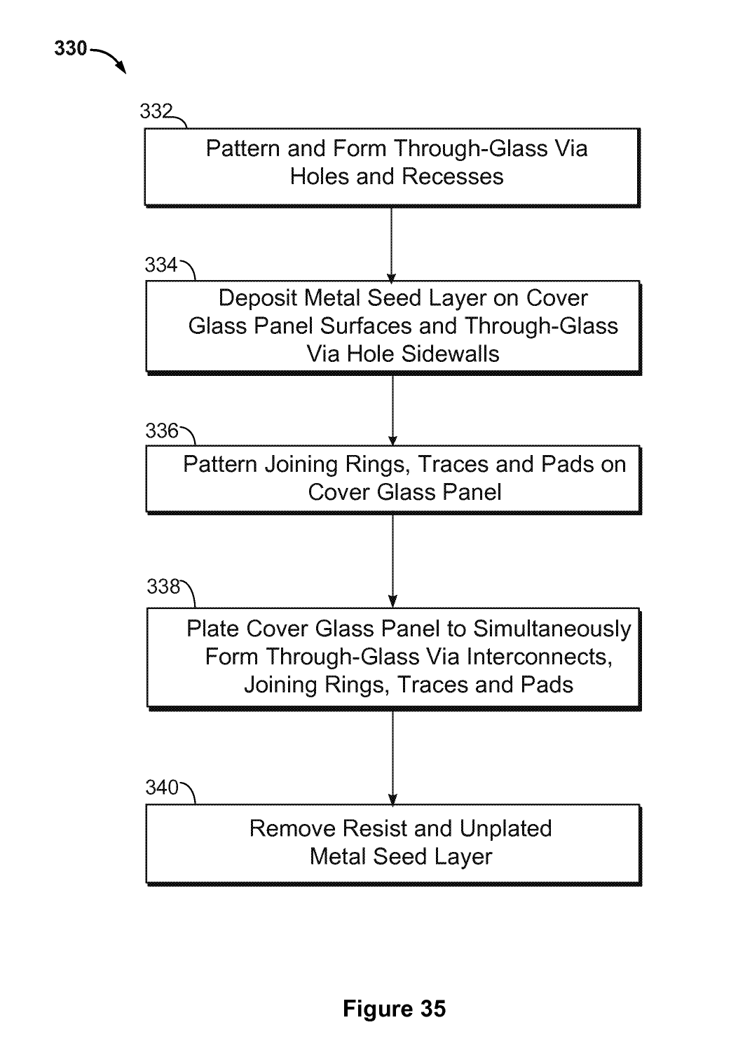

The process 300c continues at a block 310 with metallization of the cover glass sub-panel. Metallization can include formation of any of joining rings, through-glass via interconnects, conductive routing and pads, on one or more surfaces on or through the cover glass sub-panel. In some implementations in which the cover glass is not metalized, such as cover glass 96 depicted in FIG. 16A, operation 310 is not performed. Further details of an implementation of a process used to form a cover glass panel are described below with respect to FIG. 35.

The process 300 then continues at block 312 with joining the cover glass sub-panel to the glass substrate sub-panel. Joining techniques are described above with respect to FIG. 26. The joined cover glass and glass substrate sub-panels are then ready for further process operations, including for example, singulation or dicing.

In FIG. 28B, the process 320 includes parallel processes 300b and 300c, with the process 300b for forming a glass substrate sub-panel, and the process 300c for forming a cover glass sub-panel as described above with respect to FIG. 28A. Certain operations of the process 320 can be the same operations as in the process 300 described above with respect to FIG. 28A.

The process 300b begins at block 303 with fabrication of MEMS and IC devices and associated components on a first glass substrate panel. Examples of dimensions of a first glass substrate panel are described above with respect to FIG. 28A. In some implementations, the MEMS and IC devices can be built by deposition of various thin film layers on the first glass substrate panel, and selective patterning of the thin film layers to form the desired MEMS and IC devices. The IC device and MEMS device fabrication can be performed simultaneously or sequentially or some combination thereof depending on the desired implementation. In some implementations the IC devices are LTPS-TFT devices. In some implementations, the IC devices fabricated on the first glass substrate panel control circuitry for the MEMS devices, allowing the fabrication of glass packages including IC functionality without separately packaged IC devices. For example, an on-glass IC device may include a drive circuit for a multiplexing or demultiplexing MEMS sensor device. In some implementations, the on-glass IC devices provide supplemental IC functionality to an additional IC device that can be included with the package.

Eliminating a separately packaged, attached IC device from a package can facilitate smaller packages in some implementations. In addition to allowing elimination of space to accommodate separate packaging, spacing between a MEMS device and an IC device can be reduced. Tolerances for on-glass device placement can be lithographic tolerances in some implementations, which can be on the order of 3-5 microns. This is contrasted with separately packaged IC devices for which mechanical tolerances used for attachment of an IC device to a glass substrate can be on the order of 20-40 microns, for example. The process 300b continues at block 304 with scribing and breaking the first glass panel to form a glass substrate sub-panel, as described above with respect to FIG. 28A. The process 320 continues at block 312 with joining the cover glass sub-panel to the glass substrate sub-panel as described above with respect to FIG. 28A.

In the examples of FIGS. 28A and 28B, MEMS and/or IC devices are fabricated on a first glass substrate panel that is broken into sub-panels for further processing including, for example, one or more of IC device attachment operations, device encapsulation operations, and singulation operations. In some implementations, breaking larger first glass panels into sub-panels having dimensions less than 200 mm allows use of standard packaging tools readily available to the semiconductor packaging industry for post-device fabrication processing.

In some other implementations, devices can be fabricated on a glass panel that undergoes further processing without being divided into sub-panels. For example, in some implementations, panels having lateral dimensions of greater than 200 mm can undergo post-device fabrication processing. In some other implementations, devices can be fabricated on panels having lateral dimensions of less than 200 mm.

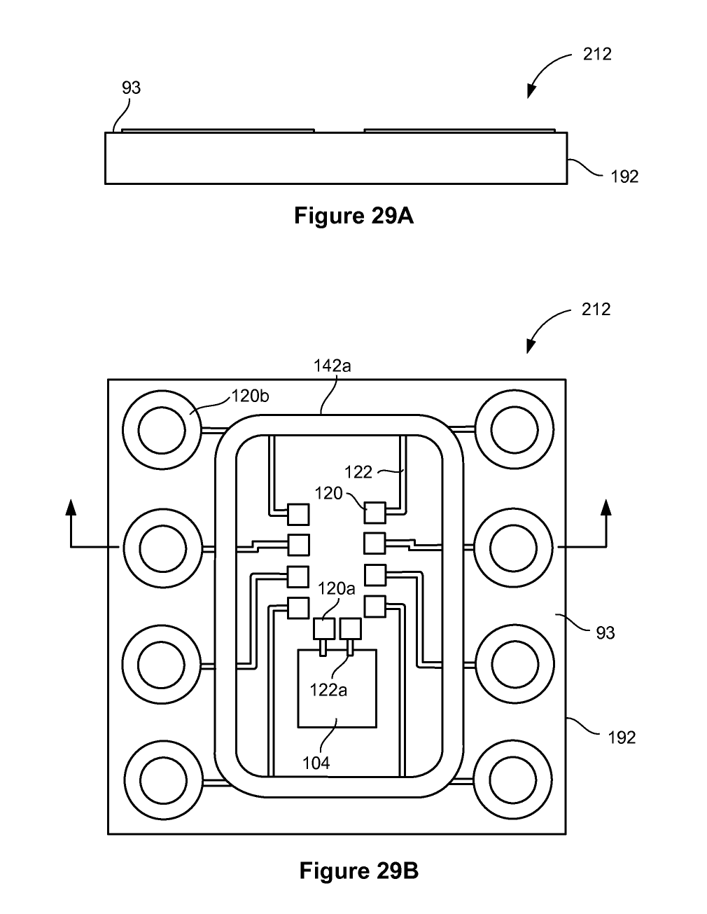

FIGS. 29A-34B show examples of cross-sectional and plan views of schematic illustrations of various stages in a method of encapsulating devices in a glass package. FIGS. 29A and 29B depict examples of cross-sectional view and plan views, respectively, of a device unit 212 on a glass substrate panel 192, a portion of which is shown in the Figures. (For clarity, certain components shown in the plan view are not labeled in the cross-sectional view.) The device unit 212 can be a single repeating unit on the glass substrate panel 192 as described above with respect to FIG. 28A. The device unit 212 includes a MEMS device 104, conductive traces 122, integrated circuit (IC) bond pads 120 and 120a, interconnect bond pads 120b, and a joining ring 142a formed on an interior surface 93 of the glass substrate panel 192. The IC bond pads 120 and 120a can be flip-chip bond pads for an IC device, with the conductive traces 122a electrically connecting the MEMS device 104 to the IC bond pads 120a, and the conductive traces 122 providing electrical connection from the IC bond pads 120 to the interconnect bond pads 120b. The interconnect bond pads 120b provide a point of connection for through-glass via interconnects in a cover glass. The joining ring 142a is a polymeric, glass, or metal joining ring surrounding the MEMS device 104, the IC bond pads 120 and 120a and overlying the conductive traces 122.

The plan view depicted in FIG. 29B is an example of an arrangement of a device unit 212. In some other implementations, for example, a device unit can include multiple MEMS devices, one or more IC devices instead of or in addition to the MEMS device 104, and multiple joining rings, some of which may be segmented or discontinuous. While IC bond pads 120 and 120a are shown in an edge pad configuration in FIG. 29B, in some other implementations, they can be arranged in alternate configurations including an area array or with a staggered geometry.

In some implementations, formation of the MEMS device 104, the conductive traces 122 and 122a, the IC bond pads 120 and 120a, the interconnect pad 120b, and the joining ring 142a on the interior surface 93 is performed across all device units 212 of the glass substrate panel 192 in one or more batch processes.

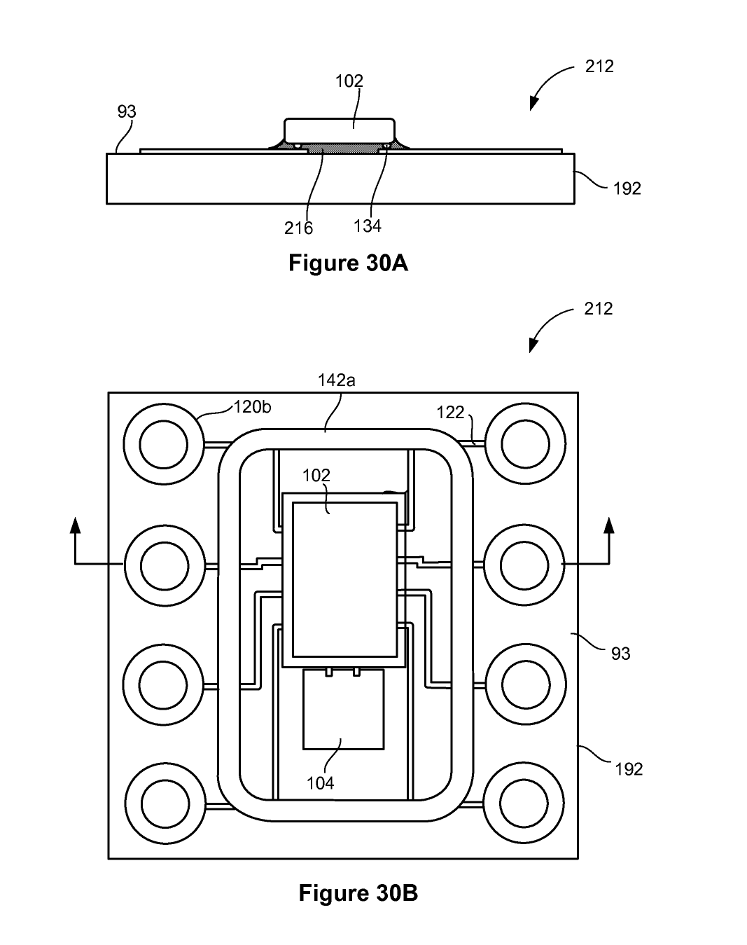

FIGS. 30A and 30B depict examples of cross-sectional view and plan views, respectively, of the device unit 212 including an IC device 102. The IC device 102 is bonded to the pads 120 and 120a (not shown) by solder bonds 134 and is electrically connected to the MEMS device 104 and to the interconnect pads 120b. An underfill material 216 is disposed between the IC device 102 and the glass substrate panel 192.

In some implementations, the IC device 102 can be attached by a flip chip bonding process in which flux is applied to the pads 120 and 120a, the IC device is placed on the interior surface 93 of the glass substrate panel 192, and the glass substrate panel 192 is reflown in a reducing atmosphere to form solder bond 134 between the IC bond pads 120 and 120a (not shown) and the IC device 102. The underfill material 216 can then be dispensed around the IC device 102 and cured. In some implementations, attachment of IC devices 102 to device units 212 is performed across all device units 212 of the glass substrate panel 192 in a batch process.

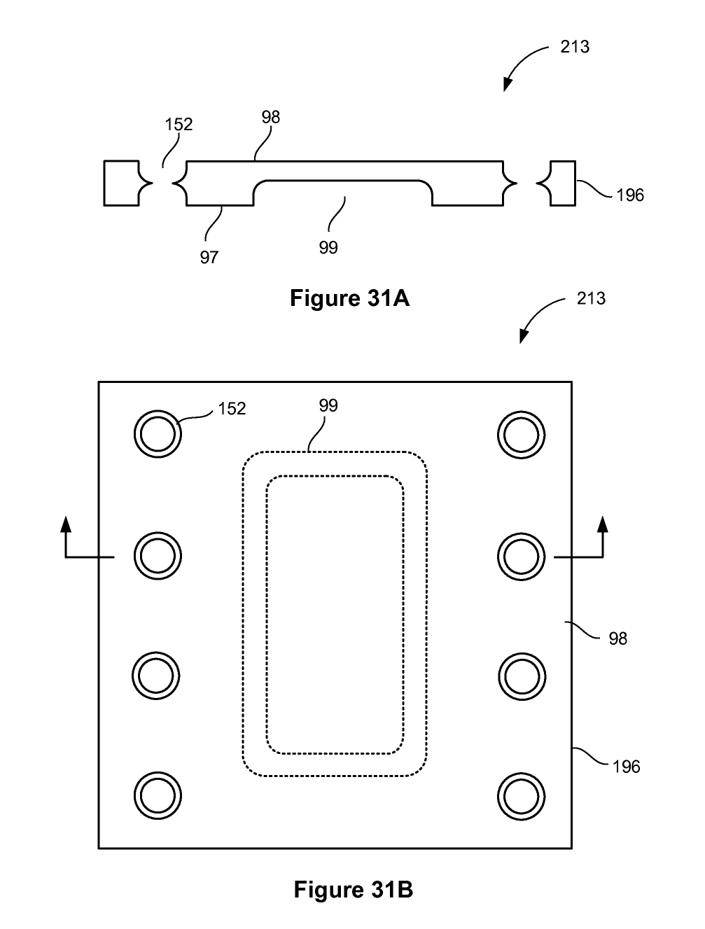

FIGS. 31A and 31B depict examples of cross-sectional view and plan views, respectively, of a cover glass unit 213 of a cover glass panel 196, a portion of which is shown in the Figures. The cover glass unit 213 includes a recess 99 in an interior surface 97 of the cover glass panel 196 and through-glass via holes 152 that extend from the interior surface 97 to an exterior surface 98. (For clarity, components behind glass surfaces in FIG. 31B are shown in dotted lines, though the cover glass panel 196 can be transparent or non-transparent according to the desired implementation.)

In some implementations, formation of the recesses 99 and through-glass via holes 152 is performed across all cover glass units 213 of a cover glass panel 192. Details of various implementations of forming recesses and through-glass via holes in a cover glass panel are discussed below with respect to FIG. 35.

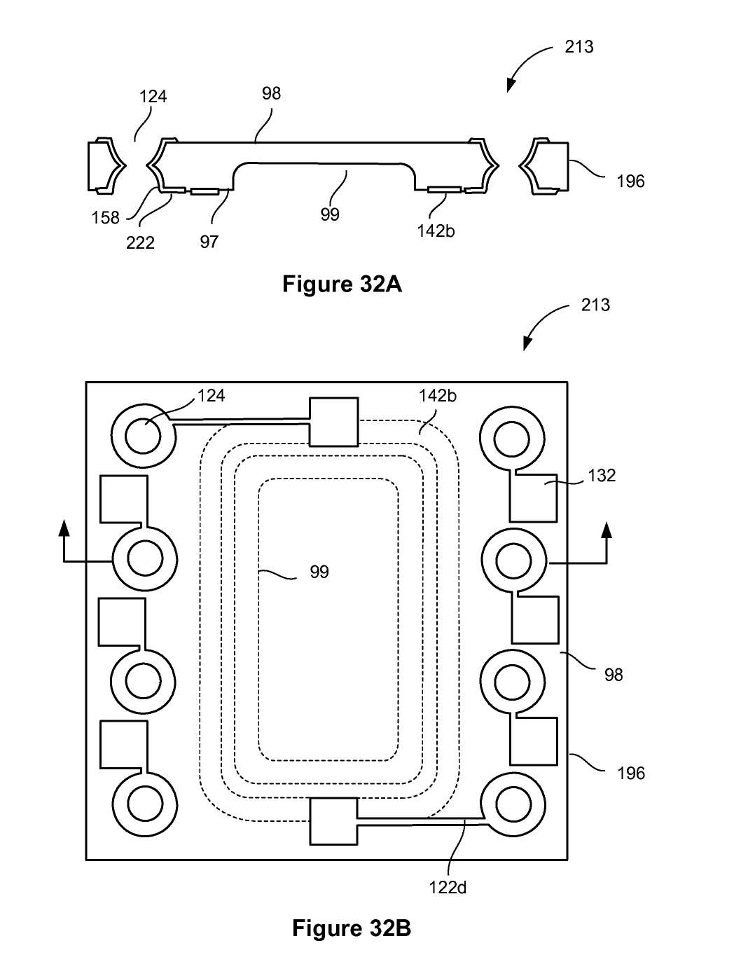

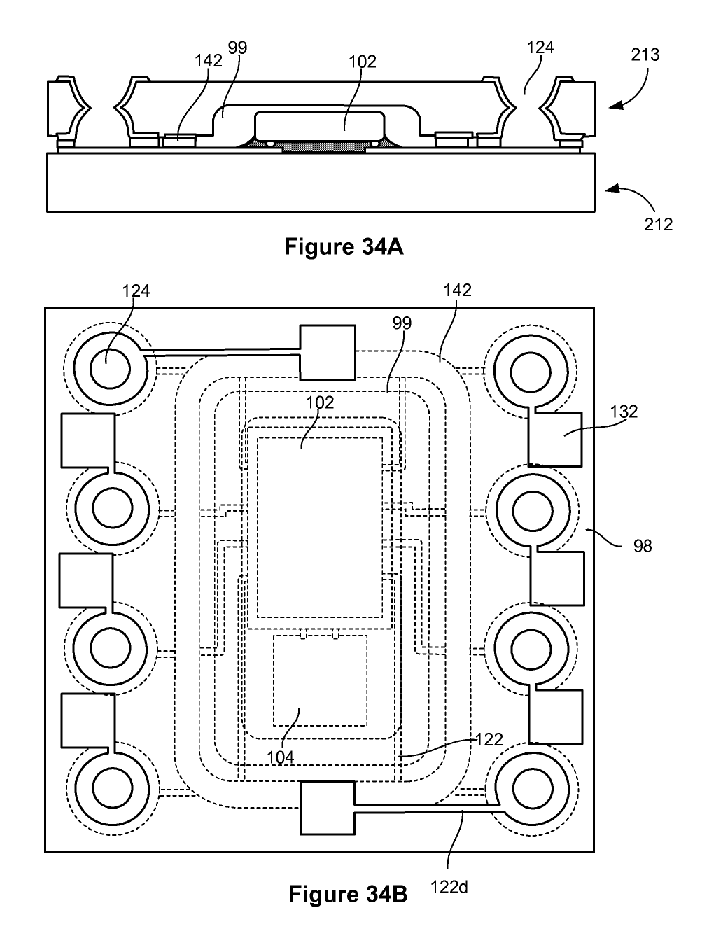

FIGS. 32A and 32B depict examples of cross-sectional and plan views, respectively, of the cover glass unit 213 after metallization. The cover glass unit 213 includes through-glass via interconnects 124, each of which includes a sidewall metallization layer 158, exterior pads 132 on an exterior surface 98, conductive traces 122d on the exterior surface 98, and a joining ring 142b on an interior surface 97. The exterior pads 132 can be connected to the through-glass via interconnects 124 by the conductive traces 122d, and can be surface mount device (SMD) pads configured to connect to a printed circuit board (PCB), for example, or may provide an electrical interface to a PCB or other device. The joining ring 142b surrounds the recess 99 and is configured to align with and be joined to joining ring 142a of device unit 212 depicted in FIGS. 29B and 30B. The sidewall metallization layer 158 of each through-glass via interconnect 124 includes a flange 222 on the interior surface 97 of the cover glass panel 196. The flanges 222 can be configured to align with the interconnect pads 120b depicted in FIGS. 29B and 30B. In some implementations, metallization of the cover glass units 213 performed across all cover glass units 213 of a cover glass panel 192 in a batch process. Details of various implementations of metalizing a cover glass panel are discussed below with respect to FIG. 34.

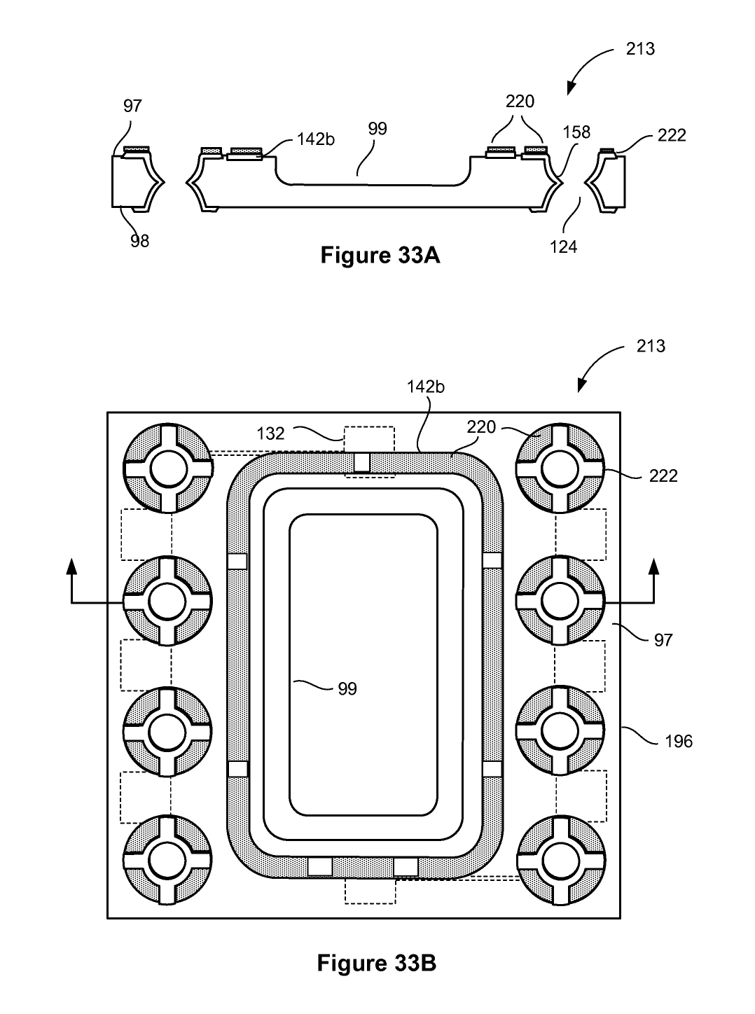

FIGS. 33A and 33B depict examples of cross-sectional and plan views, respectively, of the cover glass unit 213 including solder paste 220 for joining to the device unit 212. (Note that the plan view depicted in FIG. 33B shows the interior surface 97 face up). The solder paste 220 is disposed on the joining ring 142b and on the flanges 222 of the through-glass via interconnects 124. In some implementations, screen printing or otherwise placing solder paste 220 on the joining rings 142b and flanges 220 of cover glass units 213 is performed across all cover glass units 213 of a cover glass panel 192 in a batch process.

FIGS. 34A and 34B depict examples of cross-sectional and plan views, respectively, of the cover glass unit 213 joined to the device unit 212. In some implementations, cover glass panel 196 is aligned with and placed on the glass substrate panel 192, followed by reflow of the solder paste 220 depicted in FIGS. 33A and 33B. Solder reflow establishes electrical connections between through-glass via interconnects 124 of the cover glass unit 213 and pads 120b of the glass substrate unit 212. Solder reflow also may join the joining rings 142a and 142b of the device unit 212 and cover glass unit 213 shown in FIGS. 29B and 32B, respectively, to form a joining ring 142, which provides a seal around the IC device 102 and MEMS device 104.

FIG. 35 shows an example of a flow diagram illustrating a manufacturing process for a cover glass panel including through-glass via interconnects. The process 330 begins at block 332 with patterning and formation of through-glass via holes and recesses in the cover glass panel. Block 332 includes applying and patterning a mask on the interior and exterior surfaces of the cover glass panel. Aligned through-glass via hole openings are patterned on the interior and exterior surfaces, and recesses are patterned on the interior surfaces. The recesses and through-glass via hole openings can be patterned in the same or different operations. The mask material may be selected depending on the subsequent glass removal operation. For subsequent wet etching, for example, mask materials may include photoresist, deposited layers of polysilicon or silicon nitride, silicon carbide, or thin metal layers of chrome, chrome and gold, or other etch-resistant material. For sandblasting, mask materials include photoresist, a laminated dry-resist film, a compliant polymer, a silicone rubber, a metal mask, or a metal or polymeric screen.

Forming the through-glass via holes and recesses can involve wet etching or sandblasting, or a combination of these techniques to remove material from the cover glass panel. Wet etch solutions include hydrogen fluoride based solutions, e.g., concentrated hydrofluoric acid (HF), diluted HF (HF:H₂O), buffered HF (HF:NH₄F:H₂O), or other suitable etchant with reasonably high etch rate of the glass substrate and high selectivity to the masking material. The etchant also may be applied by other techniques such as spraying and puddling. A wet etch sequence to form through-glass via holes may be performed consecutively on one side and then the other, or on both sides simultaneously. If sandblasting is used, masking and sandblasting each side may be performed simultaneously or consecutively.

The recesses and through-glass via hole openings can be formed in the same or different operations. For example, in some implementations, the through-glass via holes can be etched, followed by patterning and etching of the recesses. In some other implementations, the through-glass via holes and recesses can be patterned and sandblasted simultaneously. Moreover, the techniques to pattern and form the recesses can be the same or different techniques as used to pattern and form the through-glass via holes.

In some implementations, multiple recesses for each cover glass unit on the cover glass panel are fabricated, such that each of the resulting individual packages includes multiple cavities. In some implementations in which multiple cavities are formed, all or some of multiple cavities can be independently and hermetically closed to the ambient, all or some of the cavities can share a closed and hermetic environment, or all or some of the cavities can partially or completely be open to ambient. In some implementations, one or more of the recesses and/or through-glass via holes can span two adjacent cover glass units, such that after die singulation, these recesses or through-glass via holes are open at a side of the glass package. In some implementations, a port or peripheral through-glass via hole can be formed.

The process 330 then continues at block 334 with deposition of a metal seed layer on the cover glass panel, including on the interior and exterior surfaces of the cover glass panel and on the sidewalls of the through-glass via holes. The metal seed layer provides a conductive substrate on which a metal layer can be plated. The metal seed layer is generally conformal to the underlying exterior, interior and sidewall surfaces of the cover glass panel to form a continuous metal seed layer connecting the interior and exterior surfaces of the cover glass panel. Examples of metals include Cu, Al, Au, Nb, Cr, Ta, Ni, W, Ti and Ag. In some implementations, an adhesion layer is conformally deposited to prior to deposition of the metal seed layer. For example, for a Cu seed layer, examples of adhesion layers include Cr and Ti. The adhesion layer and seed layer may be deposited by sputter deposition though other conformal deposition processes, including atomic layer deposition (ALD), evaporation and other chemical vapor deposition (CVD) or physical vapor deposition (PVD) processes may be used. Example thicknesses of the adhesion layer range from about 100 Å to about 500 Å, or more particularly from about 150 Å to 300 Å, though the adhesion layer can be thinner or thicker according to the implementation. Example seed layer thicknesses range from about 800 Å to 10000 Å, or more particularly from about 1000 Å to about 5000 Å, though the metal seed layer can be thinner or thicker according to the desired implementation. In one example, a Cr/Cu adhesion/seed layer having a thickness of about 200 Å/2000 Å is deposited.

The process 330 then continues at block 336 with patterning joining rings, traces and pads on the cover glass panel. Block 336 can include applying and patterning a mask on the interior and exterior surfaces of the cover glass panel. In some implementations, a laminate photoresist that tents over the through-glass via hole openings and recesses is used as a mask material. The photoresist can be patterned by techniques including masked exposure to radiation and chemical development. The laminate photoresist can be developed to allow plating inside the through-glass via holes, as well as patterned on the exterior and interior surfaces to form the electrical routing, pads (including dummy pads and electrically connected pads) and joining rings according to the desired implementation. One example of a laminate photoresist that tents is a DuPont® WBR2000 dry film photoresist, which is applied to the substrate surface by lamination. Other resists may be used including dry film, liquid and epoxy-based resists.

The process 330 then continues at block 338 with plating the cover glass panel to simultaneously form the through-glass via interconnects, joining rings, traces and pads. Examples of metals that can be plated to form the through-glass via interconnects, joining rings, traces and pads include Cu, Ni and Ni alloys including nickel cobalt (NiCo), nickel manganese (NiMn) and nickel iron (NiFe), and combinations of these. In some implementations, block 338 includes plating a thin layer of one or more metals such as Au or palladium Pd on a thicker layer of a main conductor metal. Examples of metal stacks that can be formed in block 336 include Cu, Cu/Ni/Au, Cu/Ni alloy/Au, Ni/Au, Ni alloy/Au, Ni/Pd/Au, Ni alloy/Pd/Au, Ni/Pd and Ni alloy/Pd.

The process 330 then continues at block 340 with removing the remaining resist and unplated metal seed layer. Block 340 can involve exposing the resist to an appropriate solvent and the metal seed layer to a wet or dry etch, and can be performed on a single side at a time or on both sides simultaneously.

As indicated above, in some implementations, a metal joining ring is used to join a cover glass and a glass substrate. A metal joining ring can provide a hermetic seal around one or more devices in some implementations. A metal joining ring can include a solder bond in some implementations. A solder bond can be formed from a eutectic or non-eutectic solder material according to the desired implementation. A metal joining ring can include an intermetallic compound in some implementations.

FIGS. 36A and 36B show examples of cross-sectional schematic illustrations of metal joining rings including solder bonds. FIG. 36A shows an example of a joining ring 142, including joining rings 142a and 142b and solder bond 164. (While the below discussion refers to the compositions of the joining rings 142a and 142b and solder material prior to soldering, it is understood that the resulting joining ring 142 may include one or more alloys of the metals used as well as a compositional gradient.) Each of the joining rings 142a and 142b can be, for example, a joining ring on a glass substrate or panel. In some implementations, the joining ring 142a can be disposed on one of a glass substrate or cover glass of a glass package, with the joining ring 142b disposed on the other of the glass substrate or cover glass of the glass package.

The joining rings 142a and 142b each include one or more solderable metals, and can have the same or different metallurgies. Examples of metals that can be included in a joining ring 142a or 142b include Cu, Al, Au, Nb, Cr, Ta, Ni, W, Ti, Pd, Ag and alloys thereof.

In some implementations, one or more layers of Cu, Cu alloys, Ni, Ni alloys, or a combinations of these to provide most of the thickness of the joining rings 142a and 142b. In some implementations, one or more layers of an easily soldered metal such as Pd or Au can be used to provide a top thickness of the joining rings 142a and 142b prior to soldering. Examples of joining ring metallurgies include Cu, Cu/Ni/Au, Cu/Ni/Pd/Au, Ni/Au, Ni/Pd/Au, Cu/Ni alloy/Au, Cu/Ni alloy/Pd/Au, Ni alloy/Au, and Ni alloy/Pd/Au. Examples of Ni alloys include NiCo, NiMn and NiFe. Example thicknesses of each layer can be between about 1 and 10 microns for Cu or Cu alloy layers, between about 1 and 20 microns for Ni or Ni alloy layers, less than about 1 micron from Au layers, and less than about 0.5 microns for Pd layers. Other thicknesses can be used according to the desired implementation.

In some implementations, a width (W) of each of the joining rings 142a and 142b can be between about 20 microns and 500 microns. In the example depicted in FIG. 36A, the width of joining ring 142a is the same as that of joining ring 142b.

As indicated above, the solder bond 164 can have a non-eutectic or eutectic metallurgy. In some implementations, a lead-free metallurgy is used. Examples of eutectic solders include used include InBi, CuSn, CuSnBi, CuSnIn, and AuSn. Melting temperatures of these eutectic alloys can be about 150° C. for the InBi and CuSnIn eutectic alloys, about 225° C. for the CuSn eutectic alloy, and about 305° C. for the AuSn eutectic alloy. Examples of non-eutectic solders include indium (In), indium/silver (InAg) and tin (Sn) solders.

A solder material can be added to a joining ring on a glass component by a method such as plating, screen printing or solder jetting. In the case of eutectic or other alloys, the composite metals can be plated, printed or jetted sequentially or as a composite. A solder bond is formed by applying heat and reflowing the solder material. The solder material wets and alloys with the joining rings, forming a solid bond when solidified. In some implementations, a soldering process involves using a reducing agent to reduce oxidation, which can slow or prevent a solder bond from forming. In some implementations in which a eutectic alloy is used, no reducing agent is used. This can be desirable in implementations where reducing agent trapped in a package cavity can adversely affect the performance or durability of one or more devices disposed in the cavity.

FIG. 36B shows an example of a joining ring 142, including joining rings 142a and 142b and solder bond 164. In the example of FIG. 36B, joining ring 142a is wider than joining ring 142b, such that solder bond 164 is a fillet joint. In some implementations, fillet joints can provide stronger bonds and can increase alignment tolerances. A wider joining ring, such as the joining ring 142a, can be on either glass component to be joined. In some implementations, a distance D that the joining ring 142a extends past the joining ring 142b is at least about 25 microns, with the joining ring 142a at least about 50 microns wider than the joining ring 142b.

In some implementations, the metal joining 142 is FIGS. 36A and 36B can be reinforced with epoxy or polymer coating. Implementations of metal joining rings described herein are not limited to joining glass components of an all-glass package, but can include joining any two glass components.

In some implementations, a glass component of a package includes a coating on an exterior surface. For example, a glass substrate and/or cover glass as described above can be coated with a polymer coating. It should be noted that the implementations are not limited to all-glass packages as described above, but also can be implemented with any package including a glass component. For example, a package can include a coated glass substrate and a non-glass lid or cover.

A coating can be used to increase opacity, provide package markings, increase package visibility, increase package durability, and increase scratch-resistance. For example, in some implementations, a coated surface can be marked with industry standard marking process to provide a unique identification number for the packaged device. In another example, a surface is selectively coated in pattern to provide a signal transmission pathway to an encapsulated device and enable optical communication between a packaged device and the outside.

FIGS. 37A and 37B show examples of cross-sectional schematic illustrations of a glass package including a coating. In FIGS. 37A and 37B, a glass package 90 includes a cover glass 96, including through-glass via interconnects 124, and a glass substrate 92. The cover glass 96 is sealed to the glass substrate 92 by a joining ring 142 and by solder material 164 between the through-glass via interconnects 124 and the cover glass 96. A device 100 is encapsulated between the cover glass 96 and the glass substrate 92.

In FIG. 37A, a coating layer 168 coats an exterior surface 94 of the glass substrate 92, extending to the edges of the glass substrate 92. In FIG. 37B, a coating layer 168 coats an exterior surface 94 of the glass substrate 92, extending around an edge of the glass substrate 92 and partially coating side surfaces 95. Coating around an edge or corner can reduce or prevent edge cracks in some implementations.

A coating can be applied to one or more surfaces of a glass package. For example, for a package that includes two major exterior surfaces connected by four side surfaces, any number of the major exterior and/or side surfaces can be wholly or partially coated.

In some implementations, a coating includes a vacuum-deposited film, including films deposited by sputter deposition, chemical vapor deposition (CVD), atomic layer deposition (ALD), evaporation, and plasma spray deposition. In some implementations, a coating includes an inorganic dielectric film. Examples include carbon (C) including diamond-like carbon and near-diamond-like carbon, silicon dioxide (SiO₂), aluminum oxide (Al₂O₃), aluminum nitride (AlN) and silicon nitride (SiN). In some implementations, a coating includes a metal film. Examples include titanium (Ti), tungsten (W), titanium/tungsten (TiW), chrome/gold (CrAu), and gold (Au). Metal films can be used in implementations in which the coated surface does not include through-glass vias, bond pads, conductive traces or other electrical components. Example thicknesses of vacuum-deposited dielectric or metal coatings can range from about 0.1 to about 5 microns. In some implementations, a vacuum-deposited coating has a thickness of less than about 2 microns.

In some implementations, a coating includes a polymer film. Polymer films can include spun-on films, dipped film, brushed-on films, spray-on films, rolled-on films and laminated films. Example of polymers include SU-8, polyimide, benzocyclobutene (BCB), polynorbornene (PNB), PID polymer available from Nippon Steel Corporation, particle-loaded polymers including polymers loaded with particles of metal, dielectric, or long chain polymer compounds such as a SiO₂ particle filled epoxy available from Shin-Etsu Chemical Company, and other epoxies such as epoxies as Master Bond epoxy, polyurethanes, polycarbonates, and silicones. In some implementations, dyes or other additives can be added to make a polymer coating colored or black. Example thicknesses of a polymer coating range from about 10 to 100 microns. In some implementations, a polymer coating has a thickness of less than about 50 microns. In some implementations, a coating is formed from a photoimageable polymer film. Such a coating can be patterned by photolithography according to the desired implementation.

In some implementations, a coating includes an anisotropic conductive film (ACF). An ACF film can enable contact to an electrical feed-through or other electrically active components.

In some implementations, a coating can include an inorganic dielectric film and a polymer film. For example, a package can include a scratch resistant vacuum-deposited inorganic dielectric across one or more surfaces, with polymer coverage on package corners. An inorganic dielectric film can be under or over the polymer film according to the desired implementation. Similarly, in some implementations, a coating can include a metal film and a polymer film.

Coating can be performed at any appropriate time during a manufacturing process. For example, it can be performed at a panel level of a batch process at any appropriate point prior to singulation or at on an individual package level after singulation. A glass substrate and/or cover glass panel, for example, can be coated prior to or after joining the glass substrate and cover glass panel. A glass substrate panel can be coated, for example, prior to or after fabrication of one or more devices or other components on its interior surface. Similarly, a cover glass panel can be coated, for example, prior to or after formation of recesses or other components. In some other implementations, coating can be performed at a batch level after singulation.

FIG. 38 shows an example of a flow diagram illustrating a process for coating glass packages. The process 400 begins at block 402 with placing joined glass substrate and cover glass panels on a dicing tape. The process 400 continues at block 404 with singulating the joined panels to form individual glass packages. The individual glass packages can include two major surfaces connected by side surfaces. At this point in the process, one of the major surfaces of each the package faces the dicing tape, with the other major surface exposed and accessible to coating. The side surfaces of each package may not be accessible to coating, however, due to the proximity of all the adjacent packages. The process 400 continues at block 406 with stretching the dicing tape to introduce spaces between the singulated packages, thereby physically separating the packages and increasing accessibility of the side surfaces. The process 400 then continues at block 408 with coating the exposed exterior and side surfaces of the individual packages. In this manner, all or some of the side surface area of each package can be coated at a panel level.

As indicated above, in some implementations, a glass package as described herein can be part of a display device. In some other implementations, non-display devices fabricated on glass substrates can be compatible with displays and other devices that are also fabricated on glass substrates, with the non-display devices fabricated jointly with a display device or attached as a separate device, the combination having well-matched thermal expansion properties.

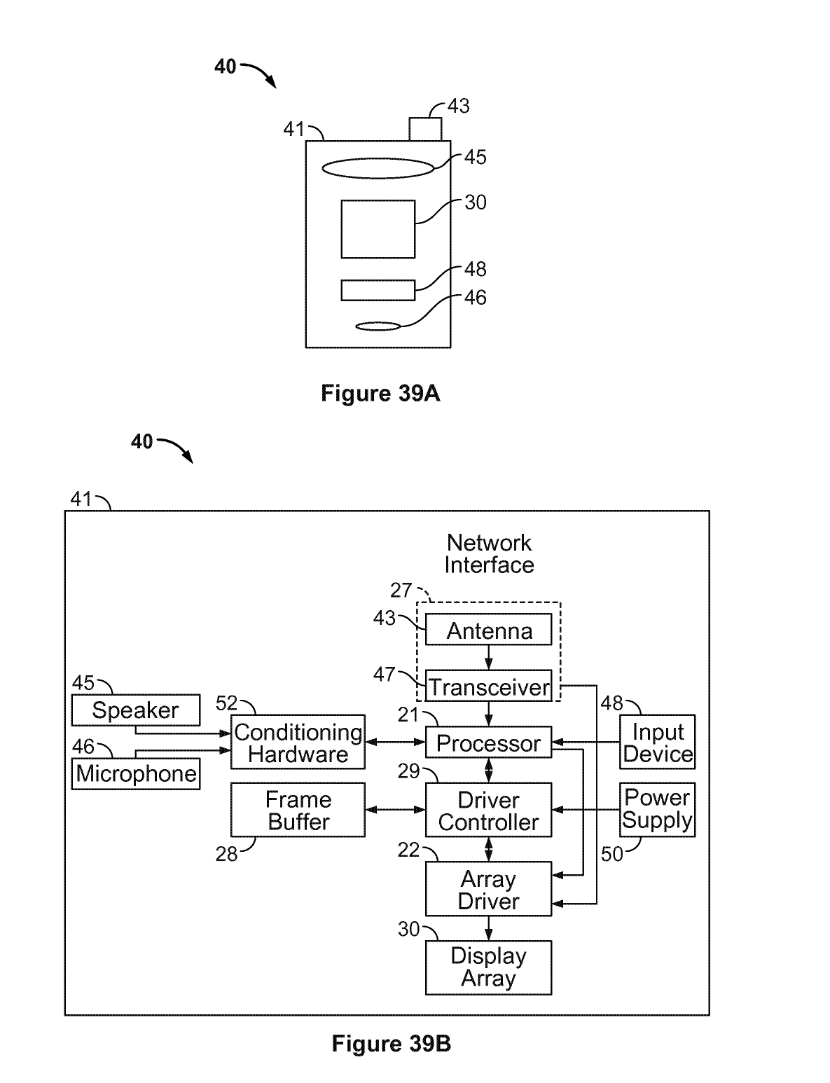

FIGS. 39A and 39B show examples of system block diagrams illustrating a display device 40 that includes a plurality of interferometric modulators. The display device 40 can be, for example, a smart phone, a cellular or mobile telephone. However, the same components of the display device 40 or slight variations thereof are also illustrative of various types of display devices such as televisions, tablets, e-readers, hand-held devices and portable media players.

The display device 40 includes a housing 41, a display 30, an antenna 43, a speaker 45, an input device 48 and a microphone 46. The housing 41 can be formed from any of a variety of manufacturing processes, including injection molding, and vacuum forming. In addition, the housing 41 may be made from any of a variety of materials, including, but not limited to: plastic, metal, glass, rubber and ceramic, or a combination thereof. The housing 41 can include removable portions (not shown) that may be interchanged with other removable portions of different color, or containing different logos, pictures, or symbols.

The display 30 may be any of a variety of displays, including a bi-stable or analog display, as described herein. The display 30 also can be configured to include a flat-panel display, such as plasma, EL, OLED, STN LCD, or TFT LCD, or a non-flat-panel display, such as a CRT or other tube device. In addition, the display 30 can include an interferometric modulator display, as described herein.

The components of the display device 40 are schematically illustrated in FIG. 39]B. The display device 40 includes a housing 41 and can include additional components at least partially enclosed therein. For example, the display device 40 includes a network interface 27 that includes an antenna 43 which is coupled to a transceiver 47. The transceiver 47 is connected to a processor 21, which is connected to conditioning hardware 52. The conditioning hardware 52 may be configured to condition a signal (e.g., filter a signal). The conditioning hardware 52 is connected to a speaker 45 and a microphone 46. The processor 21 is also connected to an input device 48 and a driver controller 29. The driver controller 29 is coupled to a frame buffer 28, and to an array driver 22, which in turn is coupled to a display array 30. In some implementations, a power supply 50 can provide power to substantially all components in the particular display device 40 design.

The network interface 27 includes the antenna 43 and the transceiver 47 so that the display device 40 can communicate with one or more devices over a network. The network interface 27 also may have some processing capabilities to relieve, for example, data processing requirements of the processor 21. The antenna 43 can transmit and receive signals. In some implementations, the antenna 43 transmits and receives RF signals according to the IEEE 16.11 standard, including IEEE 16.11(a), (b), or (g), or the IEEE 802.11 standard, including IEEE 802.11a, b, g, n, and further implementations thereof. In some other implementations, the antenna 43 transmits and receives RF signals according to the BLUETOOTH standard. In the case of a cellular telephone, the antenna 43 is designed to receive code division multiple access (CDMA), frequency division multiple access (FDMA), time division multiple access (TDMA), Global System for Mobile communications (GSM), GSM/General Packet Radio Service (GPRS), Enhanced Data GSM Environment (EDGE), Terrestrial Trunked Radio (TETRA), Wideband-CDMA (W-CDMA), Evolution Data Optimized (EV-DO), 1xEV-DO, EV-DO Rev A, EV-DO Rev B, High Speed Packet Access (HSPA), High Speed Downlink Packet Access (HSDPA), High Speed Uplink Packet Access (HSUPA), Evolved High Speed Packet Access (HSPA+), Long Term Evolution (LTE), AMPS, or other known signals that are used to communicate within a wireless network, such as a system utilizing 3G or 4G technology. The transceiver 47 can pre-process the signals received from the antenna 43 so that they may be received by and further manipulated by the processor 21. The transceiver 47 also can process signals received from the processor 21 so that they may be transmitted from the display device 40 via the antenna 43.

In some implementations, the transceiver 47 can be replaced by a receiver. In addition, in some implementations, the network interface 27 can be replaced by an image source, which can store or generate image data to be sent to the processor 21. The processor 21 can control the overall operation of the display device 40. The processor 21 receives data, such as compressed image data from the network interface 27 or an image source, and processes the data into raw image data or into a format that is readily processed into raw image data. The processor 21 can send the processed data to the driver controller 29 or to the frame buffer 28 for storage. Raw data typically refers to the information that identifies the image characteristics at each location within an image. For example, such image characteristics can include color, saturation and gray-scale level.

The processor 21 can include a microcontroller, CPU, or logic unit to control operation of the display device 40. The conditioning hardware 52 may include amplifiers and filters for transmitting signals to the speaker 45, and for receiving signals from the microphone 46. The conditioning hardware 52 may be discrete components within the display device 40, or may be incorporated within the processor 21 or other components.

The driver controller 29 can take the raw image data generated by the processor 21 either directly from the processor 21 or from the frame buffer 28 and can re-format the raw image data appropriately for high speed transmission to the array driver 22. In some implementations, the driver controller 29 can re-format the raw image data into a data flow having a raster-like format, such that it has a time order suitable for scanning across the display array 30. Then the driver controller 29 sends the formatted information to the array driver 22. Although a driver controller 29, such as an LCD controller, is often associated with the system processor 21 as a stand-alone Integrated Circuit (IC), such controllers may be implemented in many ways. For example, controllers may be embedded in the processor 21 as hardware, embedded in the processor 21 as software, or fully integrated in hardware with the array driver 22.

The array driver 22 can receive the formatted information from the driver controller 29 and can re-format the video data into a parallel set of waveforms that are applied many times per second to the hundreds, and sometimes thousands (or more), of leads coming from the display's x-y matrix of pixels.

In some implementations, the driver controller 29, the array driver 22, and the display array 30 are appropriate for any of the types of displays described herein. For example, the driver controller 29 can be a conventional display controller or a bi-stable display controller (such as an IMOD controller). Additionally, the array driver 22 can be a conventional driver or a bi-stable display driver (such as an IMOD display driver). Moreover, the display array 30 can be a conventional display array or a bi-stable display array (such as a display including an array of IMODs). In some implementations, the driver controller 29 can be integrated with the array driver 22. Such an implementation can be useful in highly integrated systems, for example, mobile phones, portable-electronic devices, watches or small-area displays.

In some implementations, the input device 48 can be configured to allow, for example, a user to control the operation of the display device 40. The input device 48 can include a keypad, such as a QWERTY keyboard or a telephone keypad, a button, a switch, a rocker, a touch-sensitive screen, a touch-sensitive screen integrated with display array 30, or a pressure- or heat-sensitive membrane. The microphone 46 can be configured as an input device for the display device 40. In some implementations, voice commands through the microphone 46 can be used for controlling operations of the display device 40.

The power supply 50 can include a variety of energy storage devices. For example, the power supply 50 can be a rechargeable battery, such as a nickel-cadmium battery or a lithium-ion battery. In implementations using a rechargeable battery, the rechargeable battery may be chargeable using power coming from, for example, a wall socket or a photovoltaic device or array. Alternatively, the rechargeable battery can be wirelessly chargeable. The power supply 50 also can be a renewable energy source, a capacitor, or a solar cell, including a plastic solar cell or solar-cell paint. The power supply 50 also can be configured to receive power from a wall outlet.

In some implementations, control programmability resides in the driver controller 29 which can be located in several places in the electronic display system. In some other implementations, control programmability resides in the array driver 22. The above-described optimization may be implemented in any number of hardware and/or software components and in various configurations.

The various illustrative logics, logical blocks, modules, circuits and algorithm steps described in connection with the implementations disclosed herein may be implemented as electronic hardware, computer software, or combinations of both. The interchangeability of hardware and software has been described generally, in terms of functionality, and illustrated in the various illustrative components, blocks, modules, circuits and steps described above. Whether such functionality is implemented in hardware or software depends upon the particular application and design constraints imposed on the overall system.

The hardware and data processing apparatus used to implement the various illustrative logics, logical blocks, modules and circuits described in connection with the aspects disclosed herein may be implemented or performed with a general purpose single- or multi-chip processor, a digital signal processor (DSP), an application specific integrated circuit (ASIC), a field programmable gate array (FPGA) or other programmable logic device, discrete gate or transistor logic, discrete hardware components, or any combination thereof designed to perform the functions described herein. A general purpose processor may be a microprocessor, or, any conventional processor, controller, microcontroller, or state machine. A processor also may be implemented as a combination of computing devices, such as a combination of a DSP and a microprocessor, a plurality of microprocessors, one or more microprocessors in conjunction with a DSP core, or any other such configuration. In some implementations, particular steps and methods may be performed by circuitry that is specific to a given function.

In one or more aspects, the functions described may be implemented in hardware, digital electronic circuitry, computer software, firmware, including the structures disclosed in this specification and their structural equivalents thereof, or in any combination thereof. Implementations of the subject matter described in this specification also can be implemented as one or more computer programs, i.e., one or more modules of computer program instructions, encoded on a computer storage media for execution by, or to control the operation of, data processing apparatus.

If implemented in software, the functions may be stored on or transmitted over as one or more instructions or code on a computer-readable medium. The steps of a method or algorithm disclosed herein may be implemented in a processor-executable software module which may reside on a computer-readable medium. Computer-readable media includes both computer storage media and communication media including any medium that can be enabled to transfer a computer program from one place to another. A storage media may be any available media that may be accessed by a computer. By way of example, and not limitation, such computer-readable media may include RAM, ROM, EEPROM, CD-ROM or other optical disk storage, magnetic disk storage or other magnetic storage devices, or any other medium that may be used to store desired program code in the form of instructions or data structures and that may be accessed by a computer. Also, any connection can be properly termed a computer-readable medium. Disk and disc, as used herein, includes compact disc (CD), laser disc, optical disc, digital versatile disc (DVD), floppy disk, and blu-ray disc where disks usually reproduce data magnetically, while discs reproduce data optically with lasers. Combinations of the above also may be included within the scope of computer-readable media. Additionally, the operations of a method or algorithm may reside as one or any combination or set of codes and instructions on a machine readable medium and computer-readable medium, which may be incorporated into a computer program product.

Various modifications to the implementations described in this disclosure may be readily apparent to those skilled in the art, and the generic principles defined herein may be applied to other implementations without departing from the spirit or scope of this disclosure. Thus, the claims are not intended to be limited to the implementations shown herein, but are to be accorded the widest scope consistent with this disclosure, the principles and the novel features disclosed herein. The word “exemplary” is used exclusively herein to mean “serving as an example, instance, or illustration.” Any implementation described herein as “exemplary” is not necessarily to be construed as preferred or advantageous over other possibilities or implementations. Additionally, a person having ordinary skill in the art will readily appreciate, the terms “upper” and “lower” are sometimes used for ease of describing the figures, and indicate relative positions corresponding to the orientation of the figure on a properly oriented page, and may not reflect the proper orientation of an IMOD as implemented.

Certain features that are described in this specification in the context of separate implementations also can be implemented in combination in a single implementation. Conversely, various features that are described in the context of a single implementation also can be implemented in multiple implementations separately or in any suitable subcombination. Moreover, although features may be described above as acting in certain combinations and even initially claimed as such, one or more features from a claimed combination can in some cases be excised from the combination, and the claimed combination may be directed to a subcombination or variation of a subcombination.

Similarly, while operations are depicted in the drawings in a particular order, a person having ordinary skill in the art will readily recognize that such operations need not be performed in the particular order shown or in sequential order, or that all illustrated operations be performed, to achieve desirable results. Further, the drawings may schematically depict one more example processes in the form of a flow diagram. However, other operations that are not depicted can be incorporated in the example processes that are schematically illustrated. For example, one or more additional operations can be performed before, after, simultaneously, or between any of the illustrated operations. In certain circumstances, multitasking and parallel processing may be advantageous. Moreover, the separation of various system components in the implementations described above should not be understood as requiring such separation in all implementations, and it should be understood that the described program components and systems can generally be integrated together in a single software product or packaged into multiple software products. Additionally, other implementations are within the scope of the following claims. In some cases, the actions recited in the claims can be performed in a different order and still achieve desirable results.

1. A method, comprising:
attaching an integrated circuit (IC) device to bond pads on a glass substrate such that the IC device is in electrical communication with an electromechanical systems (EMS) device fabricated on the glass substrate;
aligning a cover glass with the glass substrate such that the cover glass covers the EMS device and the IC device; and
joining the cover glass to the glass substrate to form a seal wholly or partially surrounding at least one of the EMS device and the IC device.

2. The method of claim 1, wherein joining the cover glass to the glass substrate includes forming a metal-to-metal bond between a metal joining ring on the cover glass and a metal joining ring on the glass substrate.

3. The method of claim 2, wherein the metal-to-metal bond includes at least one of a eutectic alloy, a non-eutectic alloy, a solder material, and an intermetallic compound.

4. The method of claim 2, wherein the metal joining ring on the cover glass and the metal joining on the glass substrate vary in width by at least about 50 microns.

5. The method of claim 2, wherein the metal-to-metal bond includes a fillet joint.

6. The method of claim 1, wherein joining the cover glass to the glass substrate includes forming an epoxy bond between the cover glass and the glass substrate.

7. The method of claim 1, wherein joining the cover glass to the glass substrate includes forming a glass frit bond between the cover glass and the glass substrate.

8. The method of claim 1, wherein attaching the IC device includes attaching the IC device to the glass substrate such that the IC device overlies the EMS device, at least in part.

9. The method of claim 1, further comprising forming one or more recesses in the cover glass.

10. The method of claim 1, further comprising forming one or more through-glass via holes in the cover glass.

11. The method of claim 1, further comprising forming a joining ring and conductive traces on the glass substrate.

12. The method of claim 1, further comprising plating the cover glass to simultaneously form one or more through-glass via interconnects and one or more metal joining rings.

13. The method of claim 1, wherein joining the cover glass to the glass substrate includes simultaneously joining the cover glass to the glass substrate and establishing an electrically conductive pathway between conductive traces on the cover glass and conductive traces on the glass substrate.

14. The method of claim 1, further comprising plating the cover glass to simultaneously form one or more bond pads and one or more metal joining rings.

15. The method of claim 1, wherein the glass substrate having an EMS device fabricated thereon is one device unit of a glass substrate panel having a plurality of arrayed device units.

16. The method of claim 15, wherein attaching an integrated circuit (IC) device to bond pads on a glass substrate includes attaching an IC device to each of the arrayed device units such that the IC device is in electrical communication with an EMS device of the device unit.

17. The method of claim 15, wherein the cover glass is one cover glass unit of a cover glass panel having a plurality of arrayed cover glass units.

18. The method of claim 17, wherein joining the cover glass to the glass substrate includes joining the cover glass panel to the glass substrate panel to simultaneously form a plurality of seals such that each cover glass unit is sealed to a device unit.

19. The method of claim 1, further comprising singulating the joined cover glass and glass substrate panels to form a plurality of individual glass packages.

20. The method of claim 19, further comprising simultaneously coating each of the plurality of individual glass packages with a polymer coating.

21. The method of claim 1, further comprising forming a metal joining ring on the glass substrate.

22. The method of claim 21, wherein the metal joining ring is formed during fabrication of the EMS device on the glass substrate.

23. An apparatus formed by the method of claim 1.

24. The apparatus of claim 23, further comprising:
a display;
a processor that is configured to communicate with the display, the processor being configured to process image data; and
a memory device that is configured to communicate with the processor.

25. The apparatus of claim 24, further comprising:
a driver circuit configured to send at least one signal to the display; and
a controller configured to send at least a portion of the image data to the driver circuit.

26. The apparatus of claim 24, further comprising:
an image source module configured to send the image data to the processor.

27. The apparatus of claim 26, wherein the image source module includes at least one of a receiver, transceiver, and transmitter.

28. The apparatus of claim 24, further comprising:
an input device configured to receive input data and to communicate the input data to the processor.

29. A method comprising:
aligning a glass substrate panel including a plurality of device units with a cover glass panel including a plurality of cover glass units;
joining the cover glass panel to the glass substrate panel; and
singulating the joined glass substrate and cover glass panels to form a plurality of individual glass packages, wherein each of the plurality of individual glass packages includes a cover glass sealed to a glass substrate, a device disposed within a cavity between the cover glass and the glass substrate, and a signal transmission pathway between the device and an exterior of the individual glass package.

30. The method of claim 29, wherein joining the glass substrate panel to the cover glass panel includes forming a plurality of joining rings, each of which seals a cover glass unit to a device unit.

31. The method of claim 29, further comprising, prior to alignment, forming a plurality of recesses and through-glass via holes in the cover glass panel.

32. The method of claim 31, further comprising, prior to alignment, metalizing the cover glass panel to form the plurality of cover glass units, wherein each cover glass unit includes a metal joining ring surrounding a recess, a through-glass via interconnect, a bond pad on a surface of the cover glass panel, and electrical routing from the through-glass via interconnect to the bond pad.

33. The method of claim 32, wherein metalizing the cover glass panel includes plating the cover glass panel to simultaneously form the metal joining, the through-glass via interconnect, the bond pad, and the electrical routing.
